(19) United States
(12) Patent Application Publication
(10) Pub. No.: US 2006/0239102 A1
(43) Pub. Date: Oct. 26, 2006

(54) Semiconductor integrated circuit device and its power supply wiring method

(76) Inventors: Atsushi Saita, Gifu (JP); Mamoru Mukuno, Gifu (JP)

Correspondence Address: MCDERMOTT WILL & EMERY LLP, 600 13TH STREET, N.W., WASHINGTON, DC, 20005-3096, US

(21) Appl. No.: 10/546,960

(22) PCT Filed: Feb. 26, 2004
(86) PCT No.: PCT/JP04/02278

§ 371 Date: Jun. 12, 2006

(30) Foreign Application Priority Data
Feb. 26, 2003 (JP) 2003-050042
Sep. 26, 2003 (JP) 2003-336427

(51) Int. Cl. G11C 5/14

(52) U.S. Cl. 365/226; 365/227

(57) ABSTRACT

The present invention discloses a power supply wiring method for stabilizing operation of a semiconductor integrated circuit device. A power supply mesh 24, which is arranged on an upper layer of a basic power supply wires 18 for supplying power to a logic circuit portion 13, includes vertical reinforcing power supply wires 22 and lateral reinforcing power supply wires 23. The widths of the vertical reinforcing power supply wires and lateral reinforcing power supply wires are optimized to mitigate IR drop or excessive current density in each division unit u0.

### FIELD OF THE INVENTION

The present invention relates to a semiconductor integrated circuit device and method for wiring a power supply.

### BACKGROUND ART

Advances in producing large-scale, highly integrated semiconductor integrated circuits (LSI) have resulted in outstanding voltage drops (IR drop) in logic circuits (for example, near the central area) caused by an increase in the resistance of power supply wiring, which is used to supply operation current to the logic circuit area. An IR drop in the power supply wiring leads to low response speed and deficient operation of the logic gate and thus cannot be overlooked. In a conventional LSI, to mitigate the IR drop, the total wiring width is increased by using reinforcing power supply wires in addition to basic power supply wire, which directly supply power to logic circuits. (See Japanese Laid-Open Patent Publication No. 2002-261245)

FIG. 91 is a plan view showing power supply wiring for a conventional LSI. The LSI 1 is provided with basic power supply wires 3 laid out in the X direction on a logic circuit portion 2, reinforcing power supply wires 4 laid out in a grid pattern on a plurality of wiring layers above the basic power supply wire 3, and a power supply ring 6.

The reinforcing power supply wires 4 are laid out at equal intervals (equal pitches) in the X direction and Y direction of FIG. 91 through automatic wiring layout. The intersections of the basic power supply wires 3 and the reinforcing power supply wires 4 are electrically connected through connection holes, such as via holes and the like. Operation current, which is supplied from power supply pads 5 to the reinforcing power supply wires 4 through the power supply ring 6, is supplied to devices in the logic circuit portion 2 via the basic power supply wires 3.

However, sufficient mitigation of the IR drop cannot be attained with the conventional power supply wiring described above due to the extended length of the wires and miniaturization of wires resulting from the rapid enlargement and integration of LSIs in recent years.

Furthermore, in parts of a logic circuit portion having relatively large power consumption, the current density of the power supply wires may locally exceed the tolerable current density. Since excessive current density causes the generation of electromigration, restriction violations in the current density reduce the reliability of the LSI.

### DISCLOSURE OF THE INVENTION

It is an object of the present invention to provide a semiconductor integrated circuit having improved stability and a method for wiring the power supply wiring of the same.

To achieve the above object, one aspect of the present invention is a semiconductor integrated circuit device including a circuit portion, a first power supply wire for supplying power to the circuit portion, and second power supply wires electrically connected to the first power supply wire. The semiconductor integrated circuit device includes at least one of width of each second power supply wire and an interval between the second power supply wires is set so as to mitigate voltage drop in the second power supply wires.

The semiconductor integrated circuit device of one embodiment includes a plurality of second power supply wires electrically connected to the first power supply wire so as to define a plurality of row regions or column regions in the circuit portion. An interval between the plurality of second power supply wires is non-uniform.

In one embodiment, the second power supply wires have different widths at a plurality of locations.

In one embodiment, a power supply trunk line extends from a power supply portion to an interior of the circuit portion to supply power to the second power supply wires.

In one embodiment, the plurality of power supply trunk lines are configured so as to have distal ends with substantially equal voltage drop values.

In one embodiment, the circuit portion includes a plurality of division regions in which the first power supply wire and the second power supply wires are arranged, each division region includes a plurality of electrically disconnected segment regions, and the power supply trunk line includes one basal portion and a plurality of distal portions respectively associated with the plurality of segment regions.

In one embodiment, the circuit portion includes a plurality of division regions in which the first power supply wire and the second power supply wires are arranged, the first power supply wire and the second power supply wires are arranged in each division region and electrically disconnected from other division regions, and the power supply trunk line includes one basal end and at least one distal end portion associated with at least one of the plurality of division regions.

In one embodiment, the second power supply wire includes a plurality of parallel wires divided into strips.

In one embodiment, the second power supply wire is one of a plurality of second power supply wires defining a plurality of row regions or column regions in the circuit, and the interval between the plurality of second power supply wires is non-uniform.

In one embodiment, the second power supply wire is one of a plurality of second power supply wires, and some of the plurality of second power supply wires include wire segments defining regions having polygonal shapes other than square shapes in the circuit portion.

In one embodiment, the second power supply wire is one of a plurality of second power supply wires, and further includes partial reinforcing wiring connected to two adjacent second power supply wires.

A semiconductor device of one embodiment includes a circuit portion, a first power supply wire for supplying power to the circuit portion, and a power supply trunk line including a basal end connected to a power supply portion and a plurality of distal portions connected to the first power supply wire. The power supply trunk line has a tree structure branching in steps between the power supply portion and the first power supply wire.

In one embodiment, the power supply trunk line has different widths at a plurality of locations.

In one embodiment, a switch device is arranged on the power supply trunk line for controlling the power supply from the power supply trunk line.

In one embodiment, the power supply trunk line includes a plurality of parallel wires divided into strips.

The present invention further provides a method for wiring a power supply of a semiconductor integrated circuit device including a circuit portion and a first power supply wire for supplying power to the circuit portion. The method includes the steps of providing second power supply wires electrically connected to the first power supply wire, and setting at least one of width of the second power supply wires and an interval of the second power supply wires to mitigate voltage drop in the second power supply wires.

In one embodiment, the step of setting includes dividing the second power supply wire in the longitudinal direction into at least one wire segment, calculating at least one of a provisional voltage drop and a provisional current density for each wire segment, and setting the width of each wire segment in accordance with the calculated value.

In one embodiment, the second power supply wire is one of a plurality of second power supply wires, and the step of setting includes provisionally laying out the plurality of second power supply wires so as to define a plurality of regions in the circuit portion, calculating a voltage drop value for each block, and setting an interval of the plurality of second power supply wires such that the total of voltage drop values of a plurality of blocks in each region is substantially equal between the plurality of regions.

In one embodiment, the second power supply wire is one of a plurality of second power supply wires defining a plurality of rectangular regions in the circuit portion. The step of setting includes calculating a voltage drop value for each of the rectangular regions, and moving a wire segment of a second power supply wire defining a rectangular region having a voltage drop value that is not tolerable such that the voltage drop values of the plurality of rectangular regions are in a tolerable range.

In one embodiment, the second power supply wire is one of a plurality of second power supply wires defining the circuit portion into a plurality of rectangular regions. The step of setting includes calculating a voltage drop value of each rectangular region, and adding a partial reinforcing wire to connect two second power supply wires associated with a rectangular region having a voltage drop value that exceeds the tolerable range so as to divide the rectangular region into two.

In one embodiment, the second power supply wire is one of a plurality of second power supply wires. The step of setting includes provisionally laying out a plurality of second power supply wires on the circuit portion to divide the circuit portion into a plurality of regions, dividing each region into a plurality of blocks, each having a predetermined minimum size, calculating a voltage drop value of each block, calculating a representative voltage drop value of the plurality of regions, comparing the representative voltage drop values of blocks in adjacent regions, provisionally laying out again the plurality of second power supply wires so that the representative voltage drop values in adjacent regions are substantially equal, obtaining distribution of the voltage drops in the circuit portion after provisionally laying out again the wires, determining whether or not a voltage drop that exceeds a predetermined upper limit is generated in the circuit portion, and when a voltage drop exceeding the upper limit is generated, repeating said calculating a voltage drop value, comparing the representative voltage drop values, and provisional laying out again the plurality of second power supply wires until the voltage drop becomes less than or equal to the upper limit.

In one embodiment, the second power supply wire is one of a plurality of second power supply wires. The step of setting includes obtaining voltage drop distribution of the circuit portion and storing a provisional voltage drop peak position at which a voltage drop peaks occur, provisionally laying out a plurality of second power supply wires such that at least one of the plurality of second power supply wires passes through the provisional voltage drop peak position, increasing width of the second power supply wire that passes through the provisional voltage drop peak position until the voltage drop value becomes less than or equal to a predetermined upper limit at the provisional voltage drop peak position, obtaining the voltage drop distribution of the circuit portion with the provisionally laid out plurality of second power supply wires, and determining whether or not a voltage drop exceeding the upper limit value is generated in the circuit portion, and when a voltage drop exceeding the upper limit is generated, repeating said storing the provisional voltage drop peak position, said provisionally laying out the plurality of second power supply wires, said increasing width of the second power supply wires, and determining the voltage drop until the voltage drop becomes less than or equal to the upper limit.

The method of one embodiment further includes arranging a provisional second power supply wire on the circuit portion, obtaining a provisional power drop distribution in the circuit portion in a state in which with the provisional second power supply wire is arranged, and storing a provisional voltage drop peak position, setting a main power piece in the circuit portion so as to include the provisional voltage drop peak position therein and substantially equalize power consumption thereof with a regulated value, obtaining the provisional voltage drop in the main power piece and storing the provisional voltage drop peak position in the main power piece under the assumption that the main power piece is electrically disconnected from other regions excluding the main power piece in the circuit portion, and arranging a power supply trunk line so as to connect a power supply portion to the vicinity of the provisional power drop peak position in the main power piece.

The method of one embodiment further includes arranging a provisional second power supply wire in the circuit portion, obtaining a provisional voltage drop distribution in the circuit portion in a state in which the provisional second power supply wire is arranged, and storing the provisional voltage drop peak position, setting a main power piece in the circuit portion so as to include the provisional voltage drop peak position therein and substantially equalize power consumption thereof with a regulated value, obtaining the provisional voltage drop in the main power piece and storing the provisional voltage drop peak position in the main power piece under the assumption that the main power piece is electrically disconnected from other regions excluding the main power piece in the circuit portion, laying out a main power supply trunk line so as to connect a power supply portion to the vicinity of the provisional power drop peak position in the main power piece, obtaining the provisional voltage drop distribution in the circuit portion in a state in which the main power supply trunk line is laid out, and storing the provisional voltage drop peak positions of the other regions, and laying out a secondary power supply trunk line so as to connect the power supply portion to the vicinity of the voltage drop peak position of the other regions.

In one embodiment, the main power piece is one of a plurality of main power pieces. The method includes when one main power piece partially overlaps at least one other main power piece, deleting a part including the overlapping region from the main power piece that has a long distance from the associated power supply portion to the overlapping region, moving the deleted part to a position that does not overlap another main power piece, and resetting the main power pieces to eliminate the overlapping region.

The present invention further provides a method for wiring a power supply of a semiconductor integrated circuit including a circuit portion and a plurality of power supply portions. The method includes the steps of dividing the circuit portion into a plurality of cluster regions, each of which includes at least one segment region, associating a plurality of cluster regions with a plurality of power supply nodes and provisionally connecting the segment regions of each cluster region to an associated power supply portion with a plurality of power supply trunk lines, and integrating the plurality of power supply trunk lines provisionally connected to each power supply portion into a single tree-like power supply trunk line having one basal portion connected to an associated power supply node, and a plurality of distal portions connected to a plurality of segment regions of an associated cluster region.

### BRIEF DESCRIPTION OF THE DRAWINGS

FIG. 1(a) is a plan view showing power supply wiring of an LSI according to a first embodiment of the present invention;

FIG. 1(b) is an enlarged view showing one power supply wire shown from FIG. 1(a);

FIG. 2(a) is a schematic diagram of the LSI;

FIG. 2(b) is an enlarged partial view of FIG. 2(a);

FIG. 3 is an enlarged partial view showing basic power supply wires;

FIG. 4 is a schematic diagram showing a process for changing the wire width to avoid IR drop;

FIG. 5 is a schematic diagram showing a process for changing the wire width to avoid excessive current density;

FIG. 6 is a table showing the relationship between the chip size and the IR drop value;

FIG. 7 is a plan view showing power supply wiring of an LSI according to a second embodiment of the present invention;

FIG. 8 is a schematic diagram showing an IR drop map;

FIGS. 9 and 10 are flowcharts of a power supply wiring method according to the second embodiment of the present invention;

FIGS. 11 through 13 are explanatory diagrams illustrating the wiring method of FIGS. 9 and 10;

FIG. 14 is a plan view showing power supply wiring of an LSI of a first modification of the second embodiment of the present invention;

FIG. 15 is a partial flowchart of the power supply wiring method of the first modification of the second embodiment of the present invention;

FIGS. 16 and 17 are explanatory diagrams illustrating the wiring method of the first modification of the second embodiment of the present invention;

FIG. 18 is a partial flowchart of a power supply wiring method of a second modification of the second embodiment of the present invention;

FIGS. 19 through 23 are explanatory diagrams illustrating the power supply wiring method of the second modification of the second embodiment of the present invention;

FIG. 23 is a partial flowchart of a power supply wiring method of a third modification of the second embodiment of the present invention;

FIGS. 24 through 28 are explanatory diagrams illustrating the power supply wiring method of the third modification of the second embodiment of the present invention;

FIG. 29 is a plan view showing the power supply wiring of an LSI of a fourth modification of the second embodiment of the present invention;

FIG. 30 is a flowchart showing part of the power supply wiring method of the modification of FIG. 29;

FIG. 31 is an explanatory diagram illustrating a wiring procedure of the reinforcing power supply wires (partial reinforcing wires);

FIG. 32 is a plan view showing power supply wires in an LSI of a third embodiment;

FIG. 33 is a flowchart of the power supply wiring method of the third embodiment;

FIG. 34 is a flowchart of the power supply wiring method of the same third embodiment;

FIG. 35 is a schematic diagram of an IR drop map;

FIGS. 36 through 38 are explanatory diagrams showing the wiring method of reinforcing power supply wires;

FIG. 39 is a plan view showing power supply wires in an LSI of a fourth embodiment;

FIGS. 40 and 41 are flowcharts of a power supply wiring method of the fourth embodiment;

FIG. 42 is a schematic diagram of an IR drop map;

FIGS. 43 through 48 are explanatory diagrams illustrating the wiring method of a power supply trunk line;

FIG. 49 is an explanatory diagram illustrating a process performed when main power pieces are overlapped;

FIG. 50 is a plan view showing power supply wires in an LSI according to a fifth embodiment of the present invention;

FIGS. 51 and 52 are flowcharts of a power supply wiring method of a fifth embodiment of the present invention;

FIG. 53 is a schematic diagram of an IR drop map;

FIGS. 54 through 63 are plan views showing the wiring procedures for a power supply trunk line;

FIG. 64 is a plan view showing power supply wires inside an LSI according to a sixth embodiment of the present invention;

FIGS. 65 and 66 are flowcharts of the power supply wiring method of the sixth embodiment;

FIGS. 67 through 70 are schematic diagrams illustrating the wiring procedure of a power supply trunk line;

FIGS. 71 and 72 are plan views showing power supply wires inside an LSI of a modification of the sixth embodiment;

FIGS. 73 and 74 are flowcharts of a power supply wiring method according to a seventh embodiment of the present invention;

FIGS. 75 through 80 are explanatory diagrams illustrating the wiring procedure of a power supply trunk line;

FIG. 81 is a plan view showing power supply wiring of an LSI according to an eighth embodiment of the present invention;

FIG. 82 is a schematic diagram showing the switch device of FIG. 81;

FIGS. 83 and 84 are flowcharts of a power supply wiring method for the eighth embodiment of the present invention;

FIG. 85 is a schematic diagram illustrating the structure of a switch device of a modification of the eighth embodiment of the present invention;

FIG. 86 is a plan view showing the power supply wiring inside an LSI using the switch device of the modification of the eighth embodiment of the present invention;

FIG. 87 is a plan view showing another example of the power supply trunk line of the present invention;

FIGS. 88 and 89 are plan views showing a variation of the power supply trunk line;

FIG. 90 is a block diagram showing an example of the layout of the switch device of the eighth embodiment of the present invention; and

FIG. 91 is a plan view showing the power supply wiring of a conventional LSI.

### BEST MODE FOR CARRYING OUT THE INVENTION

A semiconductor integrated circuit device (LSI) and a method for wiring the power supply of the same according to a first embodiment of the present invention will now be described with reference to the drawings.

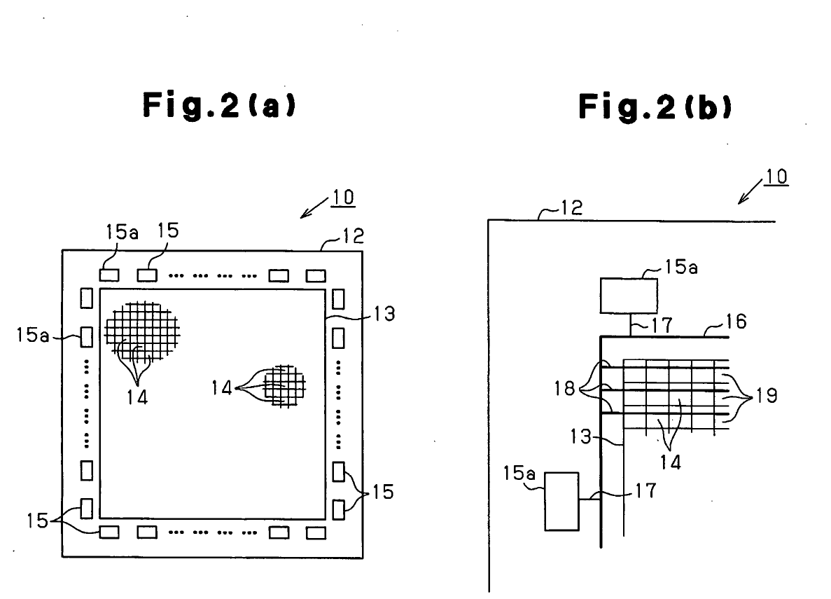

As shown in FIG. 2(a), an LSI 10 includes a square logic circuit portion 13 arranged on a circuit board 12. The logic circuit portion 13 is configured by a plurality of cells 14. A plurality of pads 15 are arranged along the periphery of the logic circuit portion 13 on the circuit board 12. Some of the pads 15 function as power supply pads (power supply portions, power supply points) for supplying power to the logic circuit portion 13. The power supply portions also may be located above and below the logic circuit portion 13.

As shown in FIG. 2(b), a ring-like power supply wiring, that is, a power supply ring 16, is arranged around the logic circuit portion 13. The power supply ring 16 is electrically connected to the power supply pads 15a via lead lines 17.

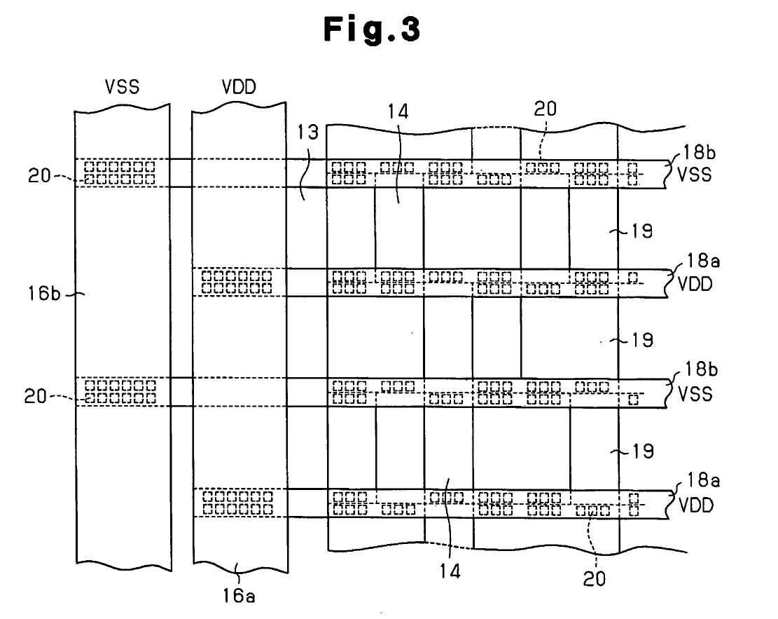

Specifically, as shown in FIG. 3, the power supply ring 16 is configured by a first ring wire 16a, which has potential VDD, and a second ring wire 16b, which has potential VSS. The first ring wire 16a or the second ring wire 16b is connected through connection holes 20, such as via holes and the like, to basic power supply wires 18 laid out on the logic circuit portion 13 to supply the logic circuit portion 13 with power.

The basic power supply wires 18 include basic power supply wires 18a connected to the first ring wire 16a and basic power supply wires 18b connected to the second ring wire 16b. The basic power supply wires 18a and 18b are alternately laid out in the lateral direction on the logic circuit portion 13. Cell arrays 19 are lined in the lateral direction between the basic power supply wires 18. Operation current supplied from the power supply pads 15a to the power supply ring 16 (16a and 16b) is further supplied to the cell arrays 19 by the basic power supply wires 18 (18a and 18b). Each cell array 19 includes cells 14 configured by, for example, inverter devices, or the like. When CAD data used to lay out the cells 14 includes data for the power supply wiring, each basic power supply wire 18 is configured by a power supply wire of a cell group, which is formed by a plurality of cells represented in the CAD data, and a power supply wire connecting the power supply wire of the cell group to the power supply ring 16.

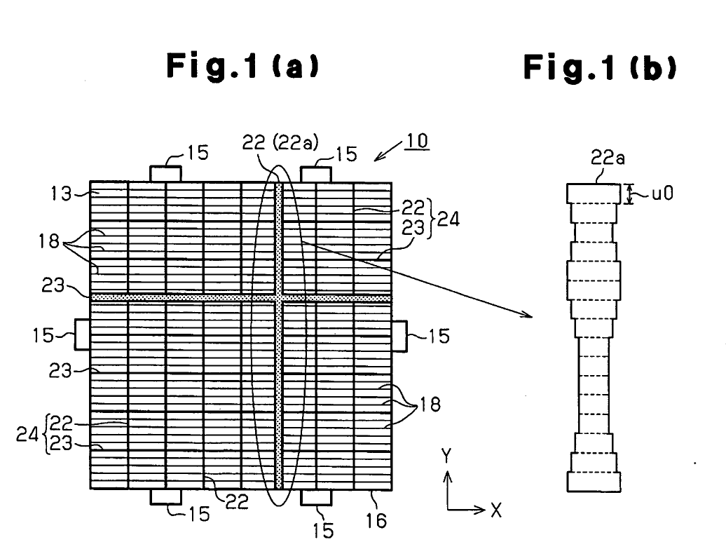

As shown in FIG. 1(a), a grid of a reinforcing power supply wire (power supply mesh) 24 for reinforcing the power supplied to the logic circuit portion 13 is arranged on the top layer of the basic power supply wires 18. The power supply mesh 24 is configured by vertical reinforcing power supply wires 22, which extend in the Y direction, and lateral reinforcing power supply wires 23, which extend in the X direction. The vertical reinforcing power supply wires 22 and lateral reinforcing power supply wires 23 are formed along a plurality of layers. The vertical reinforcing power supply wires 22 and lateral reinforcing power supply wires 23 are basically arranged at equal intervals (equal pitches).

The two ends of each vertical reinforcing power supply wire 22 and each lateral reinforcing power supply wire 23 are electrically connected to the power supply ring 16 through connection holes (not shown). The vertical reinforcing power supply wires 22 and the lateral reinforcing power supply wires 23 are electrically connected to the basic power supply wires 18 by connection holes (not shown) located at or near each intersection of the vertical reinforcing power supply wires 22 and the lateral reinforcing power supply wires 23 with the basic power supply wires 18.

Each of the vertical reinforcing power supply wires 22 and lateral reinforcing power supply wires 23 is formed by at least one of wire segments obtained in predetermined division units in the longitudinal direction. The width of each of the reinforcing power supply wires 22 and 23 is determined for each wire segment so as to mitigate at least one of IR drop (voltage drop) and excessive current density. For example, with regard to the vertical reinforcing power supply wires 22a shown in FIG. 1(a), the width of the vertical reinforcing power supply wires 22a is determined for each division unit u0 (half the grid size of the power supply mesh 24), as shown in FIG. 1(b). The wire width of each wire segment is also determined for the reinforcing power supply wires configuring the power supply mesh 24 in addition to the vertical reinforcing power supply wire 22a. The ratio of the width in the lateral direction and the dimension in the longitudinal direction of the vertical reinforcing power supply wire 22a shown in FIG. 1(b) is not the same as the actual ratio.

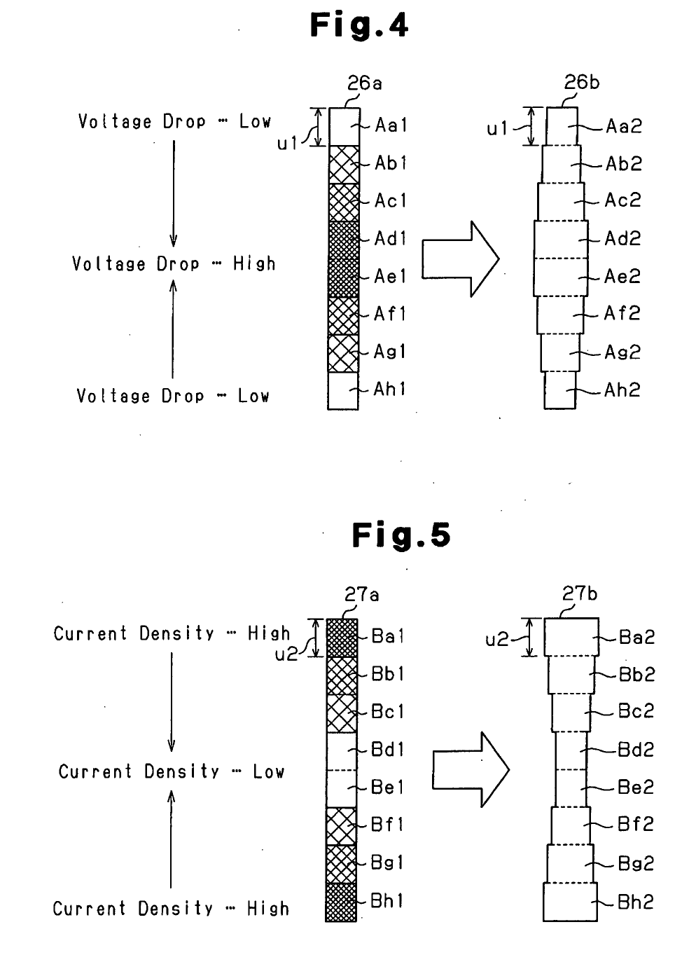

A process for setting the wire width of the reinforcing power supply wires will now be described with reference to FIGS. 4 and 5. FIG. 4 shows the relationship between the IR drop value and the wire width, and FIG. 5 shows the relationship between the current density and the wire width. The left side of FIGS. 4 and 5 shows the IR drop and current density of each wire section segment of the reinforcing power supply wires, and the right side schematically shows the width of the reinforcing power supply wire. The IR drop value refers to the IR drop value estimated when a reinforcing power supply wire that has a uniform width is provisionally laid out on the logic circuit before actually laying out the reinforcing power supply wire (provisional IR drop value). Furthermore, the current density is the current density estimated when a reinforcing power supply wire, which has a uniform width, is provisionally laid out on the logic circuit before actually laying out the reinforcing power supply wire.

The setting of the wire width corresponding to the provisional IR drop value will first be described.

As shown in FIG. 4, a reinforcing power supply wire 26a formed with a predetermined uniform width is divided into eight wire segments (Aa1 to Ah1) in division units u1 in the longitudinal direction. The division units, for example, may be set on the basis of the grid size of the power supply mesh and minimum cell size or in any wire length.

The width of the reinforcing power supply wire 26a changes at each segment Aa1 to Ah1 in accordance with the provisional IR drop value calculated for each segment Aa1 to Ah1. The reinforcing power supply wire 26b formed by the wire segments Aa2 to Ah2 of different widths is shown on the right side of FIG. 4.

That is, the provisional IR drop value of each segment Aa1 to Ah1 is calculated through an IR drop analysis. The IR drop value is calculated according to the relational equation of [IR drop value Vd=(current value I)×(sheet resistance Rs)×(wire length L)/(wire width W)]. The sheet resistance Rs is calculated by [(specific resistance ρ)/(wire film thickness d)], and is determined by the condition of the manufacturing process. The current value I is determined by performing electric power analysis. The wire width of each segment Aa1 to Ah1 changes based on the provisional IR drop value Vd calculated by the relational equation to determine the wire width of each segment Aa2 to Ah2 of the reinforcing power supply wire 26b. The wire width becomes greater as the provisional IR drop value becomes larger.

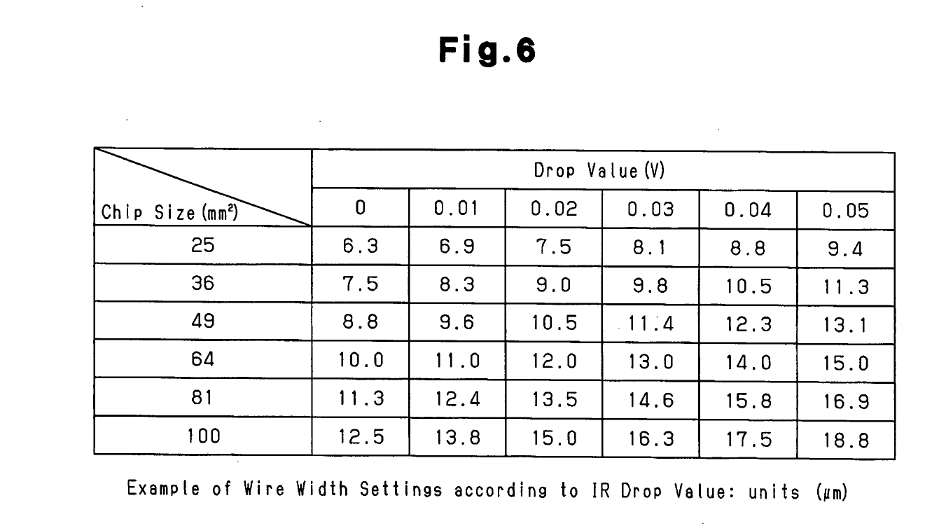

When it is difficult to increase the wire width due to a lack in wire resource, the increase in wire width of segment sections for which an increase in width is desired may be distributed to other wire sections (for example, an adjacent section). Further, the wire width may be changed based on a table of the chip size and IR drop values obtained through experience, as shown in FIG. 6.

In the case of the reinforcing power supply wire 26a, the provisional IR drop values are distributed so as to be lower at segments Aa1 and Ah1, which are located at the two ends of the wire, and higher at the segments Ad1 and Ae1, which are located at the middle of the wire. The wire width of the new reinforcing power supply wire 26b is set so as to be smaller at segments Aa2 and Ah2, which are located at the two ends of the wire, and larger at segments Ad2 and Ae2, which are located at the middle of the wire.

Setting the wire width in correspondence with the provisional current density will now be described.

When the wire width is set in correspondence with the provisional current density, the wire width of the reinforcing power supply wire 27a changes in accordance with provisional current density calculated for each segment Ba1 to Bh1 in division units u2 (grid size), as shown in FIG. 5. A reinforcing power supply wire 27b formed by the wire segments Ba1 to Bh2 which have different widths is shown on the right side of FIG. 5.

The current density J is calculated by [(current density I)/((wire film thickness d)×(wire width W))]. The wire width is determined such that the provisional current density is less than or equal to a tolerable current density, which satisfies a predetermined electromigration restriction. For example, the wire width is increased when the provisional current density exceeds the tolerable current density, and the wire width is decreased when the provisional current density has a capacity for the tolerable current density.

In the case of the reinforcing power supply wire 27a, the distribution of the provisional current density increases from the middle segments of the wire Bd1 and Be1 to the segments Ba1 and Bh1 at the two wire ends. The wire width of the new reinforcing power supply wire 27b is set such that the provisional current density of each segment Ba2 to Bh2 is less than the tolerable current density. Accordingly, the wire width of the new reinforcing power supply wire 27b is set so as to increase in width from the middle segments Bd2 and Be2 to the segments Ba2 and Bh2 at the two ends in accordance with the distribution of the provisional current density of the original reinforcing power supply wire 27a.

In the case of the reinforcing power supply wire 27a, the two wire end segments Ba1 and Bh1 that have the highest provisional current density are less than or equal to the tolerable current density. Thus, the reinforcing power supply wire 27b decreases from the segments Ba2 and Bh2, which have a margin in the provisional current density, to the middle segments Bd2 and Be2.

The power supply wiring method of the present embodiment will now be described with reference to the example of FIG. 1.

The power supply wiring of the LSI 10 shown in FIG. 1, that is, the vertical reinforcing power supply wire 22 and the lateral reinforcing power supply wire 23, are first arranged such that the wire width changes in accordance with the provisional IR drop value. Then, the wire width is changed in accordance with the provisional current density. The change in the wire width in accordance with the provisional IR drop value may follow the change in the wire width in accordance with the provisional current density, and the changes in the wire width may be repeated to obtain an optimum wire width. Furthermore, the wire width may be changed in accordance with either the provisional current density or the provisional IR drop value as long as the conditions of the provisional IR drop value and provisional current density are both satisfied.

When changing the wire width in accordance with the IR drop value, first, the size of the division unit u0 is set, and each power supply wire is divided into division units u0. The size of the division unit u0 of FIG. 1(b) is set at one half the grid size of the power supply mesh 24. The wire width is changed in accordance with the provisional IR drop value for each wire segment.

When changing the wire width in accordance with the provisional current density, the size of the division unit u0 is set, and each power supply wire is divided into division units u0. The division unit u0 is, for example, one half the grid size of the power supply mesh 24. The wire width is changed in accordance with the provisional current density for each wire segment. The change in the wire width is set for an optimum wire width while simultaneously checking the IR drop value.

The process of changing the wire width is executed by an information processor such as a computer or the like. Program data for the wiring design process is installed in the memory device of an information processor via a storage medium or communication medium. The information processor stores in a memory device the layout data of the LSI 10 generated by the execution of programs, and stores in a memory device the setting data and calculated data of the necessary upper limit IR drop value and tolerable current density and the like during processing.

The first embodiment has the advantages described below.

(1) A grid-like power supply mesh 24 is formed by vertical reinforcing power supply wires 22 and lateral reinforcing power supply wires 23 laid out along a plurality of wire layers on layers above the basic power supply wires 18, which supply power to the logic circuit portion 13. Each of the vertical reinforcing power supply wires 22 and lateral reinforcing power supply wires 23 are divided into predetermined division units in the longitudinal direction. The width of each wire segment is set so as to mitigate a provisional IR drop value and provisional current density in each wire segment.

Therefore, a wire with a wide width is arranged even in regions that have a relatively large provisional IR drop value and regions that have a relatively high provisional current density. This effectively mitigates the IR drop in the logic circuit and satisfies the electromigration restriction. Furthermore, an increase in the surface area of the power supply wiring is suppressed since a power supply wire having a narrow width is laid out in regions having a relatively small provisional IR drop value and regions having a relatively low provisional current density. As a result, the signal wire region is enlarged, and freedom of signal wiring layout is increased. Furthermore, the reinforcing power supply wires have a smooth shape with extremely small steps at the wire segments by setting the division units at a minimum, that is, by using a minimum design rule.

(2) Deficient operation due to IR drop may be prevented at an early design stage by determining the wire width based on a simulation performed through power analysis and IR drop analysis by employing an automatic wiring layout procedure.

A semiconductor integrated circuit device and a method for wiring a power supply of the same according to a second embodiment of the present invention will now be described with reference to the drawings. To facilitate description, like reference numerals are given to those components that are the same as the corresponding components of the first embodiment.

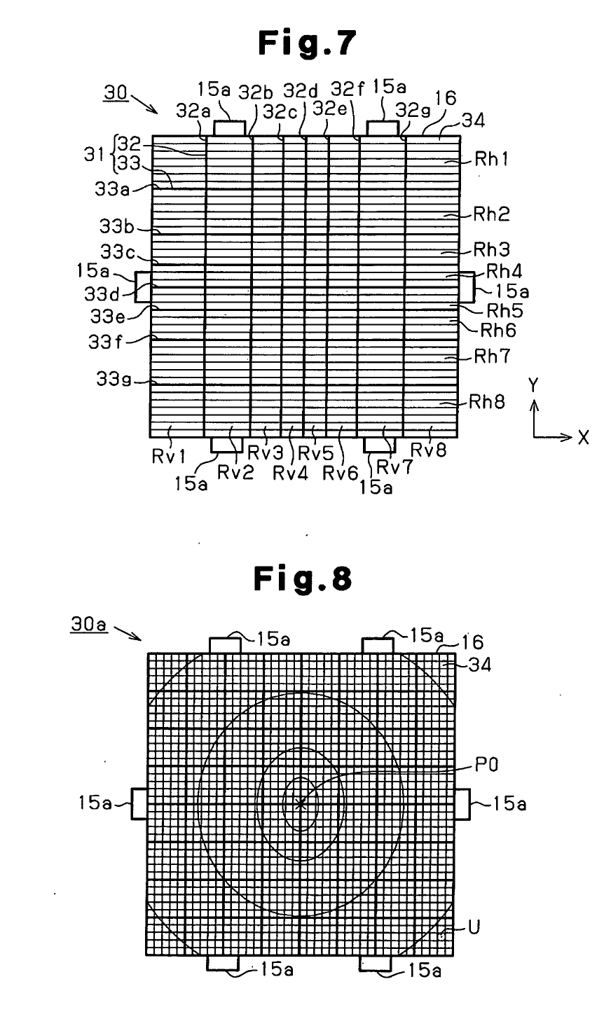

FIG. 7 is a plan view showing the power supply wiring of the LSI of the present embodiment, and FIG. 8 is a map (IR drop map) showing the distribution of provisional IR drop values.

In an LSI 30, which is shown in FIG. 7, vertical reinforcing power supply wires 32 and lateral reinforcing power supply wires 33 which form a reinforcing power supply wire (power supply mesh) 31 are respectively arranged at unequal intervals. Specifically, the interval between adjacent vertical reinforcing power supply wires 32 is set in accordance with the size of the provisional IR drop value. The interval between the adjacent lateral reinforcing power supply wires 33 is set in accordance with the size of the provisional IR drop value. The provisional IR drop value refers to the IR drop value estimated when the vertical reinforcing power supply wires 32 and lateral reinforcing power supply wires 33 are provisionally laid out at respectively uniform pitches before actually arranging the power supply mesh 31 on the logic circuit 34 (refer to FIG. 91). FIG. 8 shows an example of provisional IR drop value distribution of the LSI 30a before adjustment of the spacing intervals of the vertical reinforcing power supply wires 32 and lateral reinforcing power supply wires 33. In this example, the IR drop value maximum value position (peak position) P0 is near the middle of the logic circuit 34.

In the present embodiment, the interval of the vertical reinforcing power supply wires 32 and lateral reinforcing power supply wires 33 is adjusted so as to increase the wire density at positions near the peak position P0, that is, decrease the interval of adjacent wires at positions near the peak position P0 in the logic circuit 34. In this way, there are more vertical reinforcing power supply wires 32 and lateral reinforcing power supply wires 33 in regions that have a greater provisional IR drop value. This effectively mitigates the IR drop in the logic circuit 34.

If the logic circuit 34 is divided into square units having a predetermined minimum size (minimum block U), the vertical reinforcing power supply wires 32 are arranged such that the total provisional IR drop value determined for each minimum block U is substantially equal within adjacent regions on the logic circuit 34 defined by the vertical reinforcing power supply wires 32. Similarly, the lateral reinforcing power supply wires 33 are arranged such that the total provisional IR drop value determined in units of the minimum block U is substantially equal in adjacent regions on the logic circuit 34 defined by the lateral reinforcing power supply wires 33.

Specifically, the LSI 30 includes seven vertical reinforcing power supply wires 32a to 32g and seven lateral reinforcing power supply wires 33a to 33g, and the logic circuit 34 is divided into eight vertical regions (columns) Rv1 to Rv8 and lateral regions (rows) Rh1 to Rh8 by the seven vertical reinforcing power supply wires 32a to 32g and lateral reinforcing power supply wires 33a to 33g.

The vertical reinforcing power supply wires 32a to 32g are laid out such that the total provisional IR drop value in each minimum block U is equal in the vertical regions Rv1 to Rv8. Similarly, the lateral reinforcing power supply wires 33a to 33g are arranged such that the total provisional IR drop value of each minimum block U is equal in the vertical regions Rh1 to Rh8.

For example, the total provisional IR drop value of the minimum blocks U in the vertical region Rv5 defined by the vertical reinforcing power supply wires 32d and 32e, and the total provisional IR drop value of the minimum blocks U in the vertical region Rv6 defined by the vertical reinforcing power supply wires 32e and 32f are equal to each other. Similarly, the total provisional IR drop values of the minimum blocks U in lateral region Rh2, which is defined by the lateral reinforcing power supply wires 33a and 33b, and region Rh8, which is located at the periphery of the logic circuit 34 and defined by the lateral reinforcing power supply wire 33g, are equal to each other.

The power supply wiring method of the present embodiment will now be described.

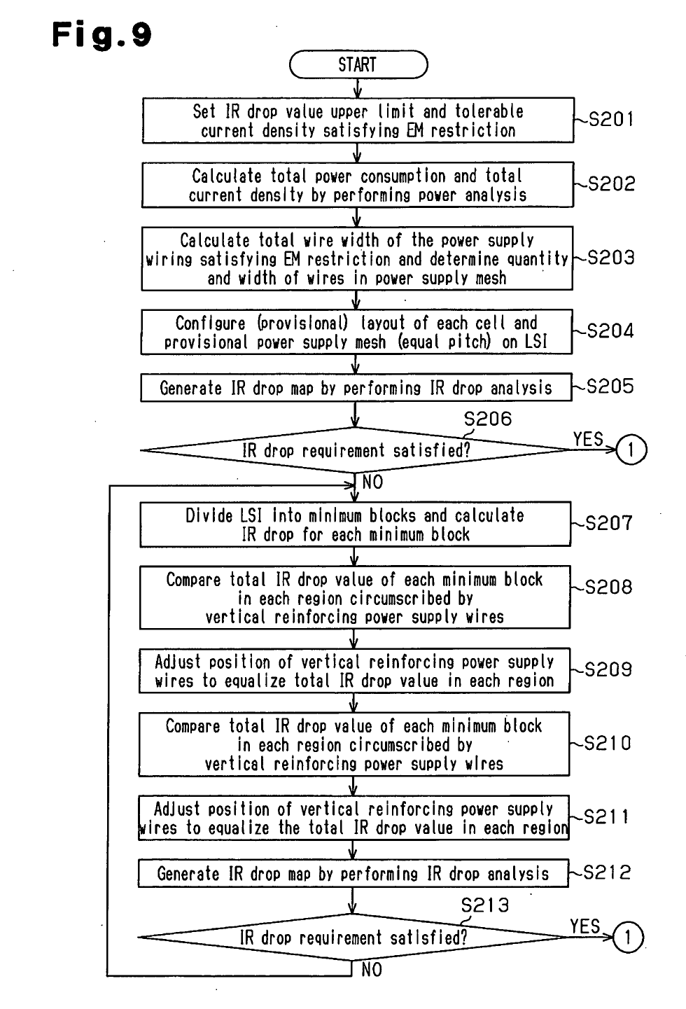

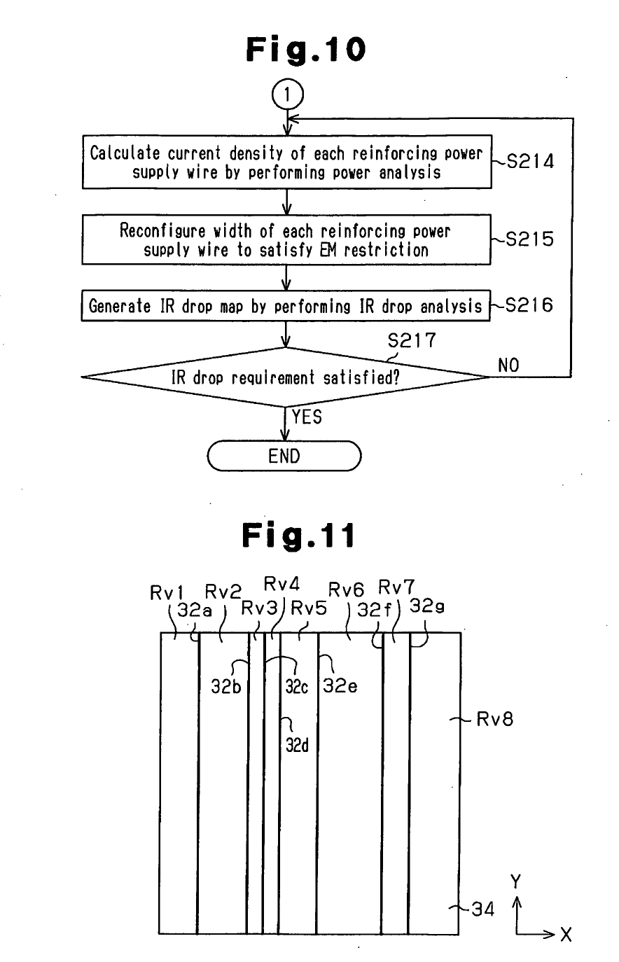

FIGS. 9 and 10 are flowcharts of a power supply wiring method, that is, the wiring design process of the present embodiment. This process is executed by an information processor such as a computer or the like. Program data for the wiring design process are installed in the memory device of an information processor through a storage medium or a communication medium. The information processor stores the layout data of the LSI 30 generated by the execution of programs in a memory device, and stores the setting data and calculated data of the necessary upper limit IR drop value and tolerable current density and the like during processing in a memory device.

In step S201, a tolerable current density of the wiring satisfying the tolerable IR drop value upper limit value and the electromigration restriction (EM restriction) are set, as shown in FIG. 9. Then, in step S202, the total power consumption and total current amount of the logic circuit 34 is calculated by power analysis.

In step S203, the total wire width of the power supply wiring which satisfies the EM restriction is calculated based on the tolerable current density set in step S201 and the total current amount calculated in step S202. The quantity and wire width of each vertical reinforcing power supply wire 32 and lateral reinforcing power supply wire 33 forming the power supply mesh 31 is determined.

In step S204, cells forming the logic circuit 34 are provisionally laid out, and a provisional power supply mesh is arranged on the logic circuit 34. The vertical and lateral reinforcing power supply wires forming the provisional power supply mesh (that is, the vertical reinforcing power supply wires 32a to 32g and the lateral reinforcing power supply wires 33a to 33g which configure the final power supply mesh 31) are provisionally laid out at uniform pitches as shown in FIG. 8.

In step S205, an IR drop analysis is performed in a state in which the provisional power supply mesh is provisionally laid out to generate the IR drop map shown in FIG. 8.

In step S206, based on the IR drop map (FIG. 8), a determination is made as whether or not the generated IR drop exceeds the upper limit value set in step S201, that is, whether or not the IR drop condition is satisfied. When the IR drop condition is satisfied (YES), the processes of step S214 and subsequent steps described later are executed.

When the IR drop condition is not satisfied (NO), the logic circuit 34 is divided into minimum blocks U, and a provisional drop value is calculated for each minimum block U in step S207. The IR drop value of the minimum block U is a representative value such as a maximum value, mean, or median of the IR drop values within the minimum block U, or the IR drop value at the center position of the minimum block U. In the present embodiment, the size of the minimum block U is in accordance with the minimum cell size but may be of any size.

In step S208, the total provisional IR drop value is calculated and compared for each minimum block U (refer to FIG. 8) in the vertical regions Rv1 to Rv8 defined by the vertical reinforcing power supply wires 32a to 32g, as shown in FIG. 11. In step S209, the wire positions of the vertical reinforcing power supply wires 32a to 32g are adjusted such that the total provisional IR drop value in each minimum block U is equal in the vertical regions Rv1 to Rv8.

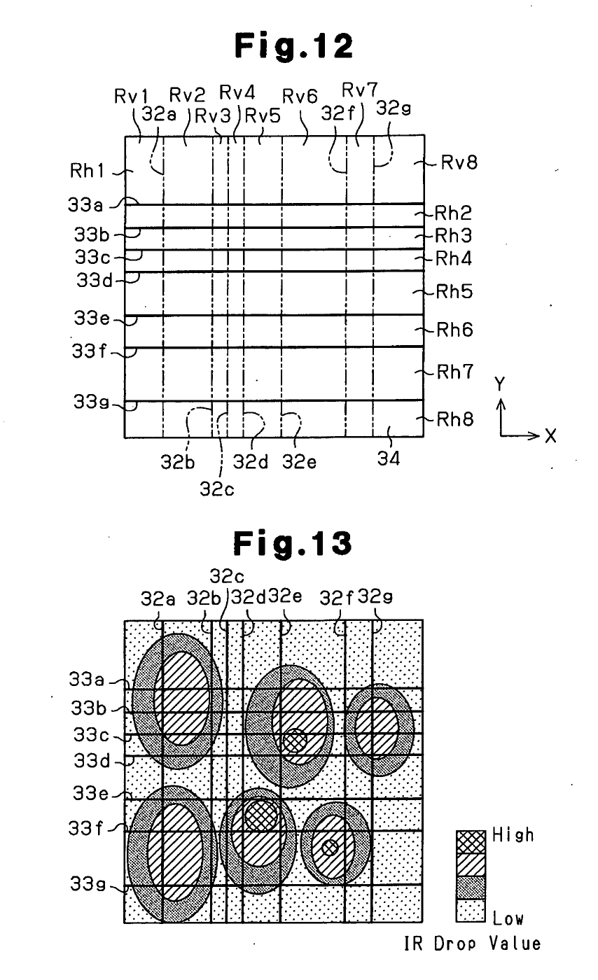

In step S210, the total provisional IR drop value is calculated for each minimum block U (refer to FIG. 8) in the lateral regions Rh1 to Rh8 defined by the lateral reinforcing power supply wires 33a to 33g, as shown in FIG. 12. In step S211, the position (wire spacing) of each lateral reinforcing power supply wire 33a to 33g is adjusted such that the total provisional IR drop value of each minimum block U is equal in the lateral regions Rh1 to Rh8.

The processes of steps S201 through S211 increase the density of the vertical reinforcing power supply wires 32 and lateral reinforcing power supply wires 33 in regions that have larger provisional IR drop values. Therefore, the power supply wiring surface area is substantially increased in regions that have larger provisional IR drop values to mitigate the IR drop. In the method of the present embodiment, when there is insufficient mitigation of the IR drop, the processes of steps S212 and S213 are executed.

In step S212, IR drop analysis is performed again in a state in which the positions of the vertical reinforcing power supply wires 32 and lateral reinforcing power supply wires 33 are adjusted. In step S213, a determination is made as to whether or not the IR drop condition is satisfied. When the IR drop condition is not satisfied in step S213 (NO), the processes of steps S207 through S212 are repeated until the IR drop condition is satisfied.

By repeatedly adjusting the wiring position of the vertical reinforcing power supply wires 32 and lateral reinforcing power supply wires 33 in this manner, the vertical reinforcing power supply wires 32 and lateral reinforcing power supply wires 33 may properly be corrected (readjusted) to positions producing the lowest IR drop in the logic circuit 34. In these repeated processes, the provisional IR drop value is re-determined for each minimum block U based on the IR drop map generated in step S212.

When the IR drop condition is satisfied (S213: YES), then in step S214, the current density (provisional current density) is calculated for the vertical reinforcing power supply wires 32a to 32g and lateral reinforcing power supply wires 33a to 33g by performing a power analysis. In step S215, the wire width of vertical reinforcing power supply wires 32a to 32g and lateral reinforcing power supply wires 33a to 33g are reconfigured so as to satisfy the EM restriction. In this state, the power supply wiring method of the first embodiment is used to divide the vertical reinforcing power supply wires 32a to 32g and lateral reinforcing power supply wires 33a to 33g into predetermined division units (having a length of the minimum block units U in the longitudinal direction) and change the wire width for each wire segment.

If there is a margin for the EM restriction when the wire width is reconfigured for the vertical reinforcing power supply wires 32 and lateral reinforcing power supply wires 33 in step S215, the wire width may be decreased to suppress consumption of wire resources of the power supply wiring. In such a case, a new IR drop is generated by decreasing the wire width. Thus, there is a possibility of an IR drop exceeding the upper limit being generated. In the present embodiment, an IR drop map is generated in step S216 by repeating the IR drop analysis for checking the reconfigured wire width. In step S217, a determination is made as to whether or not the IR drop condition is satisfied. When an IR drop exceeding the upper limit is generated (S217: NO), processing for satisfying the EM restriction is executed again (steps S214 to S216).

Accordingly, in addition to advantages (1) and (2) of the first embodiment, the second embodiment has the advantages described below.

(3) The vertical reinforcing power supply wires 32 and lateral reinforcing power supply wires 33 are laid out such that the total provisional IR drop value of the minimum blocks U within each region are equal in the mutual comparison of adjacent regions defined by the vertical reinforcing power supply wires 32 and in the mutual comparison of adjacent regions defined by lateral reinforcing power supply wires 33. This substantially increases the surface area of the power supply wiring per unit area of the logic circuit in regions that have a larger provisional IR drop value and thus effectively mitigates the IR drop before wiring the vertical reinforcing power supply wires 32 and lateral reinforcing power supply wires 33. As a result, stable operation of the semiconductor integrated circuit is ensured.

(4) After the provisional wiring of the power supply mesh 31 (vertical reinforcing power supply wires 32 and lateral reinforcing power supply wires 33), power analysis is performed to calculate the current densities of each vertical reinforcing power supply wire 32 and lateral reinforcing power supply wire 33, and the wire widths of the wires 32 and 33 are optimized to satisfy the EM restriction. This satisfies the electromigration restriction, suppresses increase in the surface area of the power supply wiring, and enables a semiconductor integrated circuit having highly reliability to be designed.

(5) Processing (processing repeating steps S207 through S213) for correcting (readjusting) the wiring positions of the vertical reinforcing power supply wires 32 and lateral reinforcing power supply wires 33 is performed. This further ensures mitigation of the IR in the logic circuit 34.

Modifications of the second embodiment will now be described.

(First Modification)

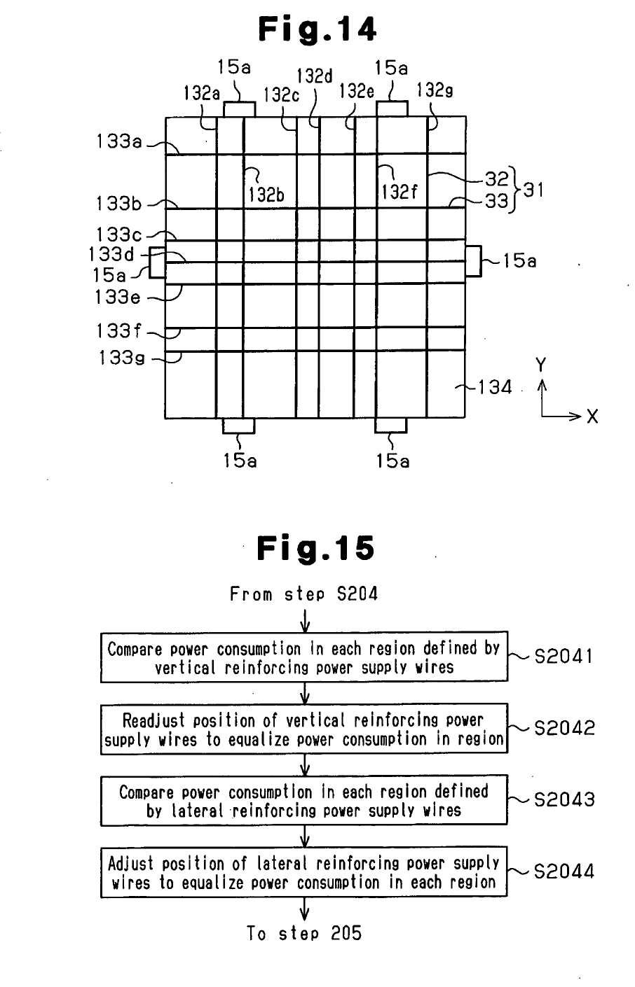

Although the reinforcing power supply wire (power supply mesh) is arranged in accordance with the magnitude of the provisional IR drop value in the second embodiment, a wiring arrangement shown in FIG. 14 may be alternatively used in the reinforcing power supply wire. That is, in this modification the vertical reinforcing power supply wires 32 are basically arranged to substantially equalize the amount of power consumption in adjacent regions defined by the vertical reinforcing power supply wires 32. Similarly, the lateral reinforcing power supply wires 33 are basically arranged to substantially equalize the amount of power consumption in adjacent regions defined by the lateral reinforcing power supply wires 33.

The power supply wiring method of this modification is described below. FIG. 15 is a flowchart showing some of the procedures executed by an information processor to lay out the power supply wiring in the present modification. As shown in FIG. 15, the processes of steps S2041 through S2044 are executed between steps S204 and S205 of FIG. 9 in this modification.

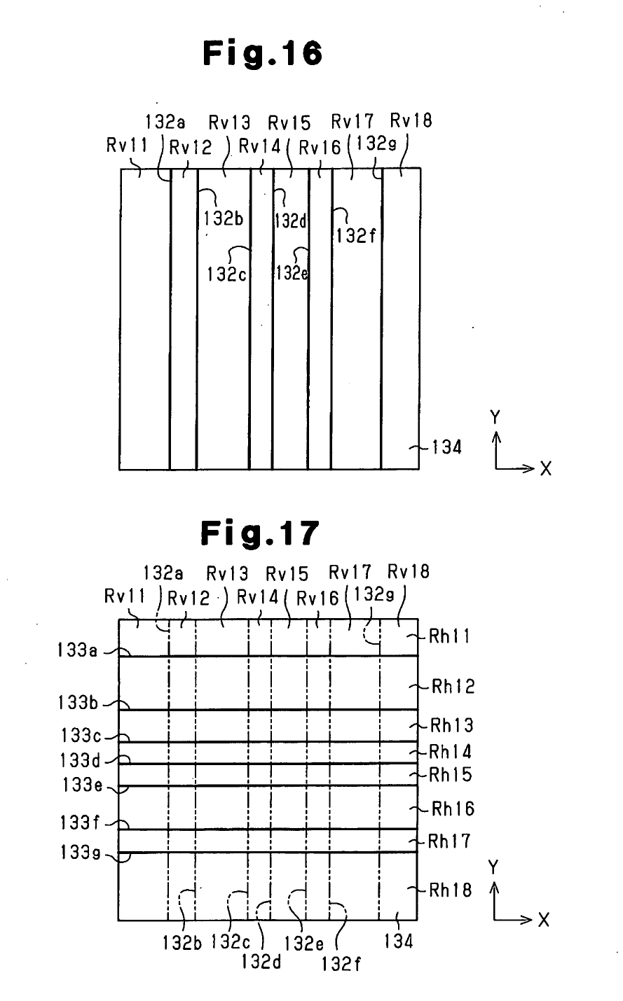

In step S2041, the amount of power consumption is calculated and compared in the vertical regions Rv11 to Rv18 defined by the vertical reinforcing power supply wires 132a to 132g, as shown in FIG. 16. In step S2042, the wiring positions of the vertical reinforcing power supply wires 132a to 132g are adjusted such that the amount of power consumption is equal in the vertical regions Rv11 to Rv18.

In step S2043, the amount of power consumption is calculated and compared in the lateral regions Rh11 to Rh18 defined by the lateral reinforcing power supply wires 133a to 133g, as shown in FIG. 17. In step S2044, the wiring positions of the lateral reinforcing power supply wires 133a to 133g are adjusted such that the amount of power consumption is mutually equal in the lateral regions Rh11 to Rh18.

According to this wiring method (steps S2041 through S2044), the vertical reinforcing power supply wires 132 and lateral reinforcing power supply wires 133 tend to be more densely arranged in regions that have higher provisional IR drop values. Therefore, in this wiring method, the power supply wiring surface area is also substantially increased in regions that have larger provisional IR drop values to mitigate the IR drop.

However, the IR drop is not sufficiently mitigated using only such a power supply wiring method (power supply wiring mode). Therefore, in this modification IR, drop analysis is again performed in step S205 with the adjusted vertical reinforcing power supply wires 132a to 132g and lateral reinforcing power supply wires 133a to 133g, and then a determination is made as to whether or not the IR drop condition is satisfied in step S213. When an IR drop exceeding the upper limit is generated in step S206, then the processes of steps S207 through S213 are repeatedly executed until the IR drop condition is satisfied (correction process of the wiring positions of the vertical reinforcing power supply wires 132 and lateral reinforcing power supply wires 133).

The first modification has advantages (1) to (5) of the first and second embodiments.

(Second Modification)

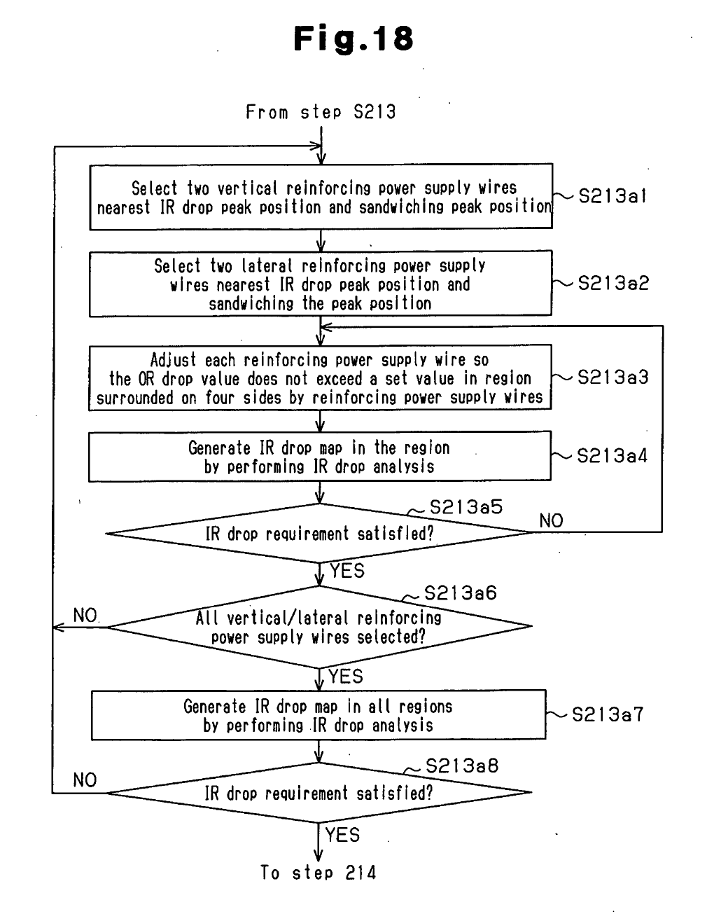

Any method for correcting the wiring positions of the vertical reinforcing power supply wires and lateral reinforcing power supply wires may be performed. For example, the processes of steps S213a1 through S213a8 shown in FIG. 18 may be substituted for the repeated processes (steps S207 to S213) in the second embodiment.

That is, when an IR drop exceeding the upper limit is generated in the first step S213 (S213: NO), the process of step S213a1 is performed rather than returning to step S207. In step S213a1, the vertical reinforcing power supply wires nearest the provisional IR drop peak position P on the IR drop map, that is, two (one set of) vertical reinforcing power supply wires 232 sandwiching the peak position therebetween, are selected. When there are a plurality of provisional IR drop peak positions, for example, the process selects the peak position that has the largest provisional IR drop value.

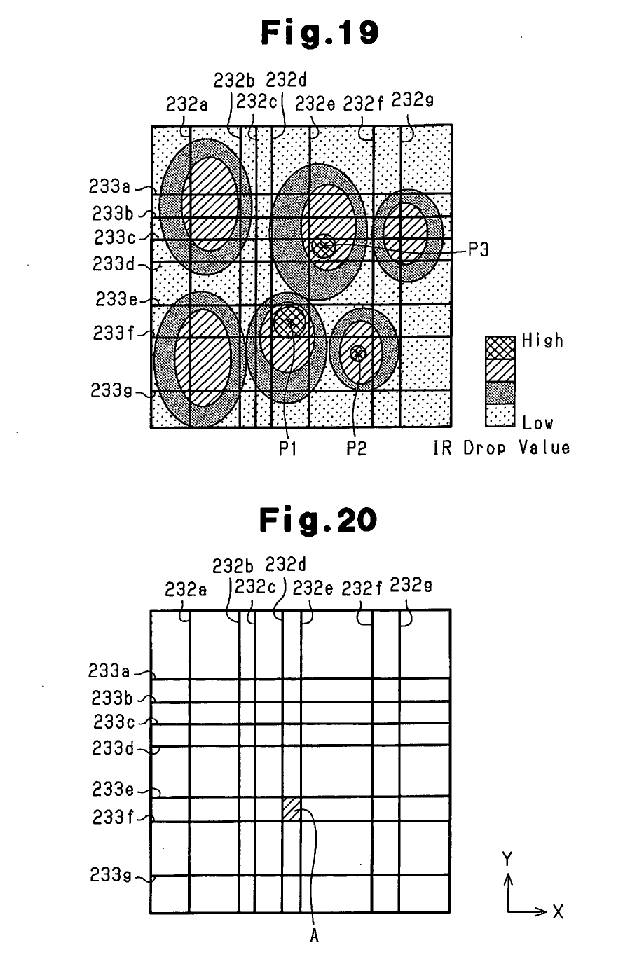

Specifically, as shown in FIG. 19, when three peak positions P1 to P3 appear on the IR drop map, the peak position P1, which has the largest IR drop value, is selected. Then, the vertical reinforcing power supply wires nearest to the peak position P1, that is, vertical reinforcing power supply wires 232d and 232e on opposite sides of the peak position P1, are selected. In step S213a2, the lateral reinforcing power supply wires nearest the target peak position P1, that is, lateral reinforcing power supply wires 233e and 233f on opposite sides of the peak position P1, are selected.

When the four reinforcing power supply wires 232d, 232e, 233e, and 233f are selected in this way, then in step S213a3, the wiring positions are corrected (adjusted) for these reinforcing power supply wires 232d, 232e, and 233e and 233f in directions that narrow region A, which is circumscribed by the selected reinforcing power supply wires 232d, 232e, 233e, and 233f, as shown in FIG. 20. Then, in step S213a4, IR drop analysis is performed with the corrected (adjusted) reinforcing power supply wires 232d, 232e, 233e, and 233f. In step S213a5, a determination is made as to whether or not the total of the provisional IR drop value determined for each minimum block U (refer to FIG. 8) in region A satisfies the IR drop condition in this state. The processes of steps S213a3 and S213a4 are repeatedly executed until the IR drop condition is satisfied (step S213a5: YES). When the IR drop condition is satisfied (step S213a5: YES), then the process of step S213a6 is executed.

In step S213a6, a determination is made as to whether or not all vertical reinforcing power supply wires 232 and lateral reinforcing power supply wires 233 have been selected. The processes of steps S213a1 through S213a5 are repeated until it is determined that all vertical reinforcing power supply wires 232 and lateral reinforcing power supply wires 233 (reinforcing power supply wires 231) have been selected.

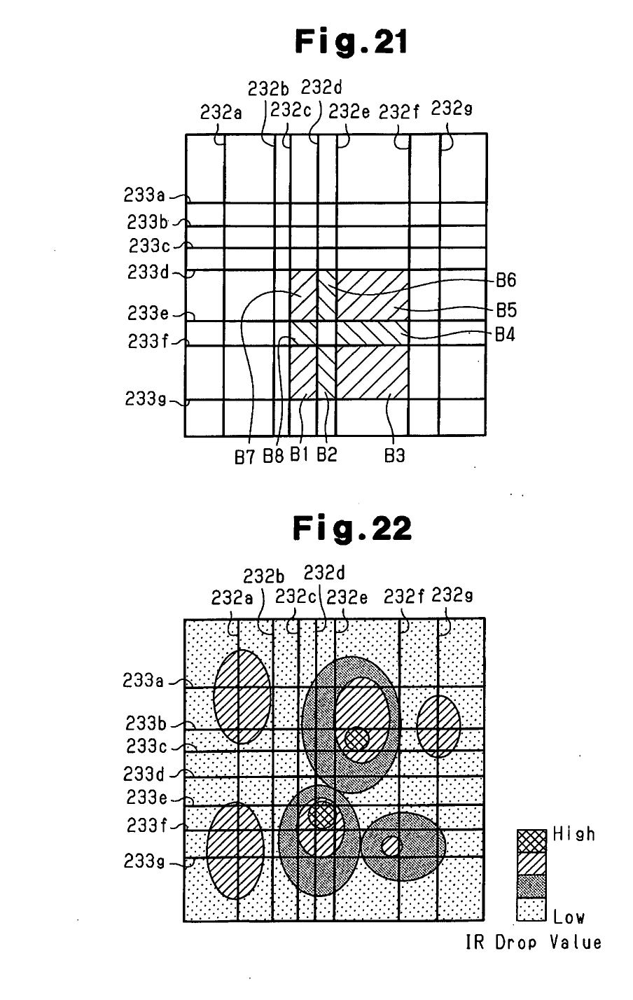

When steps S213a1 through S213a5 are repeated, the peak position P used in the processes of steps S213a1 and S213a2 is the peak position P1 used in the previous process of step S213a1, and is not changed to another peak position P. Furthermore, the once-selected vertical reinforcing power supply wires 232d and 232e and lateral reinforcing power supply wires 233e and 233f are not selected again. Therefore, the vertical reinforcing power supply wires 232c and 232f are selected in step S213a1, and the lateral reinforcing power supply wires 233d and 233g are selected in step S213a2, as shown in FIG. 21. In step S213a3, the wire positions of the reinforcing power supply wires 232b, 232f, 233d, and 233g are each corrected (adjusted) to narrow regions B1 to B8. When the regions B1 to B8 already satisfy the IR drop condition, step S213a3 may be skipped and the routine may advance to the process of step S213a4.

Furthermore, when the repeated processes are executed and only one vertical reinforcing power supply wire 232 or lateral reinforcing power supply wire 233 can be selected in steps S213a1 and S213a2, then only that one wire is selected. In this case, in subsequent step S213a3, the wire position of the selected reinforcing power supply wire is corrected (adjusted) to narrow the region circumscribed by the selected reinforcing power supply wire and the power supply ring. When no reinforcing power supply wire can be selected in steps S213a1 and 213a2, then no wire is selected.

When all vertical reinforcing power supply wires 232 and lateral reinforcing power supply wires 233 have been selected in the process of the final step S213a6, the process of step S213a7 is executed.

In step S213a7, IR drop analysis is again performed with corrected (adjusted) vertical reinforcing power supply wires 232a to 232g and lateral reinforcing power supply wires 233a to 233g, as shown in FIG. 22. In step S213a8, a determination is made as to whether or not the IR drop condition is satisfied. Then, in the process of step S213a8, the processes of steps S213a1 through S213a7 are repeatedly executed until an IR drop that does not exceed the upper limit value is generated. When the IR drop condition is satisfied, the processes of steps S214 through S217 are executed to satisfy the EM restriction.

By performing the processes of steps S213a1 through S213a8, in the regions defined by the vertical reinforcing power supply wires 232 and lateral reinforcing power supply wires 233 (reinforcing power supply wires 231), the wire interval of the reinforcing power supply wires 231 is sequentially corrected (adjusted) from the region of the peak position P of the provisional IR drop toward the periphery. In this way the IR drop is more reliably mitigated than in the previously described power supply wiring method (steps S201 to S213).

The second modification has the same advantages as advantages (1) to (5) of the first and second embodiments.

(Third Modification)

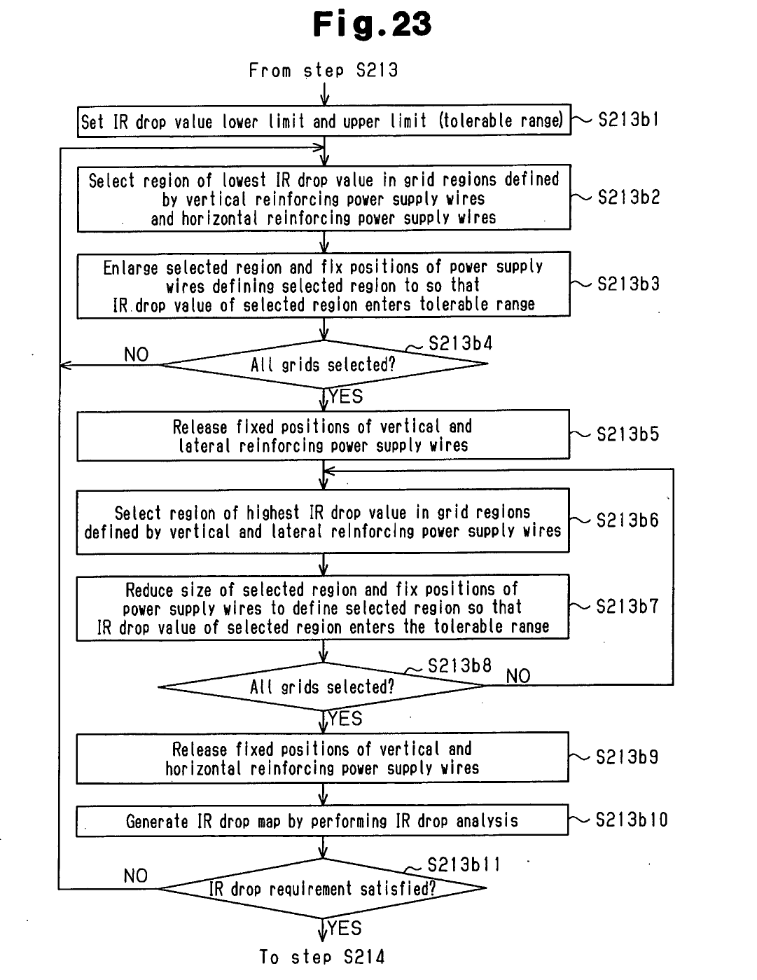

The processes of steps S213b1 through S213b11 shown in FIG. 23 may be substituted for the repeated processes (steps S207 to S213) of the second embodiment as the process for correcting the wiring position of the vertical reinforcing power supply wires and lateral reinforcing power supply wires.

More specifically, when an IR drop exceeding the upper limit is generated in the first step S213 (S213: NO), the process of step S213b1 is performed rather than returning to step S207.

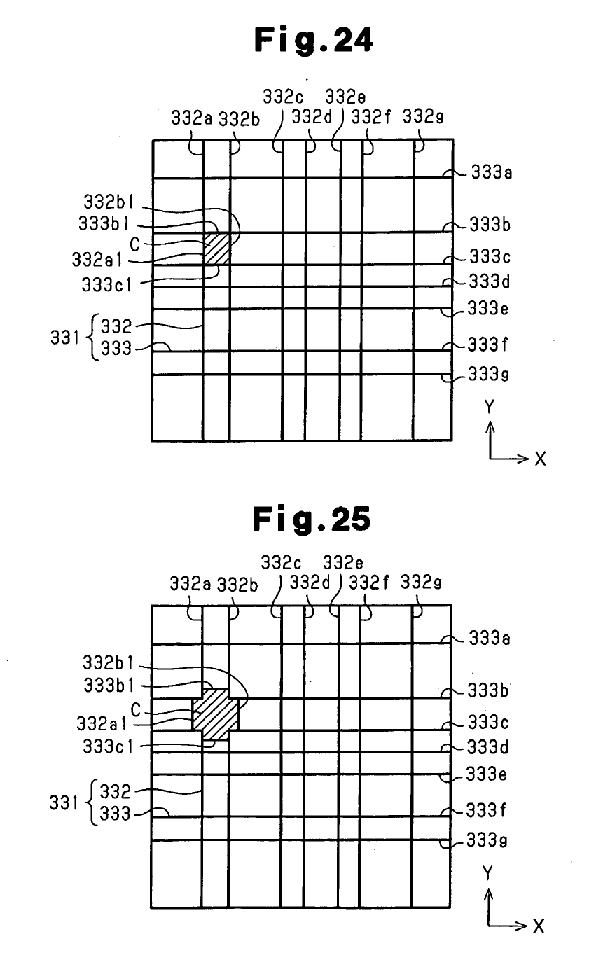

In the process of step S213b1, a lower limit value and upper limit value for the IR drop value (tolerable range) are set. In step S213b2, region C which has the lowest provisional IR drop value is selected from among the grid regions defined by the vertical reinforcing power supply wires 332 and lateral reinforcing power supply wires 333 (reinforcing power supply wires 331), as shown in FIG. 24. The provisional IR drop value of the grid region is the total of the provisional IR drop value of each minimum block U (refer to FIG. 8) in the grid region.

In step S213b3, the provisional IR drop value of the selected region C is compared with the lower limit value. When the provisional IR drop value of region C is less than the lower limit value, region C is enlarged. Specifically, among the vertical reinforcing power supply wires 332a and 332b and the lateral reinforcing power supply wires 333b and 333c that define region C, the positions of wire segments 332a1, 332b1, 333b1, and 333c defining region C are corrected so as to enlarge the region C, as shown in FIG. 25. When the provisional IR drop value of region C becomes greater than the lower limit value and enter the allowable range, the position of the adjusted wire segments (wire segments defining region C) are fixed, and the process of step S213b4 is executed. If the provisional IR drop value of the selected region C is within the allowable range from the beginning, then the process of step S213b4 is executed without enlarging the region C. In any case, the positions of the wire segments defining the selected region C are fixed in the process of step S213b3. In the example shown in FIG. 25, region C is changed from a square to a cross-like shape (a polyhedron other than a square) by moving the wire segments 332a1, 332b1, 333b1, and 333c1.

In step S213b4, a determination is made as to whether or not all grid regions defined by the vertical reinforcing power supply wires 332 and lateral reinforcing power supply wires 333 have been selected. The processes of steps S213b2 and S213b3 are repeated until all grid regions have been selected in step S213b4. When the processes of steps S213b2 and S213b3 are repeated, the grid regions defined by the wire segments of which positions are fixed are not selected again.

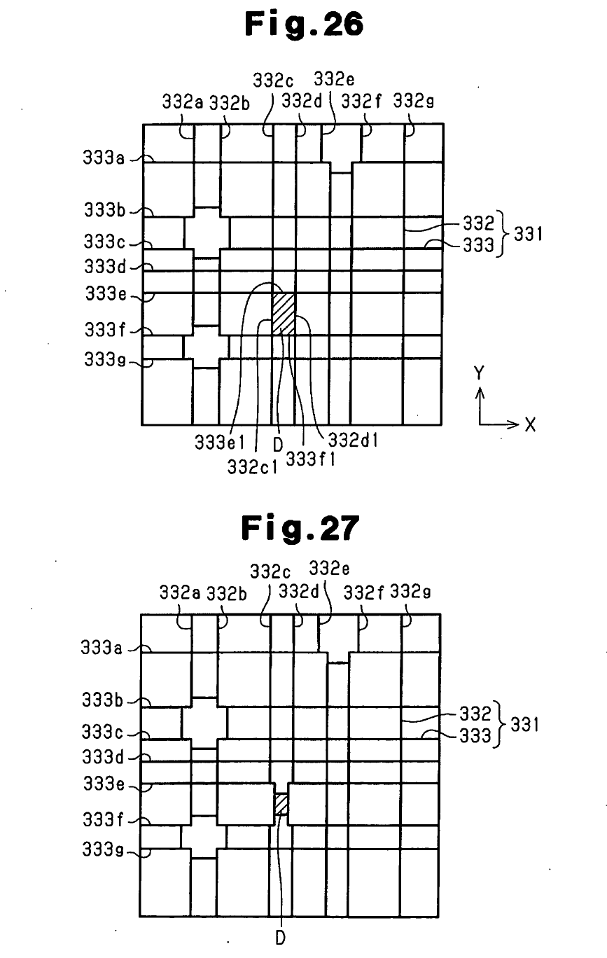

When it is determined in step S213b4 that all grid regions have been selected, then the process of step S213b5 is executed. In step S213b5, the fixed wire positions of the vertical reinforcing power supply wires 332 and lateral reinforcing power supply wires 333 are released. In step S213b6, region D which has the highest provisional IR drop value is selected from among the grid regions defined by the vertical reinforcing power supply wires 332 and lateral reinforcing power supply wires 333 (reinforcing power supply wires 331), as shown in FIG. 26.

In step S213b7, the provisional IR drop value of the selected region D is compared with the upper limit value. When it is determined that the provisional IR drop value of region D exceeds the upper limit value, the size of region D is reduced. Specifically, among the vertical reinforcing power supply wires 332c and 332d and the lateral reinforcing power supply wires 333e and 333f defining the region D, the positions of the wire segments 332c1, 332d1, 333e1, and 333f defining region D are corrected so as to reduce the size of region D, as shown in FIG. 27.

An example of the processing sequence for reducing the size of region D is described below.

When the provisional IR drop value in region D exceeds the upper limit value, the wire segments 333e1 and 333f1 defining region D are first selected from among the lateral reinforcing power supply wires 333e and 333f. The positions of the selected wire segments 333e1 and 333f1 are corrected (adjusted) in directions which reduce the distance between the selected wire segments 333e1 and 333f1. When the provisional IR drop value of region D becomes less than the upper limit value and enters the tolerable range, the process of reducing the size of the region D ends.

When the provisional IR drop value of the region D does not exceed the upper limit value even though the distance between the selected wire segments 333e1 and 333f1 is the preset minimum wire interval, the positions of the vertical reinforcing power supply wires 332c and 332d are corrected (adjusted). That is, the wire segments 332c1 and 332d1 defining region D are selected from among the vertical reinforcing power supply wires 332c and 332d. The positions of the selected wire segments 332c1 and 332d1 are corrected (adjusted) in directions which reduce the distance between the selected wire segments 332c1 and 332d1. When the IR drop value of region D becomes less than or equal to the upper limit value and enters the allowable range, the process of reducing the size of region D ends. In the example of FIG. 27, the shape of the regions adjacent to region D are changed from a square to a T-shape (polyhedron other than a square) by moving the wire segments 332c1, 332d1, 333e1, and 333f1.

The wiring position correction (adjustment) of any of the vertical reinforcing power supply wires 332 and lateral reinforcing power supply wires 333 may be started while performing the process of reducing the size of a region. Furthermore, when the process of reducing the region D ends in the process of step S213b7, the positions of the wires defining region D are fixed. That is, if the IR drop value of the region D is within the allowable range from the beginning in step S213b7, then the positions of the wire segments defining region D are fixed without performing the process for reducing the size of region D, and the process of subsequent step S213b8 is executed.

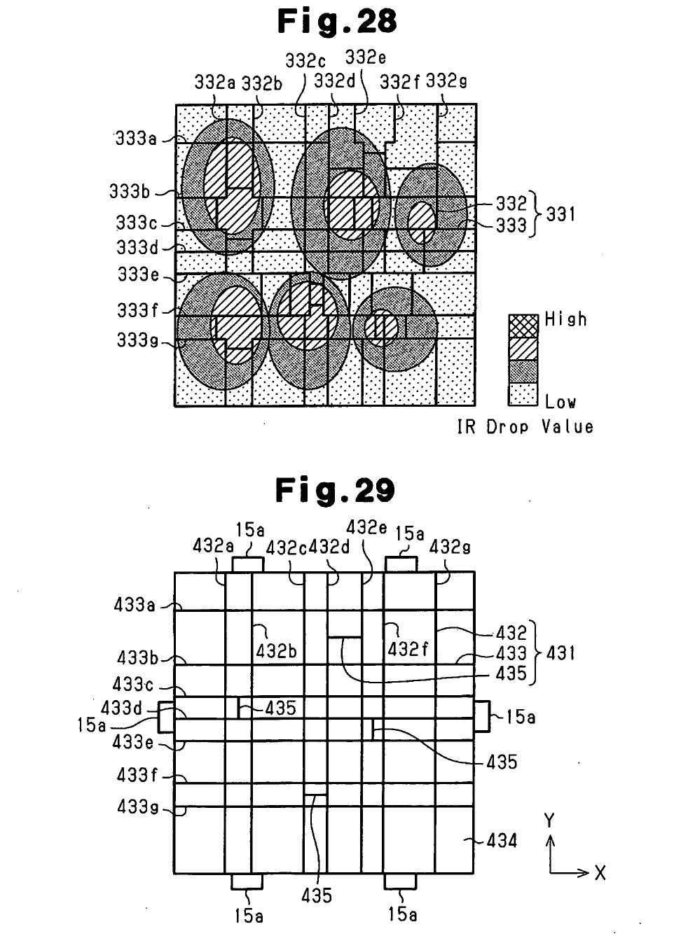

In step S213b8, a determination is made as to whether or not all grid regions defined by the vertical reinforcing power supply wires 332 and lateral reinforcing power supply wires 333 have been selected. The processes of steps S213b6 and S213b7 are repeated until all grid regions are selected (step S213b8: YES). When the processes of steps S213b6 and S213b7 are repeated, the grid regions defined by the fixed wire positions are not selected again. When all grid regions have been selected, all of the vertical reinforcing power supply wires 332 and lateral reinforcing power supply wires 333 are released from the fixed positions in step S213b9. In step S213b10, an IR drop analysis is performed with the corrected (adjusted) vertical reinforcing power supply wires 332a to 332g and lateral reinforcing power supply wires 333a to 333g, as shown in FIG. 28. In step S213a11, a determination is made as to whether or not the IR drop condition is satisfied. The processes of steps S213b2 through S213b10 are repeated until an IR drop which does not exceed the upper limit is generated. When an IR drop that does not exceed the upper limit is generated (step S213b11: YES), the processes of steps S214 to S217 are executed to satisfy the EM restriction.

According to this power supply wiring method (steps S213b1 through S213b11), the positions of the vertical reinforcing power supply wires 332 and lateral reinforcing power supply wires 333 are corrected (adjusted) only for those regions which do not satisfy the IR drop condition among the grid regions defined by the vertical reinforcing power supply wires 332 and lateral reinforcing power supply wires 333. Therefore, the IR drop of the logic circuit 34 is efficiently and reliably mitigated.

The third modification has the same advantages as advantages (1) to (5) of the first and second embodiments.

The processing order of steps S213b2 to S213b4 and the processes of steps S213b6 to S213b8 may be changed.

(Fourth Modification)

A process for correcting (adjusting) the positions of the vertical reinforcing power supply wires and lateral reinforcing power supply wires (steps S207 to S213) is performed in the second embodiment. However, this correction process may be omitted. In this case, it is desirable that mitigation of the IR drop be further ensured using the wiring mode shown in FIG. 29.

In the fourth modification, as shown in FIG. 29, a reinforcing power supply wires 431 is arranged on a logic circuit 434. The reinforcing power supply wires 431 includes vertical reinforcing power supply wires 432, lateral reinforcing power supply wires 433, and partial reinforcing power supply wires 435, which reinforce certain parts of the logic circuit 434. The partial reinforcing power supply wires 435 are connected to two adjacent vertical reinforcing power supply wires 432 or two adjacent lateral reinforcing power supply wires 433. The partial reinforcing power supply wires 435 suppress consumption of the power supply wiring resource, and easily and accurately mitigate the IR drop.

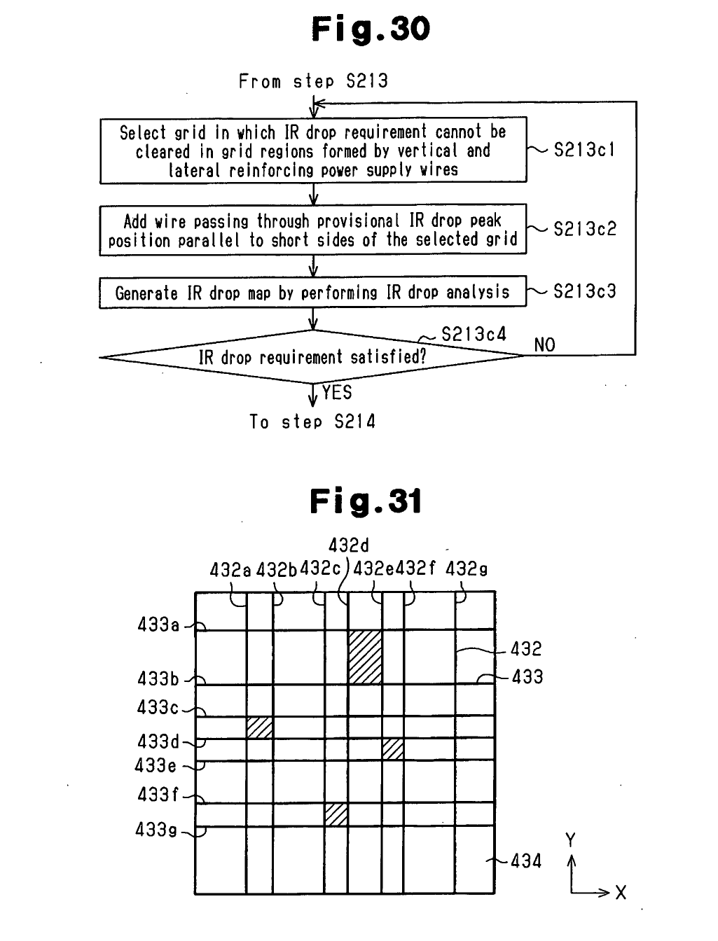

The power supply wiring method of the fourth modification is described below. FIG. 30 is a flowchart showing some of the procedures executed by an information processor to lay out the power supply wiring in the present modification.

When an IR drop exceeding the upper limit is generated (step S213: NO), the processes of steps S213c1 to S213c4 shown in FIG. 30 are executed to further add the partial reinforcing power supply wires 435, which reinforce certain parts of the logic circuit 434.

In step 213c1, referring to FIG. 31, the regions which do not satisfy the IR drop condition (regions indicated by the diagonal lines in FIG. 31) is selected from the grid regions defined by the vertical reinforcing power supply wires 432 and lateral reinforcing power supply wires 433. In step S213c2, partial reinforcing power supply wires 435 are added to each selected grid region so as to divide the selected grid region into two parts. Specifically, a partial reinforcing power supply wire 435 is added so that among the four sides defining the selected grid region, the partial reinforcing wire 435 is parallel to the short sides and extends through the provisional IR drop peak position P in that grid region.

In step S213c3, IR drop analysis is performed in a state in which the partial reinforcing power supply wires 435 are laid out. In step S213c4, a determination is made as to whether or not the IR drop condition is satisfied in all grid regions. Then, in step S213c4, the processes of steps S213c1 to S213c3 are repeated until the IR drop condition is satisfied for all grid regions. When the IR drop condition is satisfied for all regions (step S213c4: YES), the processes of step S214 and subsequent steps are executed to satisfy the EM restriction.

According to this power supply wiring method (steps S213c1 through S213c4), among the grid regions defined by the vertical reinforcing power supply wires 432 and lateral reinforcing power supply wires 433, new partial reinforcing power supply wires 435 are added to regions in which the IR drop condition is not satisfied. Accordingly, in cooperation with the previously described power supply wiring method (steps S201 to S213), the consumption of power supply wiring resources is suppressed, and an IR drop is easily and more accurately mitigated.

When regions that do not satisfy the IR drop condition are rectangles which have short sides and long sides such as the rectangular regions defined by the reinforcing power supply wires 432d, 432e, 433a, and 433b in FIG. 31, it is desirable that a partial reinforcing power supply wire 435 be added so that it is parallel to the short sides. In this case, the IR drop is effectively mitigated by adding a minimum wire resource.

Furthermore, when there is information relating to the circumstances of usage of wiring resources in the design of the LSI, the partial reinforcing power supply wires 435 may be added in accordance with the circumstances of usage of the wiring resources. For example, when much wiring resources are used in the X direction but there is surplus wiring resources in the Y direction, the partial reinforcing power supply wires 435 may be added so that that they are parallel to the Y direction.

In addition to advantages (1) to (5) of the first and second embodiments, the fourth modification has the advantage described below.

(6) Partial reinforcing power supply wires 435 are ultimately added to grid regions that do not satisfy the IR drop condition. This suppresses consumption of the power supply wiring resource and easily and accurately mitigates the IR drop.

A semiconductor integrated circuit device and a method for wiring a power supply of the same according to a third embodiment of the present invention will now be described with reference to the drawings. To facilitate description, like reference numerals are given to those components that are the same as the corresponding components of the above embodiments and will not be described.

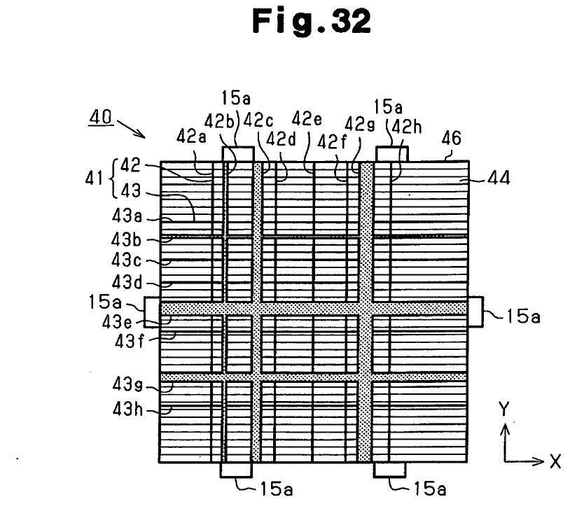

FIG. 32 is a plan view showing the power supply wiring of the LSI of the present embodiment.

As shown in FIG. 32, the reinforcing power supply wires (power supply mesh) 41 of an LSI 40 includes vertical reinforcing power supply wires 42a to 42h and lateral reinforcing power supply wires 43a to 43h arranged in unequal intervals. The widths of the vertical reinforcing power supply wires 42a to 42h and lateral reinforcing power supply wires 43a to 43h are set separately.

Specifically, the vertical reinforcing power supply wires 42a to 42h and the lateral reinforcing power supply wires 43a to 43h are arranged so as to traverse the position of the peak provisional IR drop value in the LSI 40, that is, the provisional IR drop peak position P. Furthermore, the vertical reinforcing power supply wires 42 and the lateral reinforcing power supply wires 43 have widths which sufficiently decrease the provisional IR drop at the IR drop peak position P.

The power supply wiring method of the present embodiment, and the power supply mesh 41 of the LSI 40 will now be described.

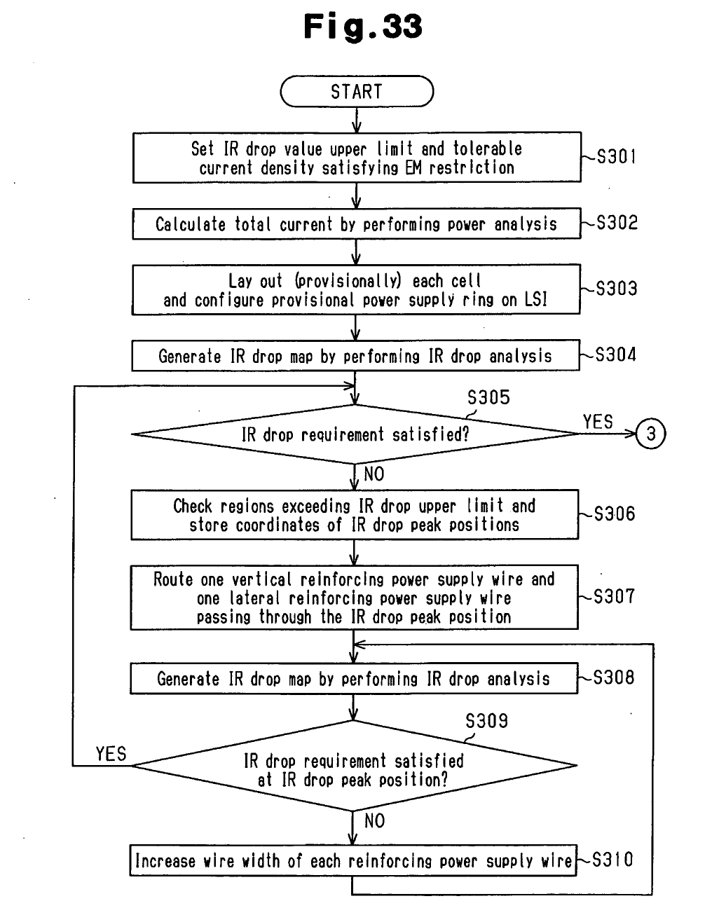

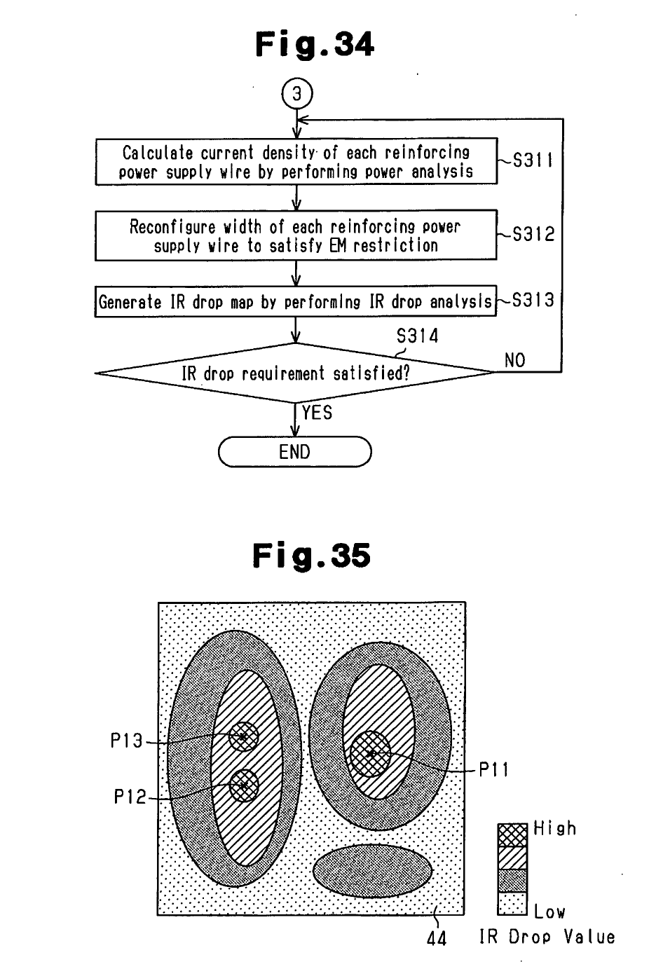

FIGS. 33 and 34 are flowcharts of the power supply wiring method, that is, the wiring design process, of the present embodiment. This process is executed by an information processor such as a computer or the like.

First, the tolerable IR drop value upper limit and the tolerable current density for wiring that satisfies the EM restriction are set (step S301), and the total current flowing to a logic circuit 44 of the LSI 40 is calculated (step S302).

Then, each cell configuring the logic circuit 44 is provisionally laid out, and the provisional power supply ring 46 is laid out around the periphery of the logic circuit 44 (step S303). In this state, IR drop analysis is performed, and a provisional IR drop map is generated, as shown in FIG. 35 (step S304). A determination is made as to whether or not an IR drop exceeding the upper limit has been generated, that is, whether or not the IR drop condition is satisfied, based on the IR drop map (step S305). When the IR drop condition is satisfied (YES), the processes of step S311 and subsequent steps described later are executed.

When the IR drop condition is not satisfied, the region in which the IR drop is occurring and the IR drop peak positions P are specified, and the coordinates of the specified peak positions P are stored in step S306. Then, the vertical reinforcing power supply wires 42 and the lateral reinforcing power supply wires 43 are provisionally laid out (added) so as to pass through the peak positions P (step S307).

The process of step S307 will now be described in detail.

Three provisional peak positions P11, P12, and P13 appear on the provisional IR drop map shown in FIG. 35. The provisional IR drop value at peak position P11 is the largest value among the three peak positions P11, P12, and P13. In this case, the peak position P11 is selected first in step S307. Then, a vertical reinforcing power supply wire 42g and a lateral reinforcing power supply wire 43e are provisionally laid out so as to intersect at the selected peak position P11.

After provisionally arranging the vertical reinforcing power supply wire 42g and the lateral reinforcing power supply wire 43e, the processes of subsequent steps S308 to S310 are executed to further ensure reduction of IR drop at the IR drop peak position P11.

IR drop analysis is again performed with the provisionally laid out vertical reinforcing power supply wire 42g and the lateral reinforcing power supply wire 43e, and an IR drop map is again prepared (step S308). A determination is made as to whether or not the provisional IR drop value at the IR drop peak position P11 satisfies the IR drop condition (step S309). When the provisional IR drop value does not satisfy the IR drop condition, the widths of the vertical reinforcing power supply wire 42g and the lateral reinforcing power supply wire 43e are increased (step S310). The processes of steps S308 to S310 are repeated until the provisional IR drop value at the IR drop peak position P11 satisfies the IR drop condition.

When the provisional IR drop value at the peak position P11 satisfies the IR drop condition in step S309, the routine returns to step S305, and a determination is again made as to whether or not the IR drop condition is satisfied in all regions of the logic circuit 44.

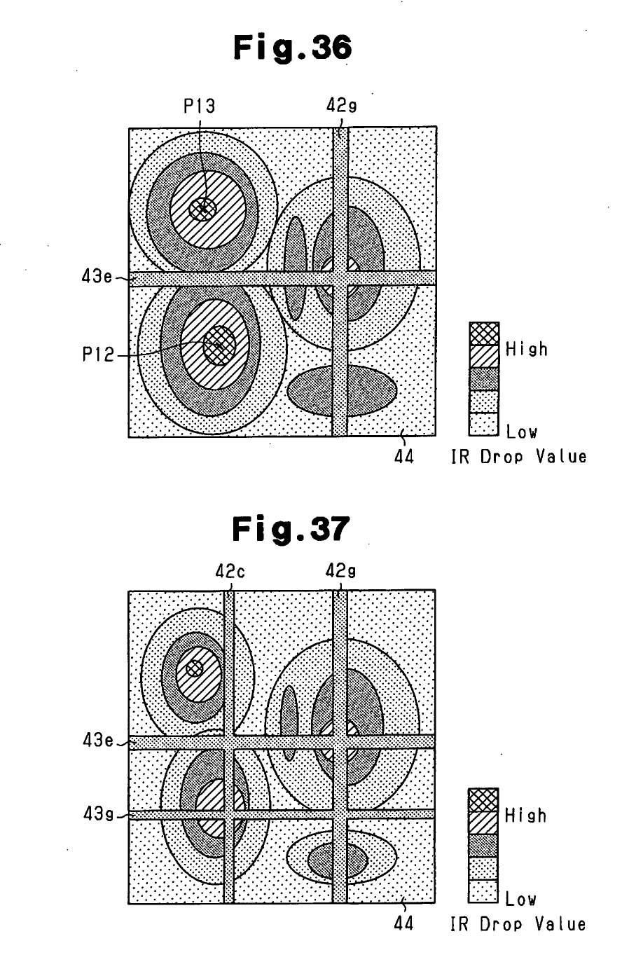

That is, the IR drop distribution in the logic circuit 44 is changed by adding the vertical reinforcing power supply wires 42g and the lateral reinforcing power supply wires 43e as can be understood by comparing FIGS. 36 and 35. The IR drop peak positions P12 and P13 are shifted in FIG. 36. Therefore, in step S305, a determination is made as to whether or not the IR drop condition is satisfied in all regions of the logic circuit 44 after the addition of the reinforcing power supply wires based on the IR drop distribution after the change. When the IR drop condition is satisfied in the process of step S305, the processes of step S311 and subsequent steps described later are executed.

However, when the provisional IR drop value at either the shifted IR drop peak position P12 or P13 still does not satisfy the IR drop condition, the processes of step S306 and subsequent steps are again executed.

When the provisional IR drop value at the shifted IR drop peak position P12 is greater than the provisional IR drop value at the shifted IR drop peak position P13, the coordinates of the provisional IR drop peak position P12 are stored in step S306. Then, in step S307, the vertical reinforcing power supply wire 42c and the lateral reinforcing power supply wire 43g are provisionally laid out so as to intersect the peak position P12 as shown in FIG. 37. The widths of the vertical reinforcing power supply wire 42c and the lateral reinforcing power supply wire 43g are increased until the provisional IR drop value at the IR drop peak position P12 satisfies the IR drop condition (steps S308 to S310).

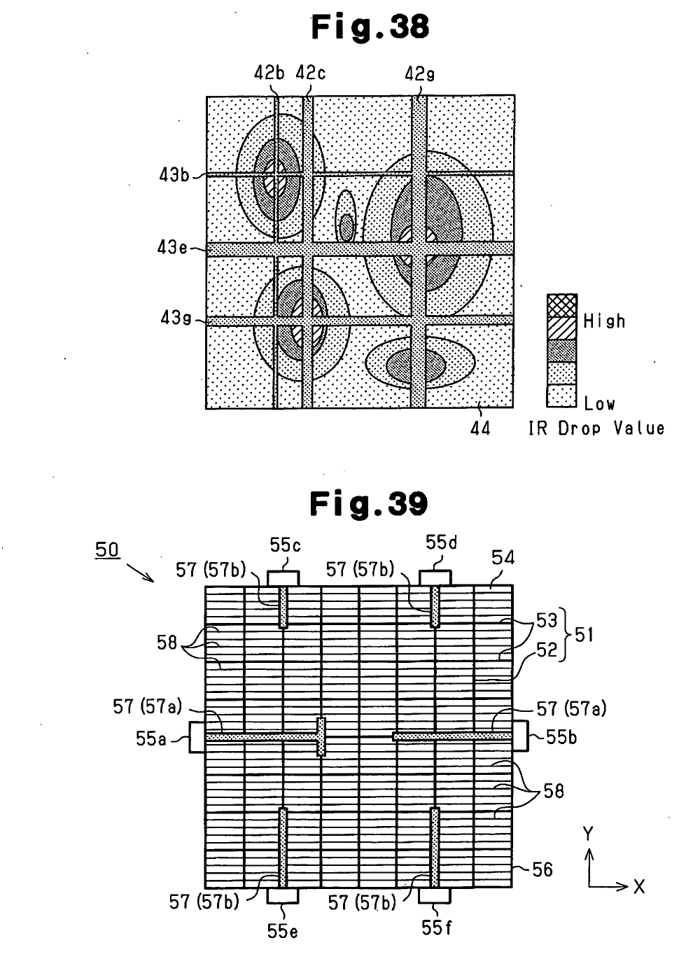

Steps S306 to S310 are repeated until the IR drop condition is satisfied in all regions of the logic circuit 44. FIG. 38 shows a logic circuit 44 that satisfies the IR drop condition. When the IR drop values satisfy the IR drop condition in all regions of the logic circuit 44 in step S305, then in the process of step S311, power analysis is performed and the current density (provisional current density) is calculated for the vertical reinforcing power supply wires 42a to 42h and the lateral reinforcing power supply wires 43a to 43h. The widths of the vertical reinforcing power supply wires 42a to 42h and the lateral reinforcing power supply wires 43a to 43h are reconfigured so as to satisfy the EM restriction. (step S312). After the wire widths have been reconfigured, an IT drop map is again prepared by IR drop analysis (step S313), and a determination is made as to whether or not the IR drop condition is satisfied (step S314). When an IR drop exceeding the upper limit is generated in step S314, the process for satisfying the EM restriction is again performed (steps S311 to S313).

In addition to advantages (1) to (5) of the first and second embodiments, the third embodiment has the advantage described below.

(7) A vertical reinforcing power supply wire 42g and a lateral reinforcing power supply wire 43e are laid out (added) so as to pass through a provisional IR drop peak position P11 obtained by IR drop analysis, and the widths of the vertical reinforcing power supply wire 42g and the lateral reinforcing power supply wire 43e are increased until the IR drop condition is satisfied at the peak position P11. Then, IR drop analysis is again performed, and a vertical reinforcing power supply wire 42c and lateral reinforcing power supply wire 43g are added so as to pass through the newly shifted IR drop peak position P12. Next, the widths of the vertical reinforcing power supply wire 42c and the lateral reinforcing power supply wire 43g are increased until the IR drop condition is satisfied at the peak position P12. In this manner, the sequence of processes, that is, the addition of vertical reinforcing power supply wires and lateral reinforcing power supply wires and the increase in their widths, are repeated until the IR drop condition is satisfied in all regions of the logic circuit 44.

Accordingly, the power reinforcement is concentrated at the provisional IR drop peak positions P, and the IR drop condition is sequentially satisfied at the shifted IR drop peak positions P in the logic circuit 44. This effectively mitigates the IR drop, and enables the design of a semiconductor integrated circuit having improved stability.

A semiconductor integrated circuit device and method wiring a power supply of the same according to a fourth embodiment of the present invention will now be described below with reference to the drawings. FIG. 39 is a plan view showing the power supply wiring of the LSI of the present embodiment.

As shown in FIG. 39, in the same manner as the first embodiment, an LSI 50 includes a plurality of power supply pads 55a to 55f laid out around a logic circuit 54. Operation current is supplied from the power supply pads 55a to 55f to basic power supply wires 58 through a power supply ring 56. Furthermore, there is no restriction in the wiring of the power supply mesh 51 configured by laying out reinforcing power supply wires (power supply mesh) 51 on the logic circuit 54 to decrease the IR drop and satisfy the EM restriction, for example, any of the wirings of the first through third embodiments may be used. For example, vertical reinforcing power supply wires 52 and lateral reinforcing power supply wires 53 may be arranged at equal pitches, as shown in FIG. 39.

The LSI 50 includes power supply trunk lines 57, which are connected to the power supply pads 55a to 55f, and extend (arranged) from the power supply pads 55a to 55f toward the inner side of the logic circuit 54. The vicinity of the distal ends of the power supply trunk lines 57 is connected to the power supply mesh 51 or basic power supply wires 58.

Each power supply trunk line 57 supplies power to a power supply point in the logic circuit 54. Since power is supplied from the interior of the logic circuit 54 toward the wiring at the edges (near the outer circumference), IR drop is effectively mitigated in the logic circuit 54.

The power supply trunk lines 57 include main power supply trunk lines 57a arranged in predetermined regions most needing IR drop mitigation, and secondary power supply trunk lines 57b excluding the main power supply trunk lines 57a. The main power supply trunk line 57a is arranged so as to have the IR drop value within the tolerable range in the region.

The power supply wiring method of the present embodiment will now be described.

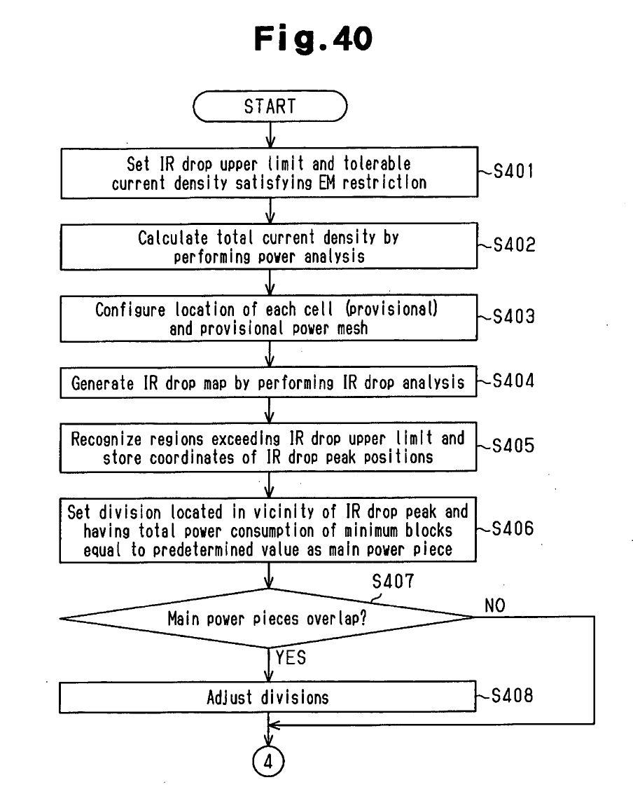

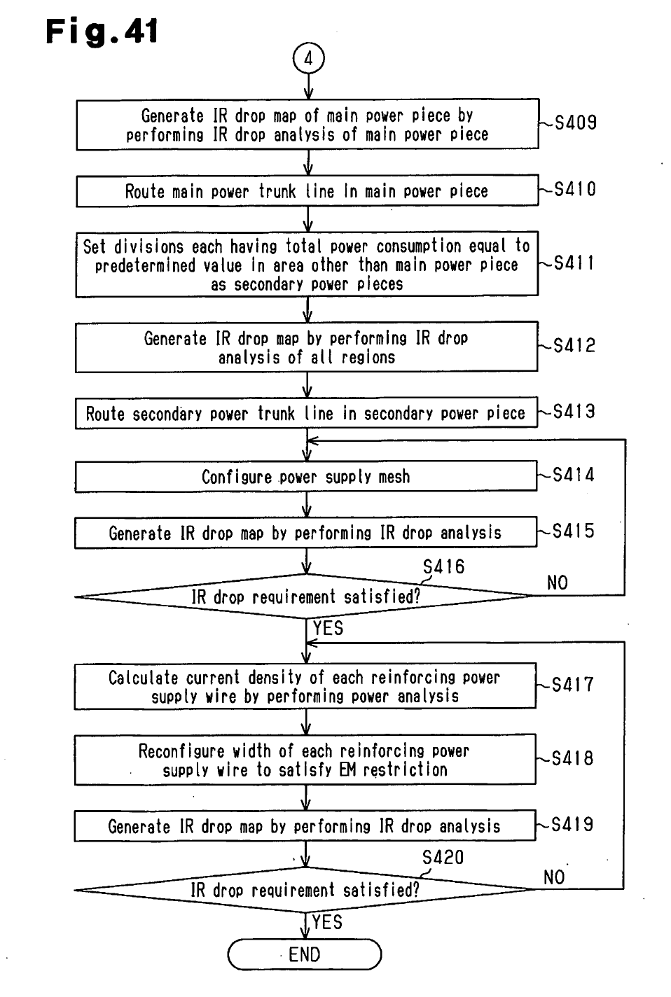

FIGS. 40 and 41 are flowcharts of the power supply wiring method, that is, the wiring design process, of the present embodiment. This process is executed by an information processor such as a computer or the like.

First, the tolerable IR drop value upper limit and the tolerable current density for wiring that satisfies the EM restriction are set (step S401). Then, the total current flowing to the logic circuit is calculated by performing a power analysis (step S402).

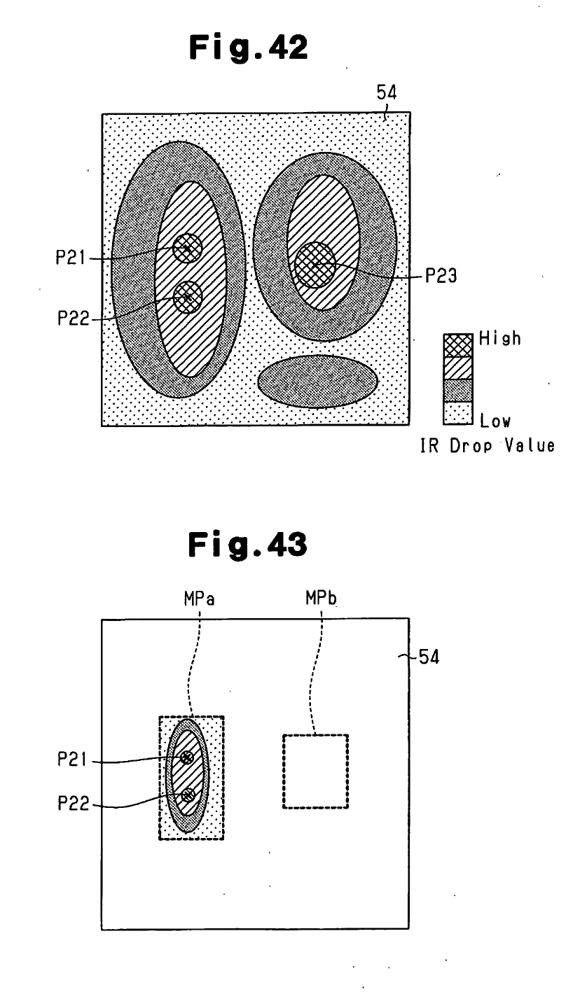

Each cell configuring the logic circuit is provisionally laid out and arranged to form a provisional power supply mesh on the logic circuit (step S403). The provisional power supply mesh is configured by vertical and lateral reinforcing power supply wires laid out at equal pitches. In this state, IR drop analysis is performed, and a provisional IR drop map is generated, as shown in FIG. 42 (step S404). Since the amount of current flowing to each cell temporally differs depending on the operating circumstances of the LSI, the analysis result will differ depending on the amount of current that at a given time that will be used as a criterion. However, an average value is used in step S404.

When an IR drop exceeding the upper limit is generated, the region in which the IR drop exceeds the upper limit is specified, and the coordinates of the provisional IR drop peak positions P are stored (step S405). In the example of FIG. 42, the coordinates of peak positions P21, P22, and P23 are stored.

In step S406, the region most requiring reduction of IR drop is specified, and that region is set as a main power piece MP. Specifically, a region including the provisional IR drop peak positions P21 and P22 near its center is set as main power piece MPa such that the total value of the power consumption (total power consumption) of the minimum blocks (refer to FIG. 8) within that region is substantially equal to a regulated value. Similarly, a region including the provisional IR drop peak position P23 near its center is set as a main power piece MPb such that the total value of the power consumption (total power consumption) of the minimum blocks in that field is substantially equal to a specified value.

When a provisional IR drop analysis is performed with the power supply mesh laid out in unequal pitches, the provisional IR drop peak positions are displaced from positions near regions of dense wiring to positions near sparse regions due to the biased power supply caused by the unequal pitch of the provisional power supply mesh. That is, the pitch of the provisional power supply mesh is adjusted so as to bias the main power piece toward a specified location.

Furthermore, the amount of power, which is a regulated value, may be set separately for each main power piece. For example, the regulated value may be weighed in accordance with the distance between the power supply pad and the provisional IR drop peak position. For example, the regulated value may be weighed so as to increase as the distance becomes shorter between the power supply pad and the provisional IR drop peak position. This is effective since more power is supplied by a shorter power supply trunk line.

When a plurality of main power pieces MPa and MPb are set, the main power pieces MPa and MPb may partially overlap each other. In the present embodiment, a determination is made as to whether or not the main power pieces MPa and MPb are partially overlapping each other (step S407). When they overlap, the locations of the main power pieces MPa and MPb are adjusted to eliminate the overlapping (step S408). When there is no overlap, step S408 is skipped.

The main power pieces MPa and MPb are set in regions which most require the IR drop reduction in the logic circuit 54. The process of step S409 is executed, as shown in FIG. 41, to lay out the power supply trunk line 57 so as to optimally reduce the IR drop of the main power pieces MPa and MPb.

More specifically, in step S409, one main power piece MPa is first selected from among the main power pieces MP as an analysis subject as shown in FIG. 43. The selected main power piece MPa is electrically shielded from other regions on the logic circuit 54, and an IR drop map is generated for the main power piece MPa assuming that a power supply of equal potential is installed on the periphery of the main power piece MPa.

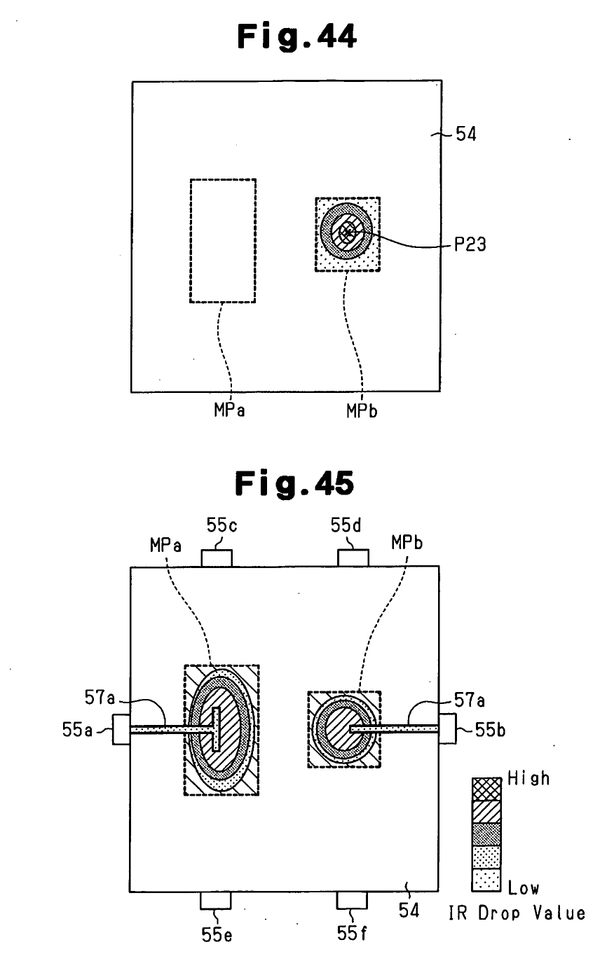

As shown in FIG. 44, another main power piece (main power piece MPb) is then selected as an analysis subject. Then, in the same manner as the main power piece MPa, the selected main power piece MPb is electrically shielded from other regions on the logic circuit 54, and an IR drop map is generated for the main power piece MPb assuming that a power supply of equal potential is installed on the periphery of the main power piece MPb. By assuming the main power pieces MPa and MPb are electrically shielded from other regions and generating IR drop maps in this manner, the IR drop peak positions P21, P22, and P23 are shifted as shown in FIGS. 42 through 44.

In step S410, main power supply trunk lines 57a are laid out so as to reach each of the shifted IR drop peak positions P and form a power supply point at each IR drop peak position P.

Specifically, the main power pieces MPa and MPb are respectively associated with the power supply pads 55a and 55b, as shown in FIG. 45. Then, power supply trunk lines 57 (main power supply trunk lines 57a) are laid out so as to connect the power supply pads 55a and 55b to the IR trop peak positions P (P21, P22, P23) of the corresponding main power pieces MPa and MPb. The widths of the main power supply trunk lines 57a are determined based on the provisional IR drop value at the IR drop peak position P with which the main power supply trunk line 57a is associated.

Main power is supplied from the provisional IR drop peak position P toward the vicinity of the outer edge of the main power piece MP by the main power supply trunk line 57a, which is laid out so as to extend along the interior of the logic circuit 54.

After laying out the main power supply trunk lines 57a, a plurality of secondary power pieces SP are set in regions outside the main power pieces MP of the logic circuit 54 so as that the total power consumption becomes equal to the normal value.

The secondary power pieces SP are continuous regions substantially provided for the regulated amount of power. For example, continuous regions are determined so as to include locations near the power supply portion such as the power supply pad, while having the regulated amount of power. This facilitates the association of the power supply portion and secondary power piece SP in accordance with the distance of the secondary power piece SP from the power supply portion. The shape of the continuous region is not limited, and may be, for example, square, I-shaped, L-shaped, T-shaped, or C-shaped.

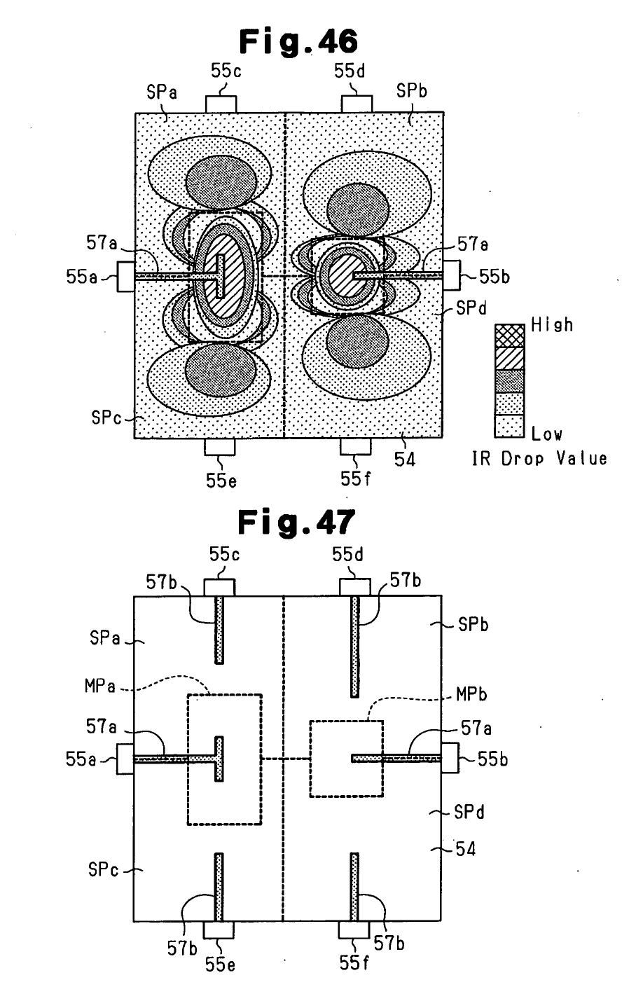

Next, IR drop analysis is performed on all regions of the logic circuit 54 in a state in which the main power supply trunk lines 57a are laid out, and an IR drop map is prepared as shown in FIG. 46 (step S412). Then, power supply trunk lines 57 are laid out for each secondary power piece Spa to SPd (step S413).

That is, secondary power pieces Spa to SPd are associated with power supply pads 55c to 55f, as shown in FIG. 47, in the same manner as the main power pieces MP. The power supply trunk lines 57 (secondary power supply trunk lines 57b) are laid out so as to connect the power supply pads 55c to 55f and the corresponding secondary power pieces Ps to Pd. The secondary power supply trunk line 57b is preferably laid out so as to reach the provisional IR drop peak position P in the secondary power pieces Spa to SPd. The widths of the secondary power supply trunk lines 57b are preferably determined based on the provisional IR drop value at the peak position P.

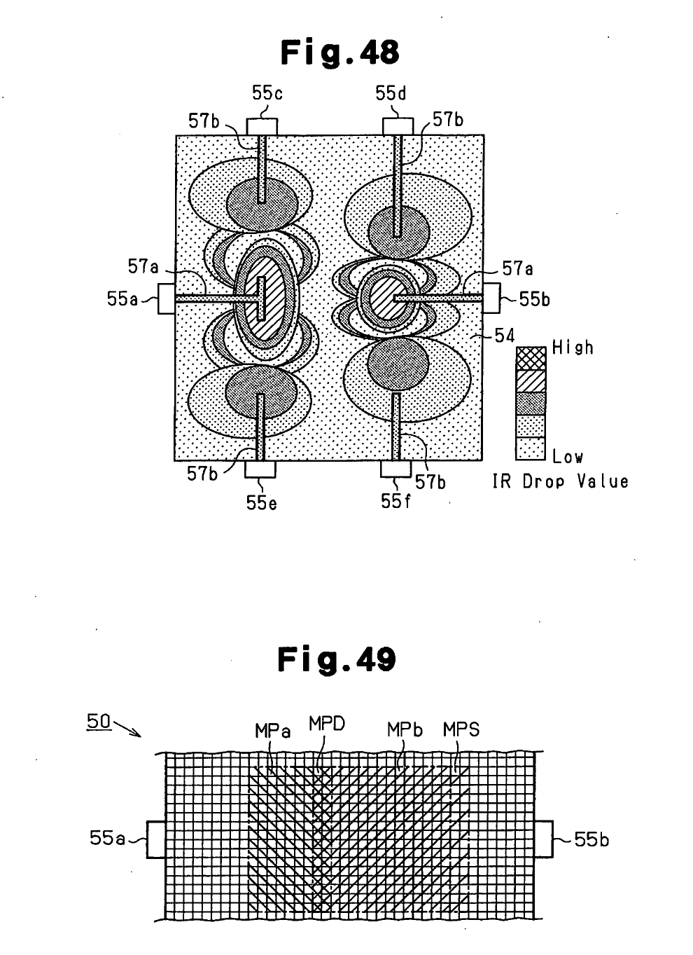

In this manner, after arranging the power supply trunk lines 57 (main power supply trunk lines 57a, secondary power supply trunk lines 57b) for all power pieces, the setting of each power piece MP and SP is released, and a power supply mesh 51 is formed in all regions of the logic circuit 54 (step S414). As shown in FIG. 48, IR drop maps are generated by performing IR drop analysis of the entire logic circuit 54 (step S415), and a determination is again made as to whether or not the IR drop condition is satisfied (step S416). The processes of steps S414 and S415 are repeated until the IR drop condition is satisfied. In step S414, for example, the power supply mesh 51 (vertical reinforcing power supply wires 52 and lateral reinforcing power supply wires 53) may be arranged using the methods of the first through third embodiments.

When the IR drop condition is satisfied (step S416: YES), the current densities (provisional current density) of the vertical reinforcing power supply wires 52 and lateral reinforcing power supply wires 53 are calculated by performing power analysis in step S417.

In step S418, the widths of the vertical reinforcing power supply wires 52 and the lateral reinforcing power supply wires 53 are reconfigured to satisfy the EM restriction. In step S419, an IR drop map is again generated by performing an IR drop analysis for the logic circuit 54 with the reconfigured wiring width. In step S420, a determination is made as to whether or not the IR drop condition is satisfied. When an IR drop exceeding the upper limit is generated, the process for satisfying the EM restriction is again performed (steps S417 to S420).

The process of overlapping main power pieces MP (step S408) is described below.

As shown in FIG. 49, it is assumed that a main power piece MPa and main power piece MPb overlap at overlap region MPD.

In this case, adjustment of a main power piece MPa, which has an overlap region MPD at a position relatively near a connected power supply pad, is not performed. Only the main power piece MPb, which has an overlap region MPD at a position relatively far from a connected power supply pad, is adjusted.

In the example of FIG. 49, the overlap region MPD is relatively far from the power supply pad 55b, and is relatively near to the power supply pad 55a. Therefore, a segment corresponding to the overlap region MPD is deleted from the main power piece MPb to the overlap region MPD related to the relatively distant power supply pad 55b. The segment of the main power piece MPa is confirmed as a region belonging only to the main power piece MPa relatively near to the power supply pad 55a. Next, a region, which includes a region adjacent to the main power piece MPb but outside the main power piece MPb and which has an amount of power that is about the same as the overlap region MPD eliminated from the main power piece MPD, is added to the main power piece MPb to reconfigure the main power piece MPb. By repeating this process, a plurality of main power pieces that have substantially a predetermined amount of power and is free of overlap regions is set.

For example, in the case of the LSI 50, the distance from the overlap region MPD to the power supply pad 55b, which is connected to the main power supply trunk line 57a associated with the main power piece MPb, is farther than the distance from the overlap region MPD to the power supply pad 55a, which is connected to the main power supply trunk line 57a associated with the main power piece MPa.

Therefore, a substitute segment MPS, which is at the side power supply pad 55b of the overlap region MPD of the main power piece MPb, is extracted from a region near the main power piece MPb outside the determined main power piece. The extracted region is added to the main power piece MPb to reset the segment of the main power piece MPb.

That is, an overlap region MPD that is distant from the power supply pad 55a power supply point is deleted from the main power piece MPb, and a segment MPS near the main power piece MPb is newly extracted from a region outside the determined main power piece and added to reset the main power piece MPb so that the total amount of power is small or equal.

In addition to the advantages (1) to (7) of the first through third embodiments, the fourth embodiment has the advantages described below.

(8) The distal ends of the main power supply trunk line 57a and secondary power supply trunk line 57b are laid out toward the inner side of the logic circuit 54 and connected to the power supply mesh 51 and basic power supply wires 58. This supplies power from the inner side of the logic circuit 54 toward portions arranged at the edges (near the periphery). This effectively mitigates IR drop in the logic circuit 54.

(9) Since the power supply trunk lines 57a and 57b are laid out at the IR drop peak positions P on the logic circuit 54, the IR drop is effectively reduced.

(10) When main power pieces MP overlap, the main power pieces MP are adjusted to eliminate the overlap region. Therefore, since the main power pieces MP is properly set for regions generating the largest IR drop, the IR drop is more effectively mitigated. As a result, a semiconductor integrated circuit having improved stability is designed.

(11) The main power pieces MPa and MPb are set. Then, the main power supply trunk lines 57a corresponding to the main power pieces MPA and MPb are laid out. Next, secondary power pieces Spa to SPd are set for regions outside the main power pieces MPa and MPb, and secondary power supply trunk lines 57b corresponding to the secondary power pieces Spa to SPd are laid out. This procedure gives priority to IR drop reduction in the main power pieces MP that have a large provisional IR drop. As a result, the IR drop is more effectively mitigated, and a semiconductor integrated circuit having improved stability is designed.

When the IR drop map is generated for the main power piece MPa in step S409, IR drop analysis may be performed assuming that a power supply of unequal potential is installed at the periphery of the main power piece MPa rather than assuming that a power supply of equal potential is installed at the periphery of the main power piece MPa. In this case, the IR drop peak position P is shifted nearer to the provisional power supply that is assumed to have a relatively low potential. By arranging the distal end of the power supply trunk line 57a near the shifted IR drop peak position P, the vicinity of the power supply assumed to have a relatively low potential is less affected by power supply fluctuation than other locations. Thus, the power supply is reinforced in the vicinity of the power supply.

Next, the power supply wires are laid out so as to widen from the distal end of the power supply trunk line 57a to the inner side of the main power piece MPa. In this process, IR drop violations of the power supply wiring in the main power piece MPa are checked using a value obtained by adding a margin electric potential (for example, the difference between a reference potential of the LSI and a relatively low potential at the periphery of the main power piece MPa) to the IR drop value in the vicinity of the edge of the main power piece Pa. In this way, power supply wiring that satisfies the IR drop condition with a sufficient margin may be laid out in the main power piece MPa.

Thus, particularly stable potential is supplied to a circuit, which is susceptible to power supply fluctuation such as a macro cell, by provisionally installing power supplies having unequal potential including power supplies having relatively weak potential around the main power piece MPa.

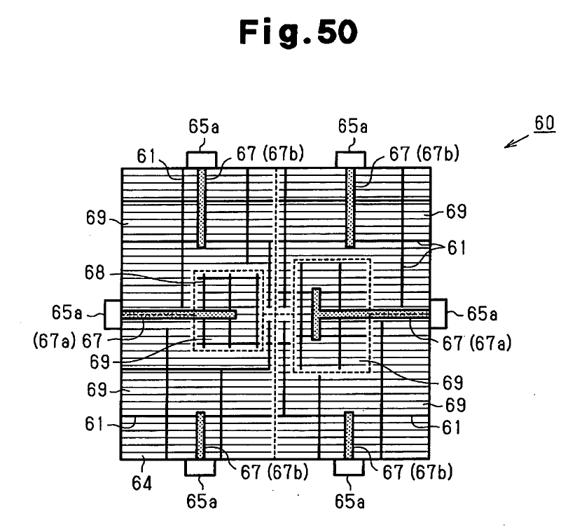

A semiconductor integrated circuit device and method wiring a power supply of the same according to a fifth embodiment of the present invention will now be described below with reference to the drawings. FIG. 50 is a plan view showing a power supply wiring of the LSI of the present embodiment.

As shown in FIG. 50, an LSI 60 has a plurality of (six) power supply pads 65a arranged along the periphery of a logic circuit 64. A power supply mesh 61 (vertical reinforcing power supply wires 61a and lateral reinforcing power supply wires 61b) is laid out in a predetermined manner on the logic circuit 64. Then, power supply trunk lines 67 (main power supply trunk lines 67a, secondary power supply trunk lines 67b) are laid out from the power supply pads 65a toward the inner side of the logic circuit 64. The logic circuit 64 includes six segment regions (division regions) 69. Power is supplied to each segment region 69 from a corresponding power supply trunk line 67.

The power supply mesh 61 and basic power supply wires 68 are arranged separately (individually) for each segment region 69. The segment regions 69 are each associated with one of the power supply pads 65a, and basically receive power only from the associated power supply pad through a power supply trunk line 67. Thus, the logic circuit 64 is supplied with the necessary power from only six power supply pads 65a. The operation of the LSI 60 is stabilized by such separation of power supplies. Power control is performed for each of the six regions 69. The amount of current required by each segment region 69 is set to be lower than the maximum tolerable current of each power supply pad 65a.

The power supply wiring method of the present embodiment is described below.

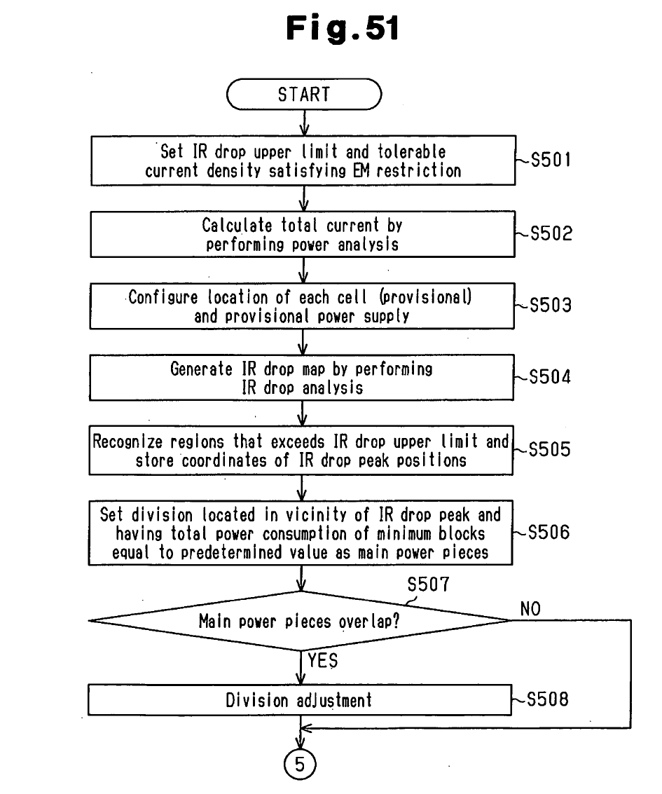

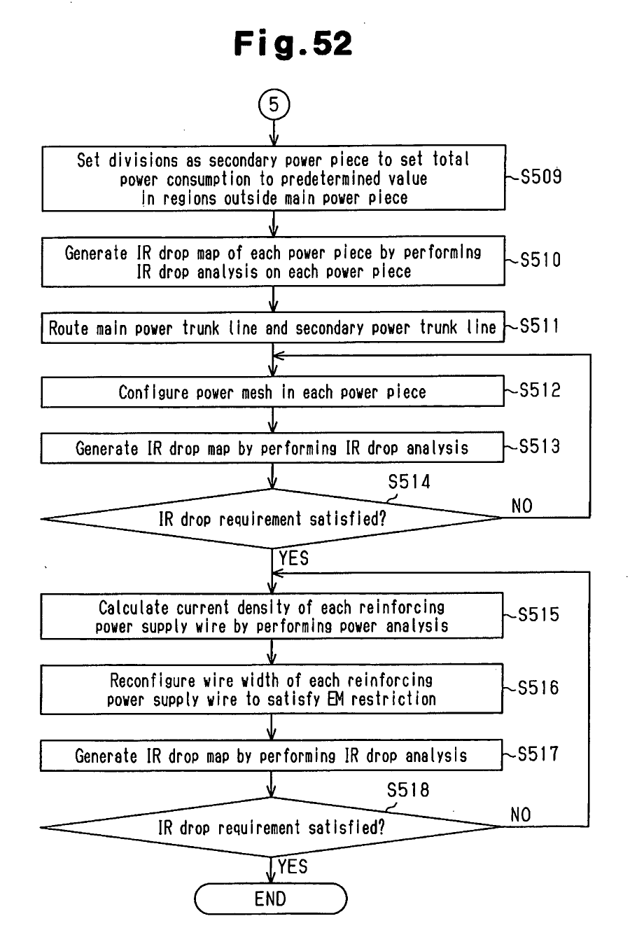

FIGS. 51 and 52 are flowcharts of the power supply wiring method, that is, the wiring design process, of the present embodiment. This process is executed by an information processor such as a computer or the like. This process is basically performed through the same procedures as the wiring design process of the fourth embodiment.

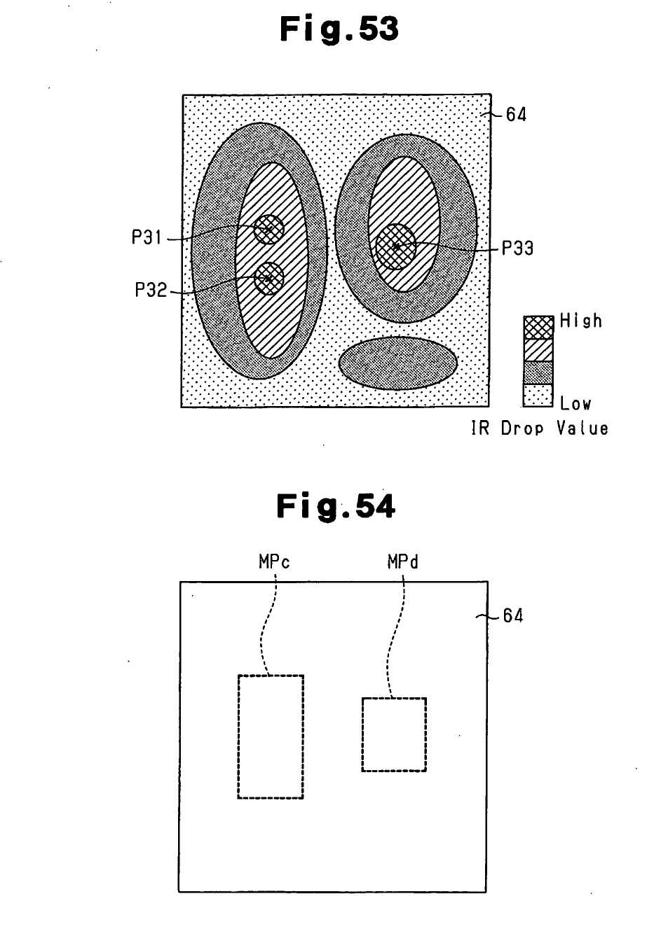

First, the IR drop value upper limit and the tolerable current density for the wiring to satisfy the EM restriction are set (step S501). Then, the total current flowing to the logic circuit 64 of the LSI 40 is calculated (step S502). Each cell forming the logic circuit 64 is provisionally laid out to form a provisional power supply mesh on the logic circuit 64 (step S503). As shown in FIG. 53, a provisional IR drop map is generated through an IR drop analysis (step S504). The IR drop analysis is performed assuming the power supply mesh is laid out at equal pitches.

When an IR drop exceeding the upper limit is generated, the coordinates of the provisional IR drop peak position P is stored (step S505). In the example shown in FIG. 53, the coordinates of IR drop peak positions P31, P32, and P33 are stored.

In the same manner as in the fourth embodiment, a main power piece MP is set on the logic circuit 64 (step S506). Specifically, in the LSI 60, a main power piece MPc, which includes peak positions P31 and P32, and a main power piece MPd, which includes the provisional IR drop peak position P33, are set, as shown in FIG. 54. The main power pieces MPc and MPd are set such that their power consumption becomes equal to a regulated value.

A determination is then made as to whether or not the main power pieces MP overlap (step S507). When the main power pieces MP overlap, the main power pieces MP are adjusted to eliminate the overlap (step S508). When there is no overlap, step S508 is skipped.

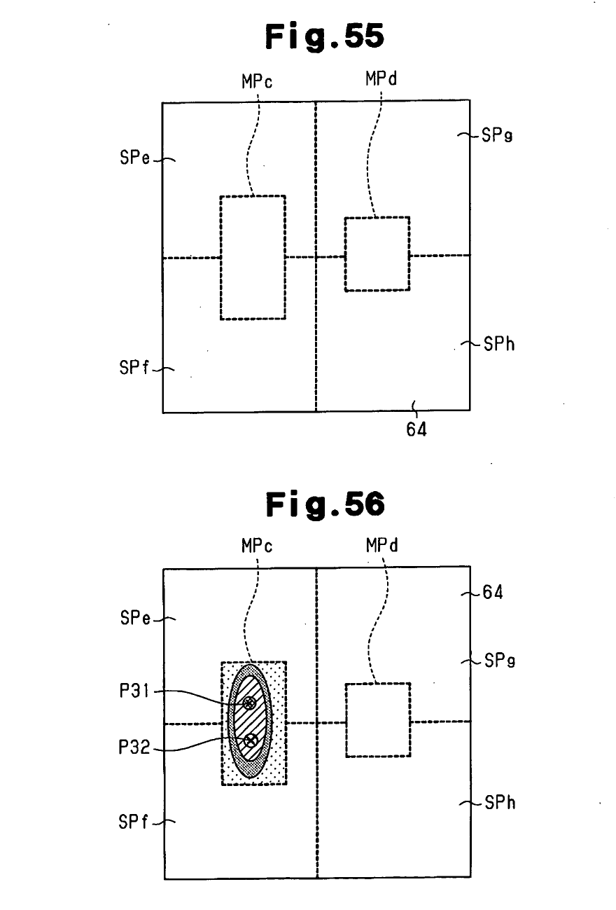

After setting the main power pieces MP, the secondary power pieces SP are set (step S509). The power consumption of the secondary power pieces SP is set at a standardized value. Specifically, the values are set as shown in FIG. 55. In the example of FIG. 55, substantially equal amounts of power are supplied from each power supply pad such that the amount of power regulated for the main power pieces and secondary power pieces is ⅙ the total amount of power.

More specifically, in this case, the number of secondary power pieces SP set on the logic circuit 64 is set such that the total number of main power pieces MP and secondary power pieces SP is the same as the total number of power supply pads 65a. For example, in the LSI 60 there are a total of six power supply pads 65a, and since two main power pieces MP are set, four secondary power pieces SPe to SPh are set in other regions.

After setting the main power pieces MP and secondary power pieces SP, IR drop analysis is performed for each main power piece MP and secondary power piece SP, and IR drop maps are generated (step S510).

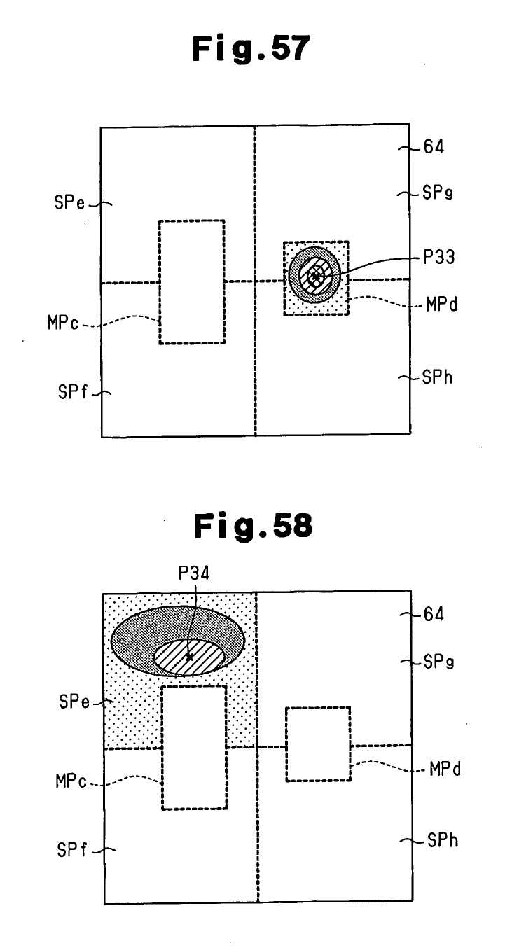

The process of step S510 is described below. As shown in FIG. 56, a main power piece MPc is first selected as an analysis subject. The main power piece MPc is electrically shielded from other regions on the logic circuit 64, power supplies of equal potentials are provisionally installed on the periphery, and an IR drop map is generated. IR drop peak values P31 and P32 appearing on this map are stored. As shown in FIG. 57, another main power piece (main power piece MPd) is then selected as an analysis subject. The main power piece MPd is electrically shielded from other regions on the logic circuit 64, and power supplies of equal potentials are provisionally installed on the periphery, and an IR drop map is prepared. An IR drop peak value P33 appearing on this map is stored.

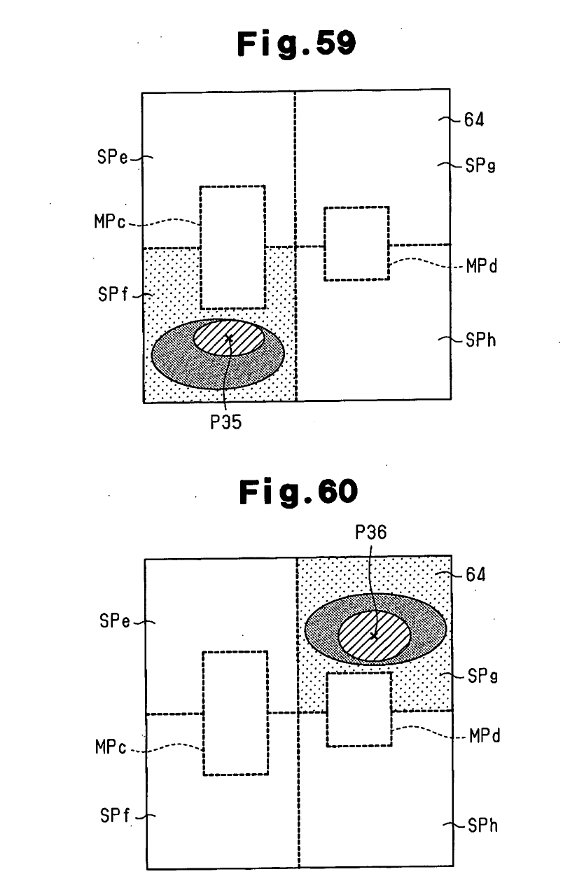

After IR drop maps are generated for all main power pieces MP, IR drop analysis is performed for the secondary power pieces SP. For example, a secondary power piece SPe is selected as an analysis subject, as shown in FIG. 58. The secondary power piece SPe is electrically shielded from other regions on the logic circuit 64, power supplies of equal potential are provisionally installed on the periphery, and an IR drop map is generated. A provisional IR drop peak value P34 appearing on this map is stored. As shown in FIG. 59, another secondary power piece SP (in this case, secondary power piece SPf) is selected as an analysis subject, the secondary power piece SPf is electrically shielded on the logic circuit 64, and an IR drop map is generated assuming a power supply of equal potential is installed on the periphery of the main power piece. A provisional IR drop peak value P35 appearing on this map is stored.

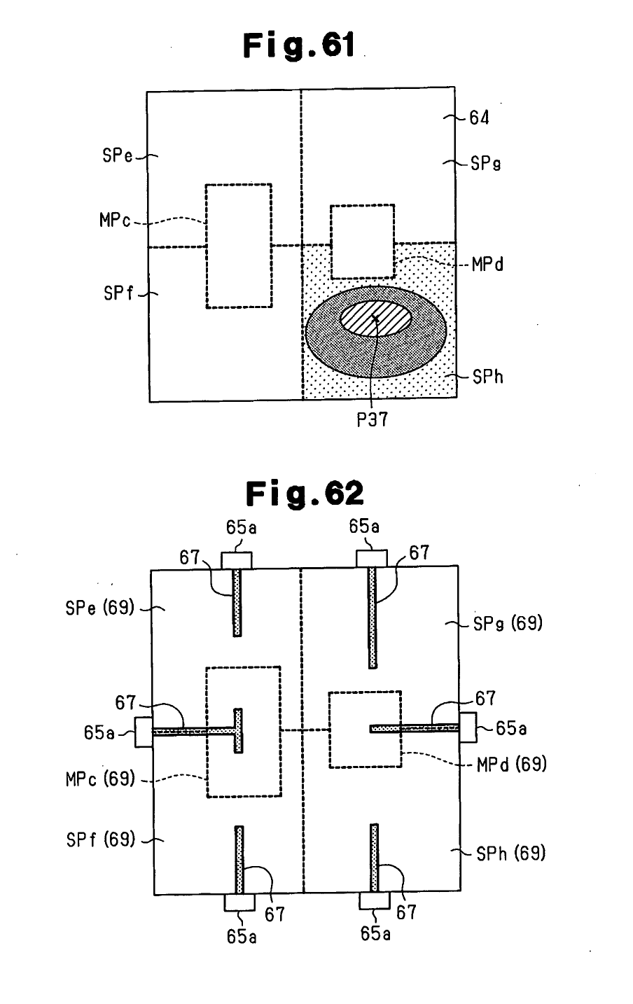

As shown in FIGS. 60 and 61, IR drop maps are generated for other secondary power pieces SPg and SPh in the same manner, and provisional IR drop peak positions P36 and P37 appearing on the map are stored.

After IR drop maps have been generated for all power pieces, power supply trunk lines 67 are arranged to arrange power supply points for each power piece in step S511.

Specifically, the main power pieces MPc and MPd and secondary power pieces SPe to SPh are respectively associated with a power supply pad 65a. The power supply trunk lines 67 are laid out so as to connect the power supply pads 65a and the corresponding power piece. The power supply trunk lines 67 are preferably laid out so as to reach the provisional IR drop peak position P. The widths of the power supply trunk lines 67 are determined based on the provisional IR drop value of the IR drop peak position P.

After the power supply trunk lines 67 have been laid out for all of the power pieces, a power supply meshes 61 is formed for all of the main power pieces MP and secondary power pieces SP in step S512. That is, a power supply mesh 61 is arranged separately for each power piece. This provisionally forms segment regions 69 of which power supplies are separated on the logic circuit 64.

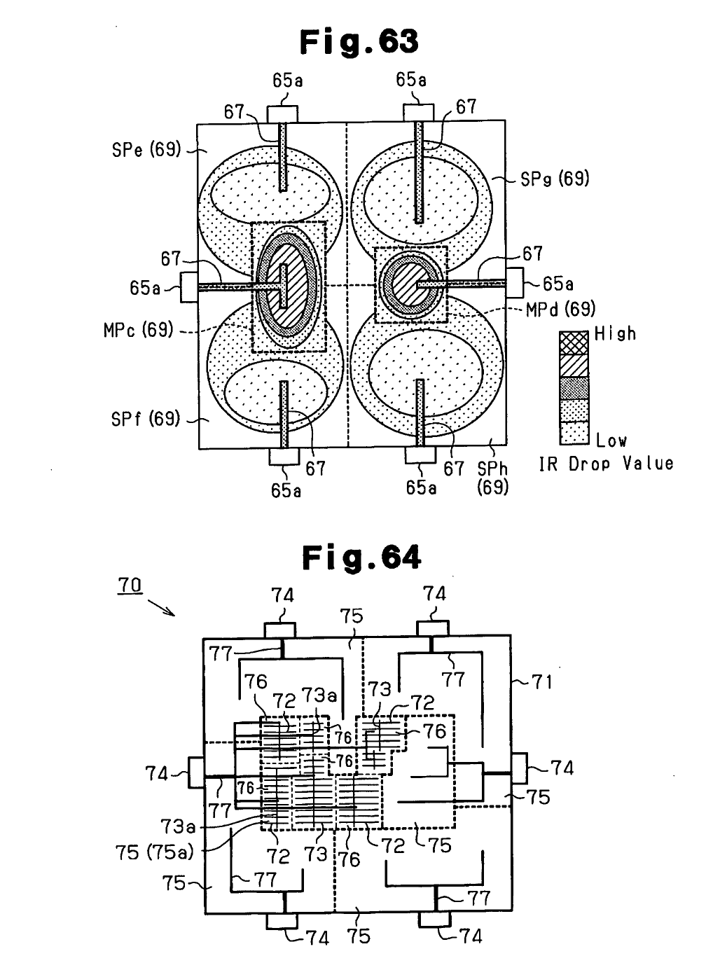

As shown in FIG. 63, IR drop analysis is performed again for all main power pieces MP and secondary power pieces SP, and IR drop maps are generated (step S513). A determination is then made as to whether or not all main power pieces MP and secondary power pieces SP satisfy the IR drop condition (step S514).

When a power piece generates an IR drop value that exceeds the upper limit in the process of step S514, the processes of steps S512 and S513 are repeated until only that power piece satisfies the IR drop condition. In the process of step S512, the wiring method of, for example, any of the first through third embodiments may be used as the wiring method of the power supply mesh 61, and processes corresponding to the used method may be executed.

When the IR drop condition is satisfied in the process of step S514, the current densities of the power supply meshes 61 (vertical reinforcing power supply wires 61a and lateral reinforcing power supply wires 61b) are calculated by power analysis in step S515.

In step S516, the widths of the vertical reinforcing power supply wires 61a and lateral reinforcing power supply wires 61b are reconfigured so as to satisfy the EM restriction. In step S517, an IR drop map is again generated for each power piece. In step S518, a determination is made as to whether or not each power piece satisfies the IR drop condition. When a power piece generates an IR drop that exceeds the upper limit, only that power piece is subjected to a process to satisfy the EM restriction (steps S515 to S517).

In addition to advantages (1) through (10) of the first through fourth embodiments, the fifth embodiment has the advantage described below.

(12) Power is supplied to the logic circuit 64 through the segment regions 69 of which power supply circuits are separated from one another. Therefore, the generation of noise and the mixing of noise due to excess power loops formed by unnecessary power supply wiring are prevented, and power is stabilized. As a result, the semiconductor integrated circuit has improved stability.

Although each segment has a separate power supply in the fifth embodiment, each segment may ultimately be connected at separated locations so that the power supplies are not separated.

A semiconductor integrated circuit device and method wiring a power supply of the same according to a sixth embodiment of the present invention will now be described below with reference to the drawings. FIG. 64 is a plan view showing the power supply wiring of an LSI in the sixth embodiment.

As shown in FIG. 64, an LSI 70 has a plurality of (six) power supply pads 74 arranged on the periphery of a logic circuit 71. Power supply meshes 73 (reinforcing power supply wires) are arranged in a predetermined manner on the logic circuit 71. The power supply mesh 73 includes vertical reinforcing power supply wires 73a and lateral reinforcing power supply wires (not shown in the drawing). Power supply trunk lines 77 are laid out from the power supply pads 74 into the logic circuit 71.

The logic circuit 71 is mainly configured by six division regions (cluster regions 75). In this example, these cluster regions 75 are defined such that the amount of power consumed by each cluster region 75 is essentially ⅙ of the total power consumption of the logic circuit 71. Each cluster region 75 is associated with one of the power supply pads 74, and basically receives power only from the associated power supply pad.

Each cluster 75 includes one or a plurality of segment regions 76, although only one of the cluster regions 75 is shown in the drawing. Basic power supply wires 72 and reinforcing power supply wires 73 are arranged in each segment region 76 such that the power supply wirings 72 and 73 of one segment region 76 are separated from those of other segment regions 76. A power supply trunk line 77 connects each segment region 76 and the power supply pad 74 of the corresponding cluster region 75. Power is supplied to each segment region 76 by the power supply trunk line 77. The reinforcing power supply wires 73 may be eliminated. In this case, power supply trunk lines 77 are connected to all basic power supply wires 72.

The wiring mode of the power supply trunk lines 77 will now be described.

As shown in FIG. 64, the power supply trunk line 77 has a tree structure which branches in steps from the power supply pad 74. Each distal portion of the tree structure power supply trunk line 77 is connected to basic power supply wires 72 or reinforcing power supply wires 73. In addition to the basic power supply wires 72 or reinforcing power supply wires 73, the distal portions of the power supply trunk line 77 may be directly connected to a power supply terminal of a circuit device such as a logic cell, memory cell, or macro cell.

As shown in FIG. 64, after branching once from the power supply pad 74, the distal portion of the power supply trunk line 77 does not have to be connected to the basic power supply wires 72. The power supply trunk line 77 may branch twice, or three or more times as long and have repeated branchings to sufficiently mitigate the voltage drop. In the example of FIG. 64, the distal portion of the power supply trunk line 77 extends to a position when the IR drop value is flattened in each segment region 76.

The width of the power supply trunk line 77 differs in each step of the branch, and is set so as to increase in steps nearer to the power supply pad 74. By changing the width of the power supply trunk line 77 in steps, the wire width is easily adjusted to mitigate the current density of the power supply trunk line 77.

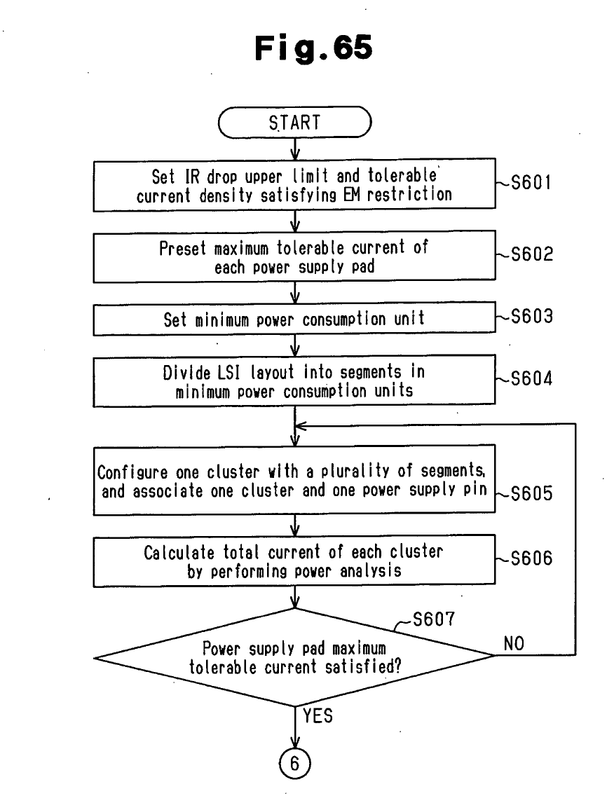

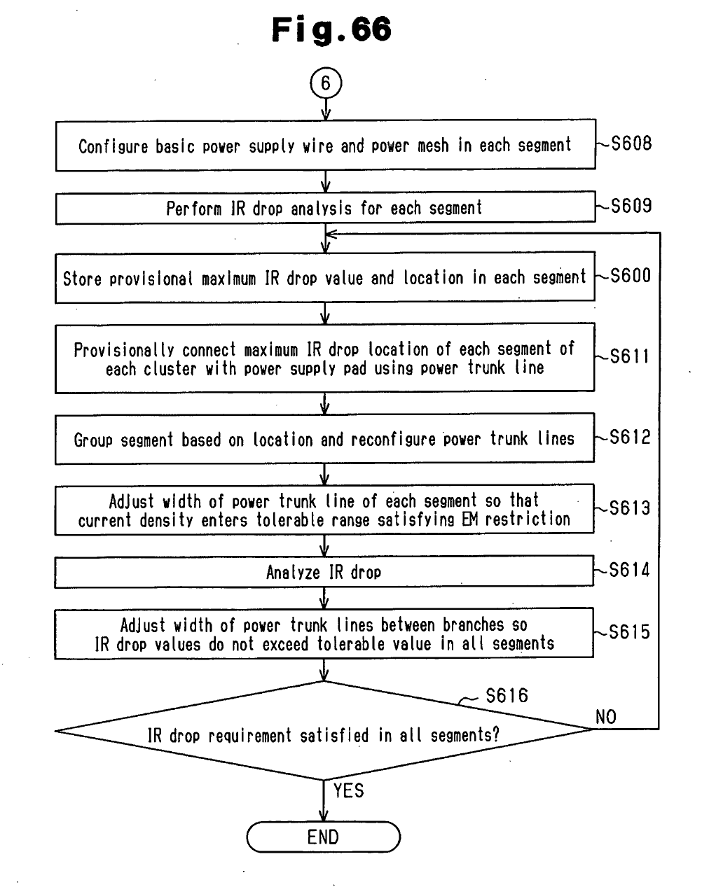

An example of the power supply wiring method and wiring design process of the LSI 70 of the present embodiment are described below with reference to FIGS. 65 and 66. This process is executed by an information processor such as a computer or the like.

As shown in FIG. 65, the IR drop upper limit value and tolerable current density satisfying the EM restriction are first set in step S601. In step S602, the maximum tolerable current is set for each power supply pad 74. In step S603, the division unit (minimum block U (refer to FIG. 8)) defining the logic circuit 71 is set. In this case, the smallest region (minimum power consumption unit), which consumes an equal amount or slightly more than the amount of power supplied by the power supply wiring when the power supply trunk line 787 has the minimum wiring width obtained from the information processor, is set as the division unit. The division units are set in units selected based on the operating frequency or the function of each module installed in the semiconductor integrated circuit, cell units, or any other units.

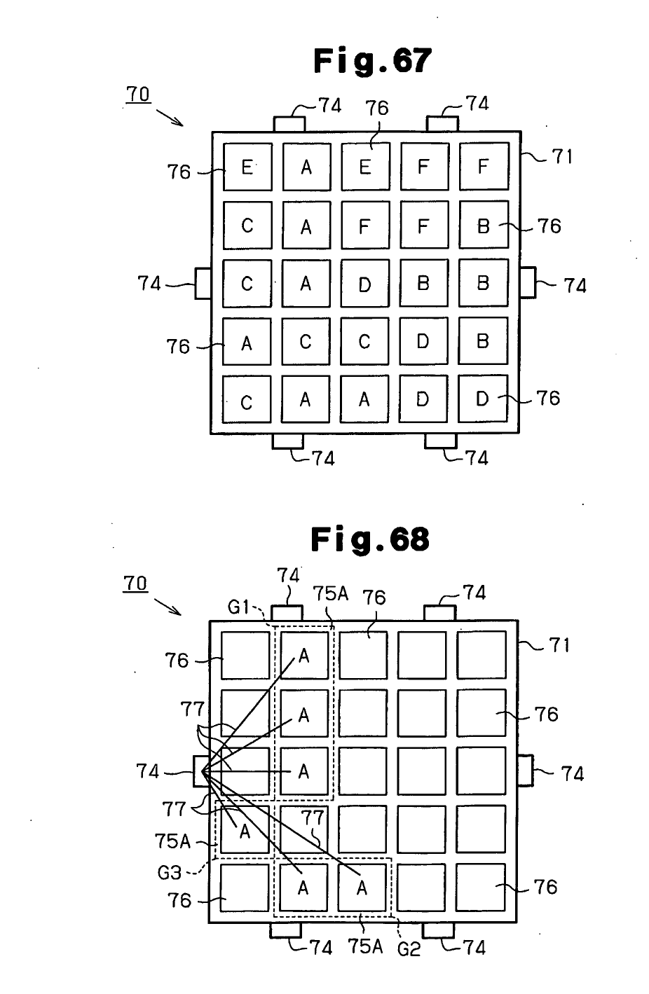

In step S604, at least one segment region 76 is defined in the logic circuit 71 (FIG. 67). The size of each segment region 76 is set so as to sufficiently mitigate the IR drop within the segment region 76 when one power supply point is arranged in each segment region 76.

In step S605, one or a plurality of segment regions 76 are grouped among the segment regions 76 to form a cluster region 75. Specifically, segment regions 76 are grouped in a number equal to the number of power supply pads 74, that is, in six groups A to F, as shown in FIG. 67. The segment regions 76 allocated to groups A to F are set as a plurality of cluster regions 75 (75A to 75F). The plurality of power supply pads 74 are respectively associated with the plurality of cluster regions 75.

In step S606, the total current of each cluster region 75 is calculated by power analysis. In step S607, a determination is made as to whether or not the total current of each cluster region 75 exceeds the maximum tolerable current of the corresponding power supply pad 74. When the total current of a cluster region 75 exceeds the maximum tolerable current, the routine returns to the process of step S605, and the cluster region 75 is reset.

When the total current of a cluster region 75 is less than the maximum tolerable current, the process of step S608 is executed. In step S608, basic power supply wires 72 and reinforcing power supply wires 73 are arranged in each segment region 76 so as to separate the power supply wires 72 and 73 of one segment region 76 from other segment regions 76.

In step S609, IR drop analysis is performed for each segment region 76. In step S610, a provisional IR drop maximum value and its position (provisional IR drop peak position P) in each segment region 76 are stored.

In step S611, as shown in FIG. 68, the provisional IR drop peak positions P are provisionally connected to the power supply pads 74 associated with the cluster regions 75, to which these peak positions P belong, by power supply trunk lines 77. In FIG. 68, the provisional wiring mode of power supply trunk lines 77 is shown only for cluster regions A.

The IR drop in each segment region 76 is sufficiently mitigated by provisionally laying out power supply trunk lines 77 for all segment regions 76 divided in appropriate sizes. In this state, there is a large wiring resource since the power supply trunk lines 77 are provisionally laid out separately from the power supply pad 74 to all segment regions 76. In step S612, reconfiguration of the wiring, such as unifying (integrating) the wiring paths of the provisionally laid out power supply trunk lines 77 with other power supply trunk lines 77, is performed.

Specifically, segment regions 76 are first grouped in accordance with the position of each segment region 76. This grouping is performed for each cluster region 75. For example, in the cluster region A shown in FIG. 68, group G1 includes three segment regions 76, group G2 includes two segment regions 76, and group G3 includes one segment region 76.

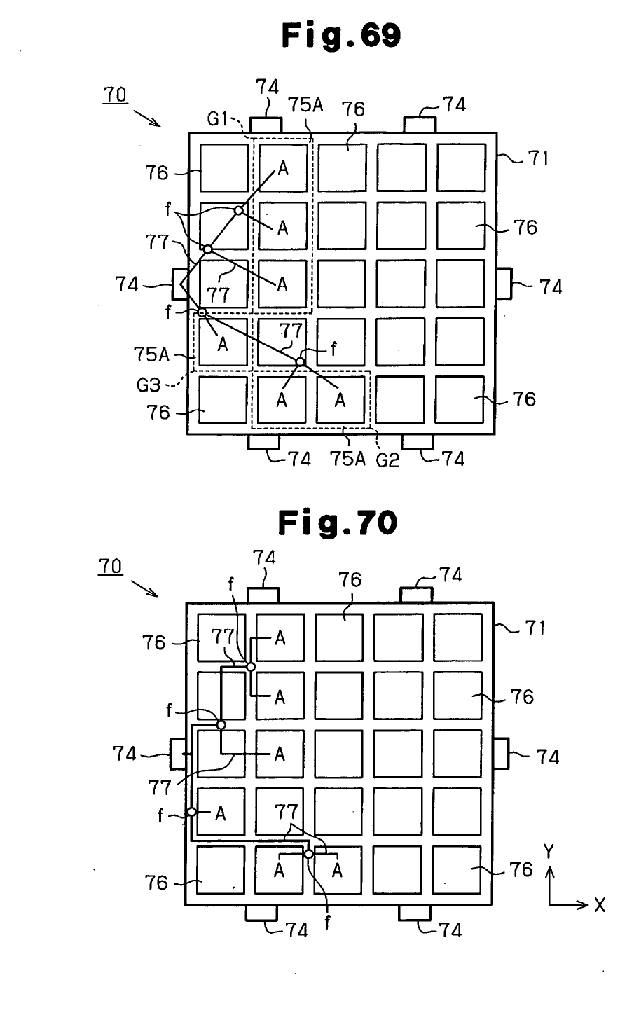

Next, nodes f are set in each power supply trunk line 77, as shown in FIG. 69. The nodes f of one power supply trunk line 77 are integrated with the nodes f of another power supply trunk line 77 for each group G. Subsequently, the nodes f are integrated such that a single power supply trunk line 77 is associated with a single group G near the power supply pad 74. Thereafter, the wiring paths of the power supply trunk lines 77 undergo a final adjustment such that the arranged power supply trunk lines 77 have a tree structure, as shown in FIG. 70.

In step S613, the widths of the power supply trunk lines 77 are adjusted such that the current density of the power supply trunk line 77 is less than the tolerable current density. Specifically, the width of each branch of the power supply trunk line 77 in the tree structure is increased in steps from the distal portions of the power supply trunk line 77 in the tree structure toward the power supply pad 74.

In step S614, IR drop analysis is performed for each segment region 76, and IR drop maps are generated. In step S615, a determination is made as to whether or not the IR drop condition is satisfied in each segment region 76. When an IR drop that exceeds the upper limit is generated, the wiring widths are adjusted only for the power supply trunk line 77 provisionally laid out in the segment region 76 that generated the IR drop exceeding the upper limit.

In step S616, IR drop analysis is performed again for each segment region 76. When an IR drop that exceeds the upper limit is generated after the process of step S616, the processes of steps S610 to S615 are repeated only for the segment regions 76 that generated the IR drop exceeding the upper limit.

In addition to advantages (8), (9), and (12) of the fourth and fifth embodiments, the sixth embodiment has the advantages described below.

(13) Power supply trunk lines 77 having a tree structure that branches in steps from the power supply pad 74 are provided, and each distal portion of the power supply trunk lines 77 is connected to a basic power supply wire 72 or a reinforcing power supply wires 73. This ensures mitigation of the voltage drop, and optimally suppresses the generation of electromigration.

(14) Since the widths of each branch wire of the power supply trunk line 77 is set so as to satisfy the requirements of either the voltage drop or current density, generation of electromigration based on the voltage drop and excessive current density is accurately mitigated through the synergistic effect of the step-like branching structure of the power supply trunk line 77.

(15) Integration of all of the power supply trunk lines 77 is accomplished at the same time after all power supply trunk lines 77 have been provisionally laid out. Since the final wiring paths are adjusted when the power supply trunk lines 77 are integrated, the tree-structure power supply trunk lines 77 is accurately arranged without waste.

Although a single power supply pad is allocated as a power supply portion to each cluster region in the sixth embodiment, a plurality of power supply pads may be connected to one another and allocated as a power supply portion for each single cluster region. Furthermore, a single power supply pad may also be allocated as a power supply portion to a plurality of cluster regions.

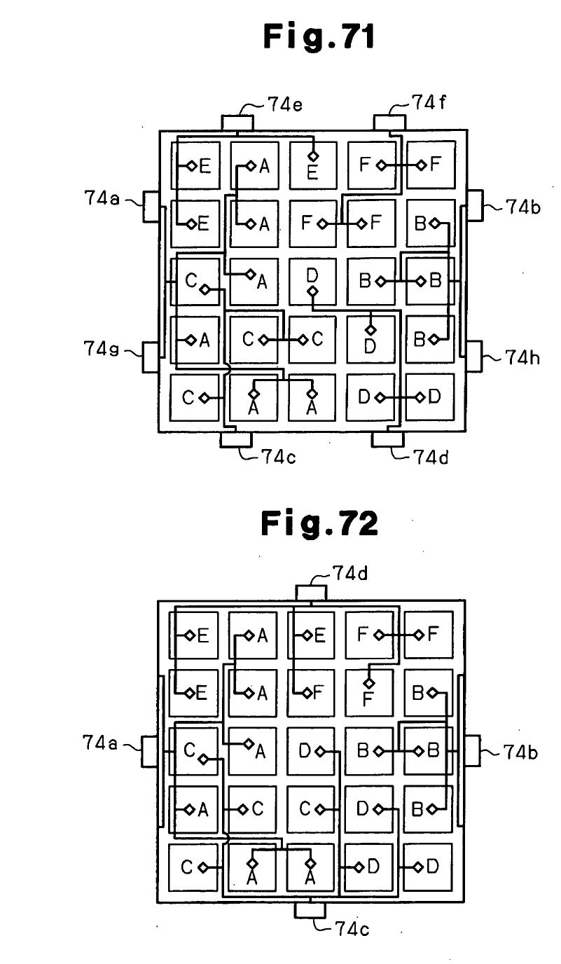

For example, in the example of FIG. 71, eight power supply pads 74a to 74h are provided for six cluster regions 75A to 75F. The power requirements of the clusters 75A and 75B are double the power requirements of the other cluster regions 75C to 75F. In this case, the power supply pads 74a and 74g are allocated to the cluster region 75A, the power supply pads 74b and 74g are allocated to the cluster region 75B, and the power supply pads 74c to 74f are respectively allocated to the other cluster regions 75C to 75F.

For example, in the example of FIG. 72, four power supply pads 74a to 74d are provided for six cluster regions 75A to 75F. The amount of power required by the cluster region 75A, the amount of power required by the cluster region 75B, the total amount of power required by the cluster regions 75C and 75D, and the total amount of power required by the cluster regions 75E and 75F are the same. In this case, the power supply pads 74a and 74b are respectively allocated to the cluster regions 75A and 75B, a single power supply 74c is allocated to the two cluster regions 75C and 75D, and a single power supply pad 74d is allocated to the two cluster regions 75E and 75F.

Although each segment and each cluster have separate power supplies in the sixth embodiment, the power supplies need not be separate.

A semiconductor integrated circuit device and method wiring a power supply of the same according to a seventh embodiment of the present invention will now be described below with reference to the drawings.

An LSI 80 of the present embodiment basically has the same structure as the sixth embodiment, and the power supply trunk lines 87 are arranged in a tree structure with step-like branches. In addition to basic power supply wires or reinforcing power supply wires, the distal portions of the power supply trunk lines 87 may directly be connected to the power terminals of the circuit terminals, such as logic cells, memory cells, macro cells or the like.

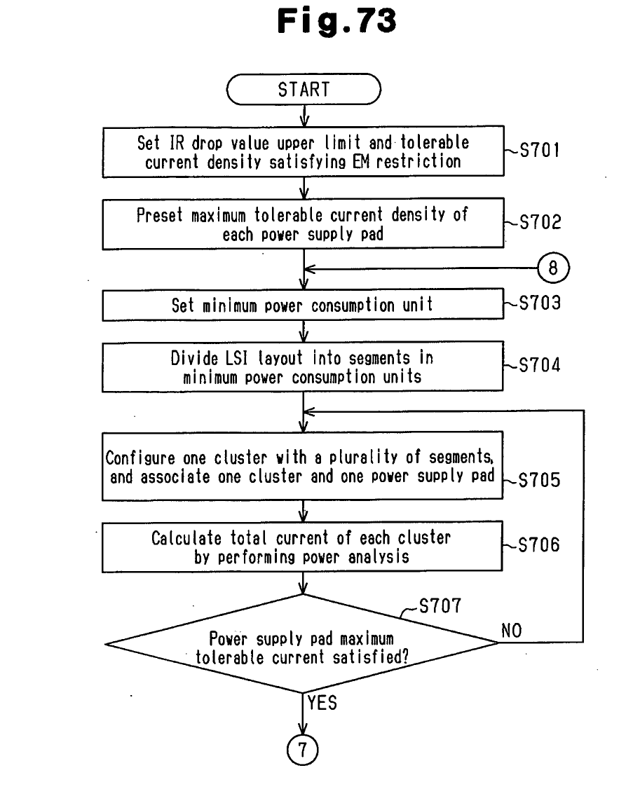

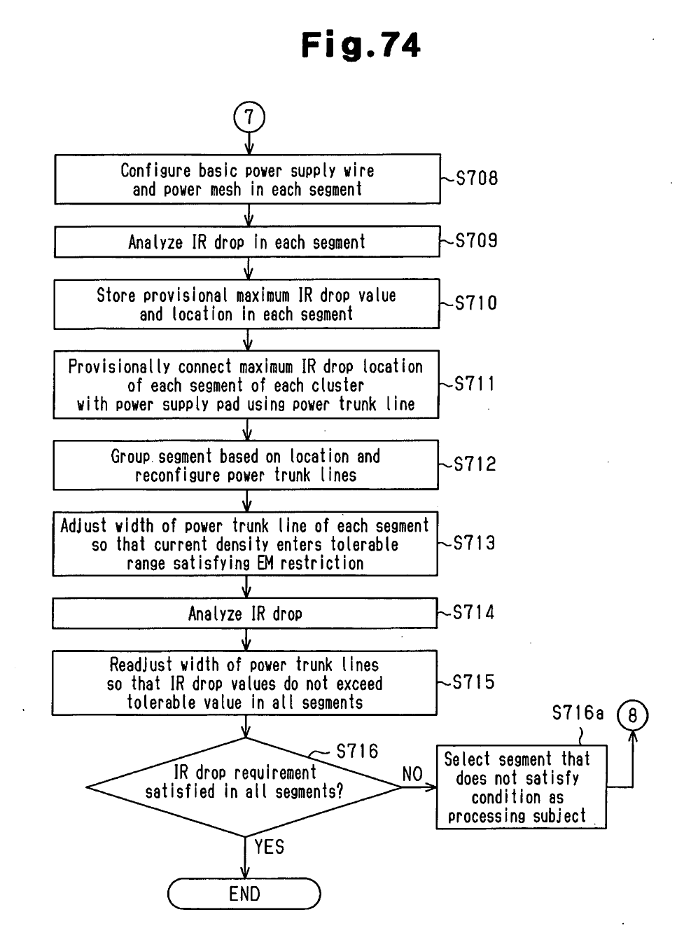

The power supply wiring method of the present embodiment is described below. FIGS. 73 and 74 are flowcharts showing the wiring procedures of the power supply wires executed by an information processor such as a computer or the like in the present embodiment.

In step S701, the IR drop value upper limit (tolerable limit) and the tolerable current density satisfying the electromigration restriction are set. In step S702, the maximum tolerable current is set for each power supply pad 84. In step S703, the division unit (minimum block U (refer to FIG. 8)) for defining the logic circuit 81 is set. The division unit may be set, for example, at the minimum power consumption unit.

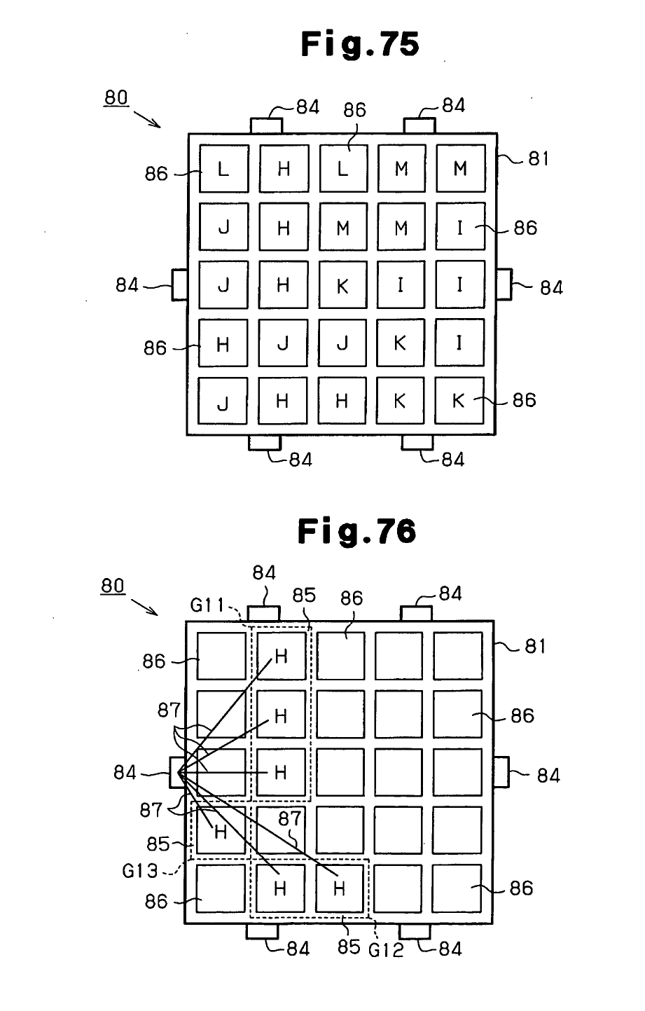

In step S704, the logic circuit 81 is defined, and the segment regions 86 are set. Specifically, the segment regions 86 are set as shown in FIG. 75. The segment regions 86 are set so that they have the same power consumption. In the present embodiment, the setting of the segment regions 86 is optional. For example, the segment regions 86 may be set so as to have the same operating frequency and functions in the modules that the segment regions 86 are incorporated in.

In step S705, one or a plurality of segment regions 86 are grouped and set as a cluster region 85. Specifically, segment regions 86 are grouped in six groups H to M which have four power supply pads 74. The groups H to M are respectively set as cluster regions 85 (85H to 85M). Furthermore, the power supply pads 84 are associated with the cluster regions 85.

In step S706, the total current of each cluster region 85 is calculated by performing power analysis. In step S707, a determination is made as to whether or not the total current in all cluster regions 85 exceeds the maximum tolerable current of the associated power supply pad 84. When there is a cluster region for which total calculated current exceeds the maximum tolerable current (S707: NO), the routine returns to the process of step S705, and the cluster region 85 is reset. Then, steps S705, S706, and S707 are repeated until the total current of all cluster regions 85 is less than the maximum tolerable current.

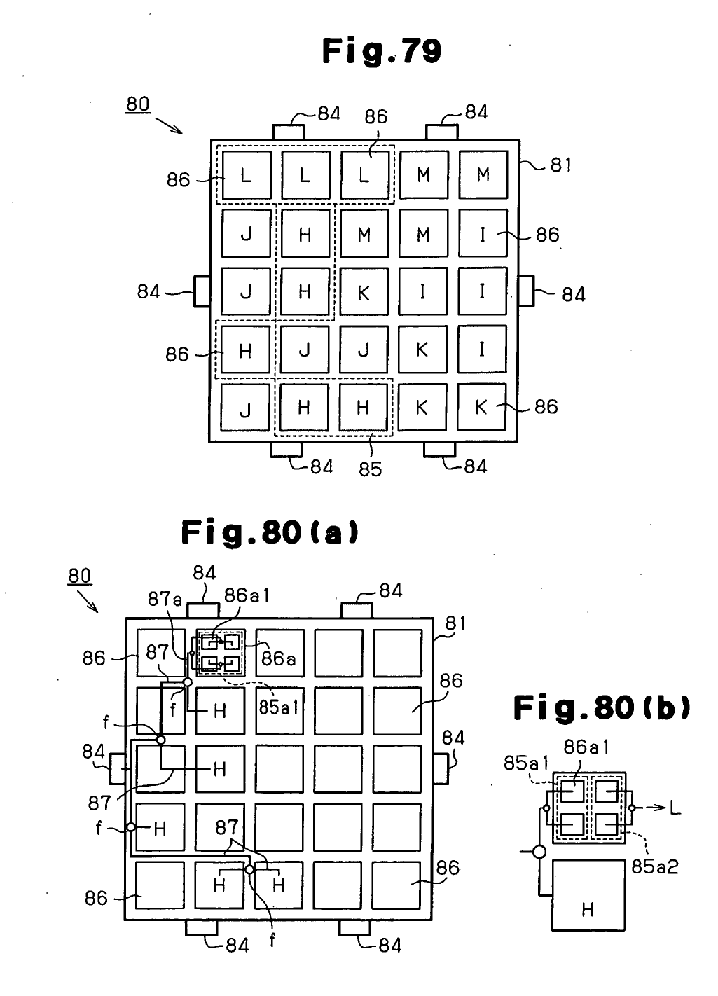

If the current of the cluster region 86 including the segment region H exceeds the maximum tolerable current of the associated power supply pad 84, and the current of the cluster region 85 including the segment region L is sufficiently less than the maximum tolerable current of the associated power supply pad 84, then the cluster regions 85 are reconfigured as shown in FIG. 79.

However, when the total current in all cluster regions 85 is less than or equal to the maximum tolerable current (S707: YES), then in step S808, basic power supply wires 92 and reinforcing power supply wires 73 are arranged for each segment region 86 so as to separate one segment region 86 from another segment region 86 (refer to the seventh embodiment in FIG. 64).

In step S709, IR drop analysis is performed for each segment region 86. In step S710, a provisional IR drop maximum value and position (provisional IR drop peak position P) in each segment region 86 are stored.

In step S711, the stored provisional IR drop peak positions P are provisionally connected to the power supply pads 84 associated with the cluster regions 85 to which the peak positions P belong by power supply trunk lines 87. FIG. 76 shows the provisional wiring of the power supply trunk lines 87 only for the cluster regions H.

In step S712, reconfiguration of the wiring paths of the provisionally laid out power supply trunk line 87, such as unification (integration) with the wiring paths of the other power supply trunk lines 87, is performed.

Specifically, similar segment regions 86 are first grouped in accordance with the location of each segment region 86. This grouping is performed for each cluster region 75. For example, in the cluster regions H shown in FIG. 76, group G11 includes three segment regions 86, group G12 includes two segment regions 86, and group G13 includes one segment region 86.

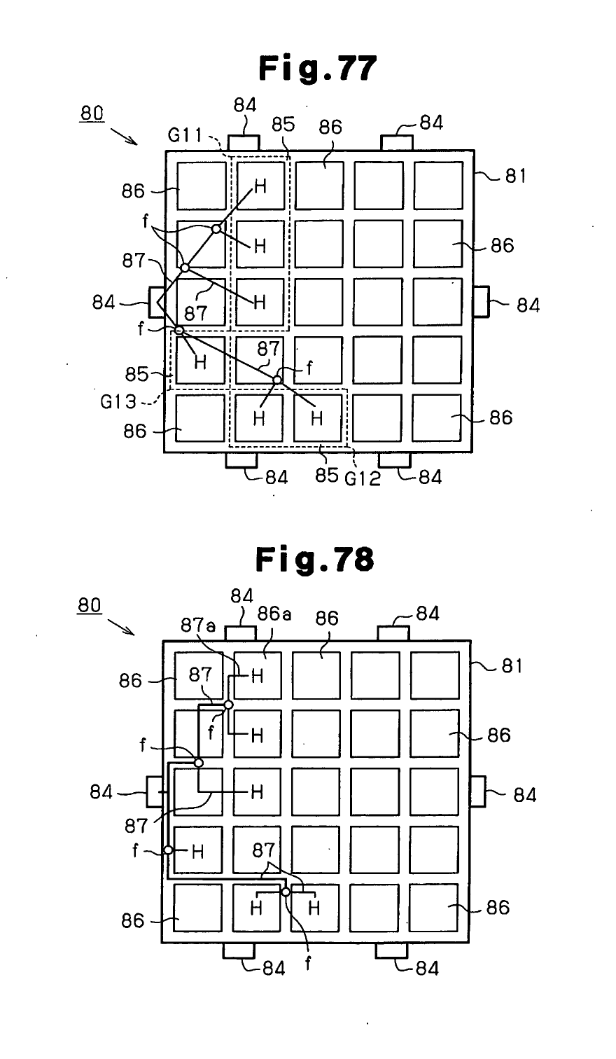

Next, nodes f are provided in each provisionally laid out power supply trunk line 87, as shown in FIG. 77. The nodes f of one power supply trunk line 87 are integrated with the nodes f of another power supply trunk line 87 for each group G. Finally, the nodes f are integrated such that a single power supply trunk line 87 is associated with a single group G near the power supply pad 84. Thereafter, the wiring paths of the power supply trunk lines 87 are subjected to final adjustment.

In step S713, the widths of the power supply trunk line s87 are adjusted such that the current density of the power supply trunk line 87 is less than the tolerable current density. Specifically, the wiring width of each branch of the power supply trunk line 87 is increased in steps from the distal portion of the power supply trunk line 87 toward the power supply pad 84.

In step S714, IR drop analysis is performed for each segment region 86, and IR drop maps are generated. In step S715, a determination is made as to whether or not the IR drop condition is satisfied in each segment region 86. When an IR drop that exceeds the upper limit is generated, the wiring widths are adjusted only for the power supply trunk line 87 provisionally laid out in the segment region 86 that generated the IR drop exceeding the upper limit.

In step S716, IR drop analysis is performed again for each segment region 86. When an IR drop that exceeds the upper limit is generated, the segment region (for example, segment region 86a in FIG. 80a) generating the IR drop exceeding the upper limit is selected as a processing subject (S716a). This processing subject undergoes the processes of steps S703 and subsequent steps in a recursively repeated manner.

During this repetition, the segment region 86a is regarded as an entire circuit, the power supply trunk line 87a reaching the segment region 86a is regarded as a power supply pad, and the processes of step S703 and subsequent steps are executed. This divides the segment region 86a into a plurality of smaller sub-segment regions 86a1. In the example shown in FIG. 80(a), one sub-cluster region 85a1 is formed by a plurality of sub-segment regions 86a1, and each sub-cluster region 85a1 is associated with a cluster region H. A power supply trunk line 87a is branched from the distal portion (provisional distal portion) in step S717, and extended to each sub-segment region 86a1.

This repeated process is executed until it is determined that the IR drop condition is satisfied in all segment regions 86 in step S717. Power supply trunk lines 87 having a tree structure are laid out by repeating the sequential branching at the distal portions of the power supply trunk lines 87.

In step S716a, only the segment region that generates an IR drop exceeding the upper limit may be selected as a processing subject. Alternatively, this segment region and a separate segment region may be selected as a processing subject. The separate segment region may be a segment region near or adjacent to the segment generating the IR drop that exceeds the upper limit or may be a segment region within another cluster region.

When it is expected that the IR drop condition cannot be satisfied, part of the sub-segment region may be incorporated into another cluster region so as to reconfigure the cluster region. For example, in the example shown in FIG. 80(b), a plurality of sub-cluster regions 85a1 and 85a2 are configured by a plurality of sub-segment regions 86a1. The sub-cluster region 85a1 is associated with the cluster region H, and the sub-cluster region 85a2 is associated with the cluster region L.

In addition to advantages (8), (9), and (12) to (14) of the fourth through sixth embodiments, the seventh embodiment has the advantage described below.

(16) Step S703 and subsequent steps are recursively repeated until the IR drop in the logic circuit 81 is sufficiently mitigated. Therefore, tree-structure power supply trunk lines 87 are laid out with the length necessary to mitigate the IR drop in the logic circuit 81.

Furthermore, the power supply trunk lines 87 are laid out at locations that require power in the logic circuit 81. Therefore, the supply of excess power in part of the logic circuit 81 is prevented, and power is efficiently supplied.

In the seventh embodiment, a plurality of power supply pads are connected to each other and allocated as a single power supply portion for each cluster region. Furthermore, a single power supply pad also may be allocated as a power supply portion to a plurality of cluster regions.

Although each segment and each cluster have separate power supplies in the seventh embodiment, the power supplies need not be separate.

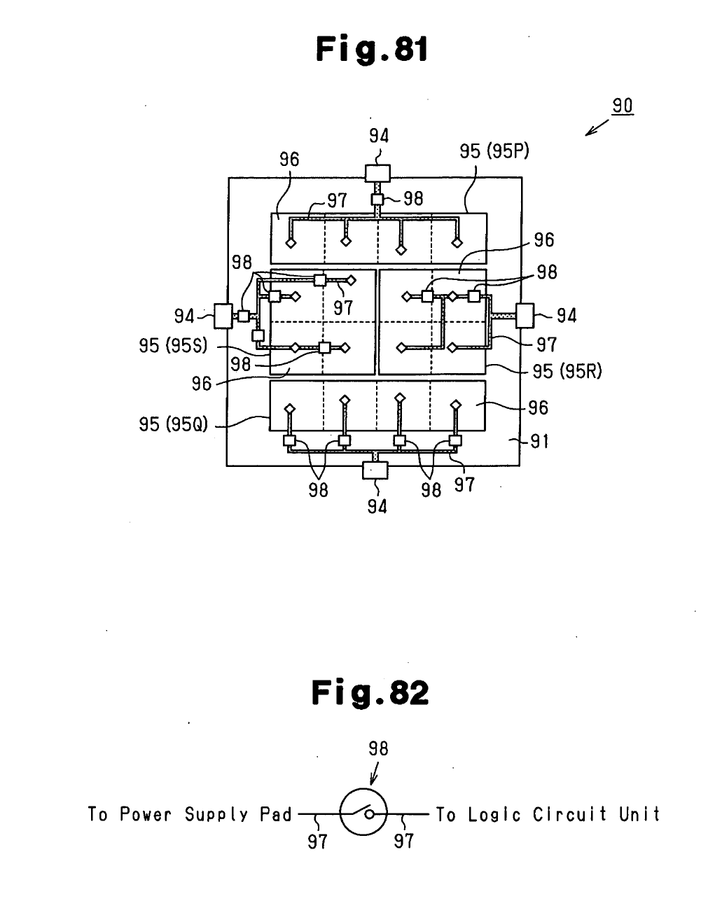

A semiconductor integrated circuit device and method wiring a power supply of the same according to an eighth embodiment of the present invention will now be described below with reference to the drawings. FIG. 81 is a plan view showing the power supply wiring of an LSI of the present embodiment.

As shown in FIG. 81, an LSI 90 has a plurality (four) power supply pads 94 arranged along the periphery of a logic circuit 91. Basic power supply wires and reinforcing power supply wires (not shown) are laid out in a predetermined manner in the logic circuit 91. A power supply trunk line 97 is laid out from the power supply pad 94 to the inner side of the logic circuit 91. In FIG. 81, the rhomboid symbols shown at intermediate points and distal portions of the power supply trunk line 97 are power supply points at which the power supply trunk line 97 supplies power to the logic circuit 91.

The logic circuit 91 includes a plurality of division regions (four clusters (95P to 95S)). In this example, the cluster regions 95 are defined such that the power consumption of each cluster region 95 is essentially ¼ of the total power consumption of the logic circuit 91. Each cluster region 95 is associated with one power supply pad 94 and basically receives power from only the associated power supply pad 94.

In the logic circuit 91, each cluster region 95 is provided with one or a plurality of segment regions 96. A power supply trunk line 97 connects each segment region 96 and the power supply pad 94 of the corresponding cluster region 95. Power is supplied to each segment region 96 by the power supply trunk line 97.

The power supply trunk line 97 has a tree structure arranged with step-like branches from the power supply pad 94. Each distal portion of the power supply trunk line 97 is connected to a basic power supply wire or a reinforcing power supply wire. In addition to a basic power supply wire or a reinforcing power supply wire, the distal portions of the power supply trunk lines 97 may be directly connected to the power supply terminals of circuit devices, such as logic cells, memory cells, or macro cells or the like.

In the eighth embodiment, the power supply trunk line 97 includes a simple switch device 98 that opens and closes the path of the power supply trunk line 97. Power is selectively supplied to each segment region 96 by the switch device 98. This improves the freedom and efficiency of the power control of the semiconductor integrated circuit.

As shown in FIG. 81, the switch device 98 is arranged to enable control of the power supplied to each segment region 96 by the power supply pad 94. For example, the following arrangement is possible.

(i) In the power supply trunk lines 97 that extend toward the segment region 96 in the cluster regions 95, the switch device 98 is arranged on a common path of the power supply path from the power supply pad 94 toward each segment 96.

(ii) In the power supply trunk lines 97 that extend toward the segment region 96 in cluster region 95Q, the switch device 98 is located at distal portions of the power supply trunk lines 97 that are connected in parallel.

(iii) In the power supply trunk lines 97 laid out in series to adjacent segment regions 96, a switch device 98 is arranged in correspondence with each segment region 96 as in the power supply trunk line 97 extending toward the segment region 96 of the cluster region 95R.

As shown in cluster region 95S, the switch devices 98 are arranged by combining (i), (ii), and (iii). The switch devices 98 are preferably large capacity switch devices (for example, power transistor, power MOSFET or the like).

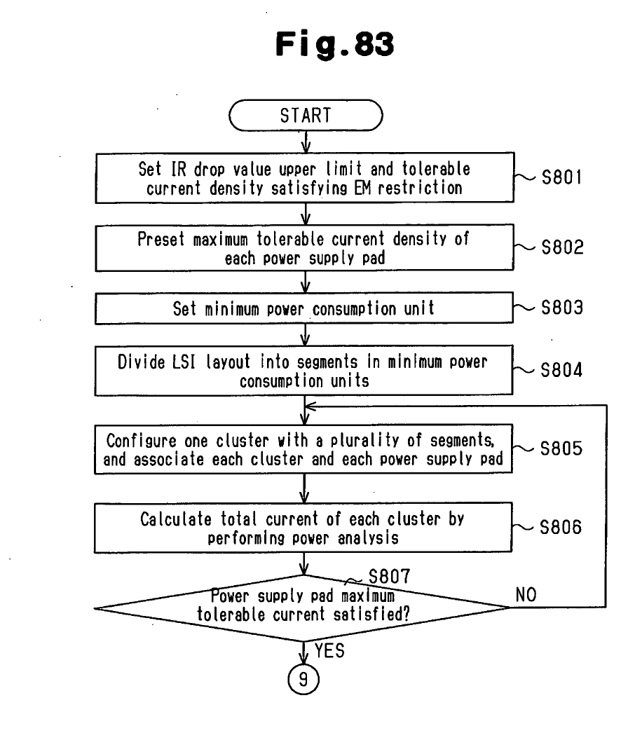

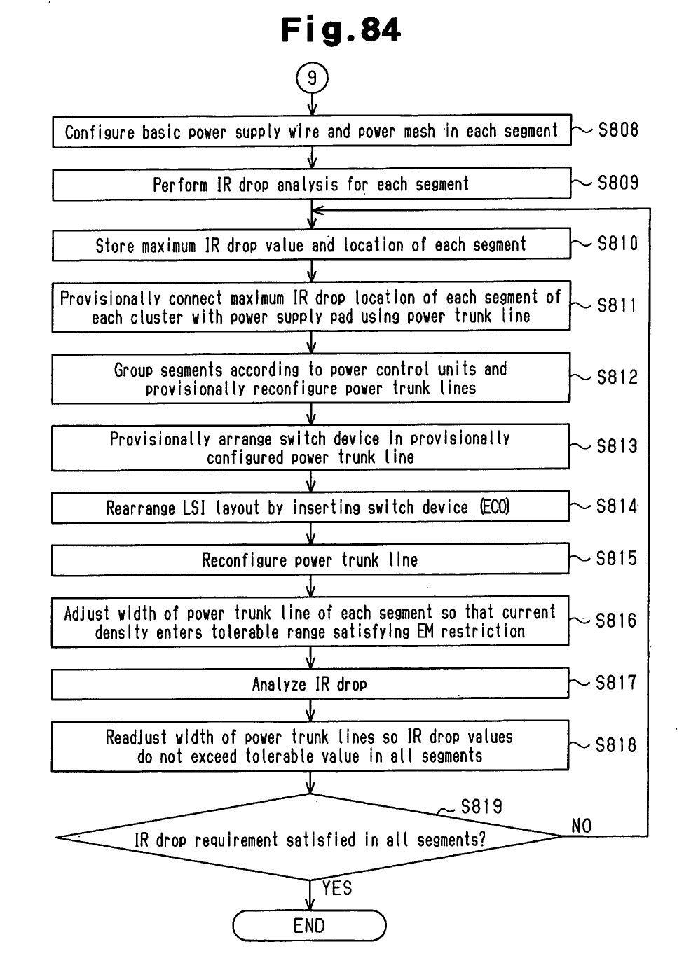

An example of the power supply wiring methods, that is, the wiring design process, of the LSI 90 of the eighth embodiment is described below with reference to FIGS. 83 and 84. This process is executed by an information processor such as a computer or the like.

First the voltage drop (IR drop) upper limit value and the tolerable current density satisfying the electromigration restriction are set in step S801. In step S802, the maximum tolerable current is set for each power supply pad 94. In step S803, the division unit (minimum block U (refer to FIG. 8)) is set for defining the logic circuit 91. The division units may be, for example, the minimum power consumption unit.

In step S804, the logic circuit 91 is divided, and the segment regions 96 are set. In step S805, one or a plurality of segment regions 96 are grouped and set as a cluster region 95. The detailed process for setting the segment region 96 and cluster region 95 is as described in the sixth embodiment.

In step S806, the total current of each cluster region 95 is calculated by power analysis. In step S807, a determination is made as to whether or not the total current of each cluster region 95 exceeds the maximum tolerable current of the corresponding power supply pad 94. When the total current of a cluster region 95 exceeds the maximum tolerable current, the routine returns to the process of step S805, and the cluster region 95 is reset.

When the total current is less than or equal to the maximum tolerable current, basic power supply wires and reinforcing power supply wires are arranged in each segment 96 in step S808 so as to separate the basic power supply wires and the reinforcing power supply wires of one segment region 96 from those of another segment region 96.

In step S809, IR drop analysis is performed for each segment region 96. In step S810, a provisional IR drop maximum value and its position (provisional IR drop peak position P) in each segment region 96 are stored.

In step S811, the stored provisional IR drop peak value P is provisionally connected to the power supply pad 94 associated with the cluster region to which the peak position P belongs by a power supply trunk line 97.

In step S812, the segment regions 96 are grouped in each cluster 95. The grouping of the segments regions 96 is preferably performed to control the power of the logic circuit 91, for example, the segment regions 96 having the same operation frequency are grouped. Then, in step S812, after the segment regions 96 are grouped, the IR drop in the logic circuit 91 is sufficiently mitigated by integrating the wiring paths of the provisionally laid out power supply trunk lines 97 to form a tree structure power supply trunk line 97.

In step S813, switch devices 98 are provisionally arranged in the power supply trunk line 97. The switch devices 98 may be arranged in any manner. For example, the above described arrangements (i), (ii), or (iii) may be employed. When the switch devices 98 are provisionally arranged, the installation space of the switch device 98 may conflict with the installation space of the logic devices installed on the logic circuit 91.

In step S814, the layout of the LSI 90 is reconfigured as required, and the final layout of the LSI 90 is determined so as to avoid conflicting with the installation space of the switch devices 98. In step S815, the layout path of the power supply trunk lines 97 is determined, and the same power supply trunk line 97 is reconfigured.

In step S816, the width of each power supply trunk line 97 is adjusted such that the current density of each power supply trunk line 97 is less than the tolerable current density. In step S817, IR drop analysis is performed for each segment region 96, and IR drop maps are generated. In step S818, a determination is made as to whether or not the IR drop condition is satisfied in each segment region 96. When an IR drop that exceeds the upper limit is generated, the wiring widths are adjusted only for the power supply trunk line 97 provisionally laid out in the segment region 96 that generated the IR drop exceeding the upper limit.

In step S819, IR drop analysis is again performed for each segment region 96. When an IR drop that exceeds the upper limit is generated after the process of step S819, the processes of steps S810 to S818 are repeated only for the segment regions 96 that generated the IR drop exceeding the upper limit.

In addition to advantages (8), (9), and (12) to (15) of the fourth through sixth embodiments, the eighth embodiment has the advantage described below.

(17) Switch devices 98 are arranged in the power supply trunk lines 97. Thus, the power to the segment regions 96 is supplied and stopped by activating and inactivation the switch devices 98. This efficiently reduces the IR drop of the semiconductor integrated circuit, and the semiconductor integrated circuit is designed with a greater degree of freedom. Furthermore, the supply of power to the logic circuit 91 is controlled in steps before power is supplied to the basic power supply wires. Thus, there is less leakage current in the logic circuit 91, and power consumption is reduced in the semiconductor integrated circuit.

Although each segment and each cluster have separate power supplies in the seventh embodiment, the power supplies need not be separate.

Modifications of the eighth embodiment will now be described.

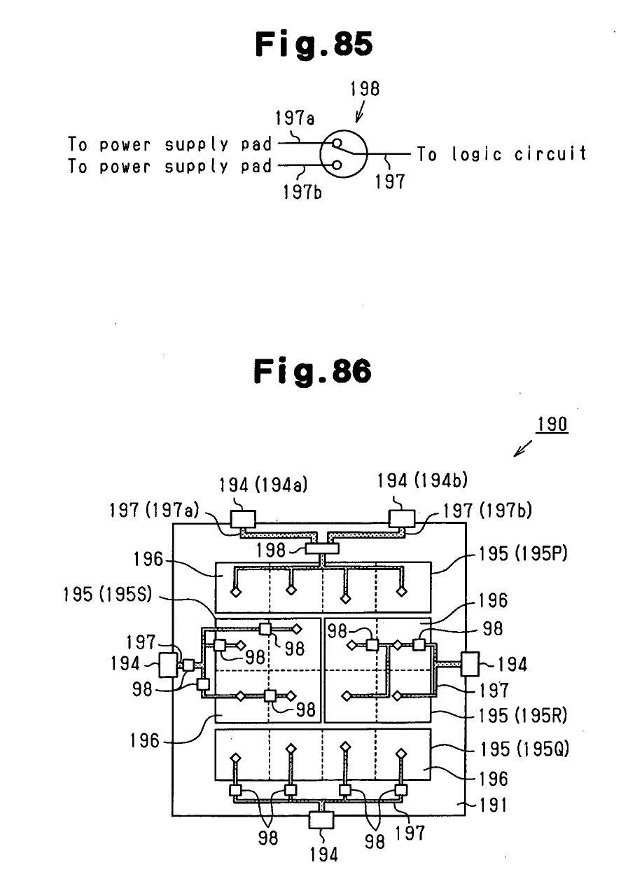

The switch device 198 shown in FIG. 85 may be used in lieu of the simple switch device 98 shown in FIG. 82. The switch device 198 is a multiplexer type switch device arranged between a power supply trunk line 197, which extends toward the logic circuit, and two power supply trunk lines 197a and 197b, which are respectively connected to the two power supply pads. The switch device 198 selects one of the two power supply trunk lines 197a or 197b. Power from the power supply pad connected to the selected power supply trunk line is supplied to the logic circuit through the power supply trunk line 197.

When the two power supply pads connected to the two power supply trunk lines 197a and 197b have different power potentials, a high potential and low potential power may selectively be supplied to the logic circuit by switching the switch device 198. For example, high potential power may be supplied to a specific region of the logic circuit to operate in a high-speed operating mode, and low potential power may be supplied to operate in a low-speed operating mode. Therefore, there is a high degree of freedom in the power supply wiring of a semiconductor integrated circuit having selectable operating modes.

FIG. 86 is a plan view of the power supply wiring of an LSI using the switch device 198 shown in FIG. 85.

In the LSI 90, the logic circuit 191 has four cluster regions 195 (195P to 195S). Five power supply pads 194 are arranged on the periphery of the four cluster regions 195. The cluster region 195P is associated with two power supply pads 194a and 194b. The power potential of the power supply pad 194a is higher than that of the power supply pad 194b. A multiplexer type switch device 198 is arranged between the cluster region 195P and the power supply pads 194a and 194b. This switch device 198 selects one of the two power supply trunk lines 197a and 197b respectively connected to the two power supply pads 194a and 194b. High potential power or low potential power is selectively supplied to each segment region 196 in the cluster region 195 by switching the switch device 198.

In addition to advantages (8), (9), and (12) to (15) of the fourth through sixth embodiments, this modification has the advantage described below.

(18) A multiplexer type switch device 198 is arranged in the path connecting the cluster region 195P and the two power supply pads 194a and 194b so as to integrate the power supply trunk lines 197a and 197b extending from the two power supply pads 194a and 194b. Therefore, the semiconductor integrated circuit realizes power delivery with a higher degree of freedom when considering the reduction of IR drop.

Each of the embodiments also may be modified as described below.

In the second embodiment, the power supply wiring procedures of each of the described modifications (first through fourth modifications) may be combined as required when performing the wiring process of the power supply wiring. For example, when the wiring sequences of the first and second modifications are combined, based on the wiring process of the first modification, the correction process of the reinforcing power supply wire position (steps S207 to S213) in the first modification may be performed in lieu of the correction process of the second modification (steps S213a1 to S213a8). In the same manner, the wiring procedures of the first and third modifications may be combined.

Furthermore, the wiring procedure of the fourth modification may be combined with a combination of the wiring procedures of the first and second modifications or the first and third modifications. In this case, the process for adding and laying out the partial reinforcing power supply wires 435 (steps S213c1 to S213c4) may be performed as the final wiring process of the power supply wiring.

In the third modification of the second embodiment, ultimately, the reinforcing power supply wires 331 may be laid out again so that the reinforcing power supply wires 331 are straight. In this case, the reinforcing power supply wires 331 are laid out again so as not to generate an IR drop that exceeds the upper limit.

In the process for changing the width of the reinforcing power supply wires or the power supply trunk lines in the second through eighth embodiments, the process described in the first embodiment (process for dividing the reinforcing power supply wires in predetermined units in the longitudinal direction and for setting the wire width to mitigate at least either one of the excessive current density or IR drop in each wire segment) may be performed.

In the third embodiment, a process may be performed to add the partial reinforcing power supply wires 435.

In the fourth and fifth embodiments, when an overlap region is generated between a plurality of main power pieces MP, a division adjustment process is performed only for the main power piece MP that has the farthest distance from the power supply pad to the overlap region, and division adjustment is not performed for the main power piece MP with the shortest distance from the power supply pad connected to the main power supply trunk line to the overlap region (refer to FIG. 49). However, the invention is not limited in this manner and division adjustment also may be performed for both overlapping main power pieces MP.

In the fourth and fifth embodiments, the power piece is electrically shielded from other regions, and IR drop analysis is performed for that power piece assuming that equal potential power supplies are arranged on the periphery. Alternatively, a plurality of power supplies having different potentials may be assumed to be arranged on the periphery of the power piece when performing IR drop analysis. For example, IR drop analysis may also be performed assuming that low potential power supplies are arranged on the periphery near cells susceptible to power fluctuation. By arranging the reinforcing power supply wires based on the analysis result, the reinforcing power supply wire can be arranged on a priority mainly in cells susceptible to power fluctuation.

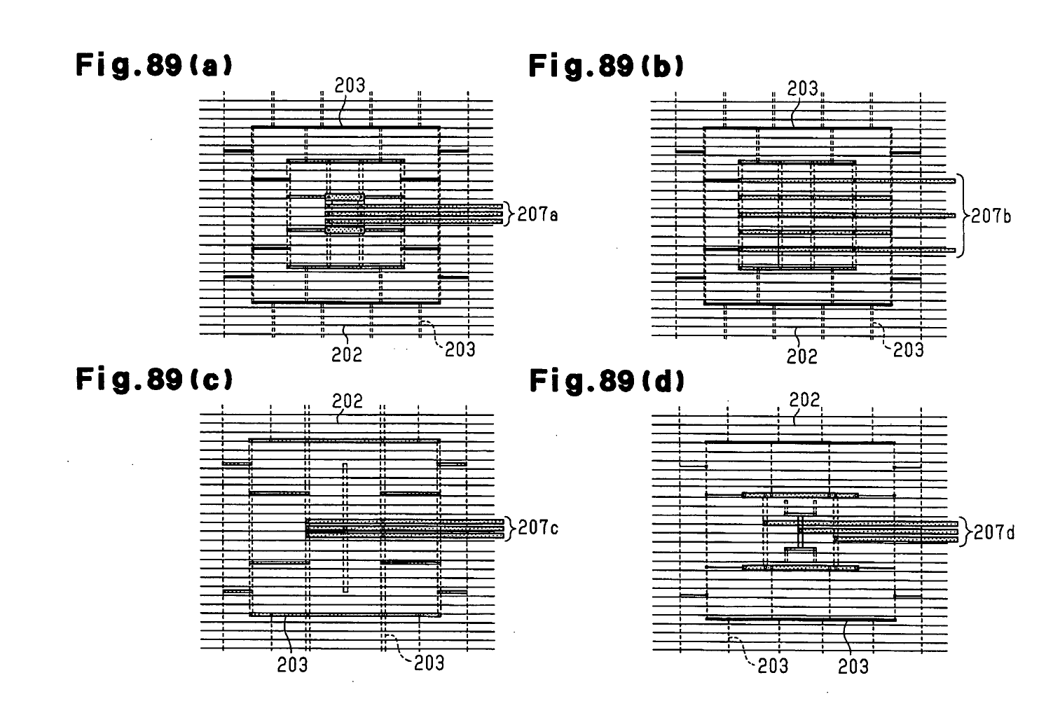

In the fourth through eighth embodiments, at least one power supply trunk line (57, 67, 77, 87, 97, 197) is designed as a power supply trunk line 207 formed by a plurality of parallel strip-like divided parallel wires, and this power supply trunk line 207 may be connected to a basic power supply wire 202 and reinforcing power supply wire 203. Furthermore, such a power supply trunk line is not limited to the power supply trunk line 107 and may be power supply trunk lines 207a to 207d shown FIG. 89(a) to 89(d). In FIGS. 88 and 89, the basic power supply wires 202, reinforcing power supply wires 203, and power supply trunk lines 207, 207a to 207d are respectively equivalent to the basic power supply wires (58, 68, 72), reinforcing power supply wires (51, 61, 73), and power supply trunk lines (57, 67, 77, 87, 97, 197) of the fourth through eighth embodiments. Furthermore, in FIGS. 88 and 89, the square symbols shown in the power supply wiring and at each distal portion are predetermined connection holes, such as via holes or the like, and are electrical connection points of the power supply wiring.

In the fourth through eighth embodiments, regulated values, such as amount of power and the like, may be set individually for each segment. Furthermore, regulated values, such as amount of power and the like, may be set individually for each cluster. For example, regulated values of cluster regions or segment regions may be weighted in accordance with the distance to the power supply pad. In this case, since weighting is performed to increase the regulated values from the power supply pads approaching nearer to the segments and clusters, more power is effectively supplied by shorter power supply trunk lines.

In the fifth through eighth embodiments, the power supply ring described in the first embodiment may be arranged, and the power supply ring and the power supply trunk lines may be electrically connected.

In the fifth through the eighth embodiments, a power supply ring may be provided for each cluster region and each segment region.

In the fifth through eighth embodiments, cluster regions are provided in numbers equal to the number of power supply pads, however, the number of cluster regions may be different from the number of power supply pads. In this case, the association of the power supply pads and cluster regions may be accomplished, for example, based on the distance between the power supply pad and the power supply point, or the amount of power consumed in the cluster region or the like.

In the fifth through eighth embodiments, the power supply mesh (reinforcing power supply wires) is open and there are no power supply wires connecting between distal ends. However, the power supply mesh may be connected between distal ends in a ring-like (closed) manner.

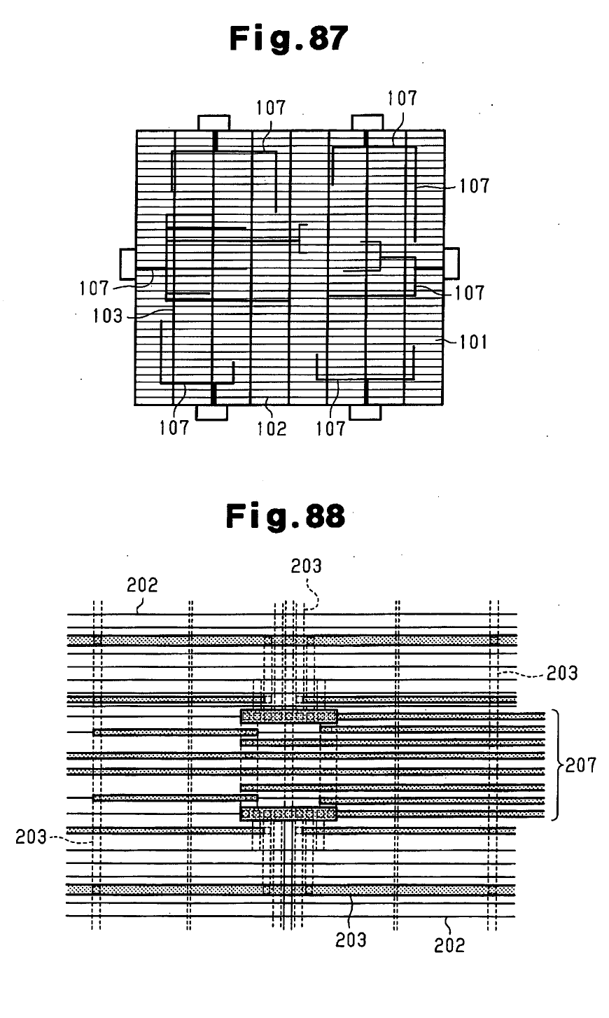

In the sixth through eighth embodiments, the power supply trunk line 107 may be arranged in the logic circuit 101 without separating the basic power supply wires 102 and reinforcing power supply wires 103 in all regions as shown in FIG. 87, rather than providing power supply trunk lines having a tree structure with step-like branches. In FIG. 87, the basic power supply wires 102, reinforcing power supply wires 103, and power supply trunk lines 107 are respectively equivalent to the basic power supply wires (72), reinforcing power supply wires (73), and power supply trunk lines (77, 87, 97, 197) of the sixth through eighth embodiments.

In the sixth through eighth embodiments, the power supply trunk lines may be arranged on the circuit after the reinforcing power supply wires are arranged in the wiring mode of the first through third embodiments.

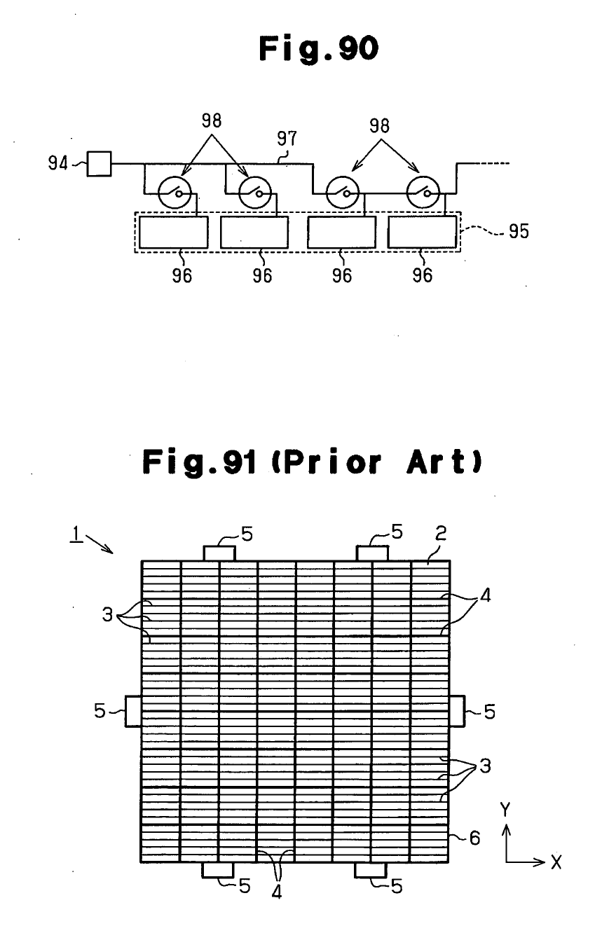

The switch device 98 of the eighth embodiment also may be arranged in multiple steps. For example, as shown in FIG. 90, a power switch may be configured by two switch devices 98 arranged in parallel between the power supply pad 94 and two segment regions 96, and a switch device 98 arranged in series between the power supply pad 94 and two segment regions 96.

In each embodiment, the power supply wiring also may be arranged in predetermined directions other than the X direction and Y direction.

In each embodiment, the position of the power supply pad is not limited to the periphery of the logic circuit and may be anywhere on the chip.

In each embodiment, the reinforcing power supply wire also may be arranged using the wiring mode of the power supply trunk lines 207, and 207a to 207d shown in FIGS. 88 and 89(a) to 89(d).

In each embodiment, both the vertical reinforcing power supply wire and lateral reinforcing power supply wire are laid out. However, only one of the vertical reinforcing power supply wire and the lateral reinforcing power supply wire may be laid out.

In each embodiment, the current of each cell calculated when preparing the IR drop map also may be a representative value such as a maximum value, median value or the like.

In each embodiment, the IR drop analysis is performed for provisional power supply wiring (simulation model) assuming that the basic power supply wire is connected. However, the analysis also may be performed with an actual power supply wiring in which the basic power supply wires are actually connected.

In each embodiment, the IR drop analysis is performed with or in parallel with the EM analysis (current density calculation). Therefore, when configuring the power supply wiring by IR drop analysis, the width of the power supply wiring can be adjusted based on the current density obtained by EM analysis.

In each embodiment, ground potential power supply wiring, or VSS potential power supply wiring, and other power supply wiring can be arranged in the same manner as in the reinforcing power supply wires in the first through fifth embodiments or in the same manner as the power supply trunk lines in the fourth through eighth embodiments.

In each embodiment, the width adjustment of the power supply wiring includes increasing and decreasing the number of strip-like parallel wires.

In each embodiment, the power supply portion is not limited to a power supply pad. For example, the power supply portion also may be a power supply point such as a power output terminal provided in the power circuit (not shown), an internal power supply circuit and the like.

The present invention is applicable for power supply to circuits other than a logic circuit, such as a memory circuit and an analog circuit.

1-29. (canceled)

30. A semiconductor integrated circuit device comprising:
a circuit portion;
a first power supply wire for supplying power to the circuit portion;
second power supply wires electrically connected to the first power supply wire, wherein at least one of width of each second power supply wire and an interval between the second power supply wires is set so as to mitigate voltage drop in the second power supply wires, wherein the second power supply wires define a plurality of row regions or column regions in the circuit portion, and the interval between the plurality of second power supply wires is non-uniform.

31. A semiconductor integrated circuit device comprising:
a circuit portion;
a first power supply wire for supplying power to the circuit portion;
second power supply wires electrically connected to the first power supply wire, wherein at least one of width of each second power supply wire and an interval between the second power supply wires is set so as to mitigate voltage drop in the second power supply wires, and wherein some of the second power supply wires include wire segments defining regions having polygonal shapes other than square shapes in the circuit portion.

32. A semiconductor integrated circuit device including a circuit portion and a first power supply wire for supplying power to the circuit portion, the semiconductor integrated circuit device being characterized by:
a plurality of second power supply wires electrically connected to the first power supply wire so as to define a plurality of row regions or column regions in the circuit portion, wherein an interval between the plurality of second power supply wires is non-uniform.

33. The semiconductor integrated circuit device according to claim 32, wherein the second power supply wires have different widths at a plurality of locations.

34. A semiconductor integrated circuit device comprising:
a circuit portion;
a first power supply wire for supplying power to the circuit portion;
second power supply wires electrically connected to the first power supply wire, wherein at least one of width of each second power supply wire and an interval between the second power supply wires is set so as to mitigate voltage drop in the second power supply wires; and
a power supply trunk line extends from a power supply portion to an interior of the circuit portion to supply power to the second power supply wires.

35. The semiconductor integrated circuit device according to claim 34, wherein the circuit portion includes a plurality of division regions in which the first power supply wire and the second power supply wires are arranged, each division region includes a plurality of electrically disconnected segment regions, and the power supply trunk line includes one basal portion and a plurality of distal portions respectively associated with the plurality of segment regions.

36. The semiconductor integrated circuit device according to claim 34, wherein the circuit portion includes a plurality of division regions in which the first power supply wire and the second power supply wires are arranged, the first power supply wire and the second power supply wires are arranged in each division region and electrically disconnected from other division regions, and the power supply trunk line includes one basal end and at least one distal end portion associated with at least one of the plurality of division regions.

37. A semiconductor integrated circuit device comprising:
a circuit portion;
a first power supply wire for supplying power to the circuit portion;
a power supply trunk line including a basal end connected to a power supply portion and a plurality of distal portions connected to the first power supply wire, the power supply trunk line having a tree structure branching in steps between the power supply portion and the first power supply wire.

38. The semiconductor integrated circuit device according to claim 37, wherein the power supply trunk line has different widths at a plurality of locations.

39. The semiconductor integrated circuit device according to claim 37, further comprising:
a switch device arranged on the power supply trunk line for controlling the power supply from the power supply trunk line.

40. A method for wiring a power supply of a semiconductor integrated circuit device including a circuit portion and a first power supply wire for supplying power to the circuit portion, the method comprising:
providing second power supply wires electrically connected to the first power supply wire; and
setting at least one of width of the second power supply wires and an interval of the second power supply wires to mitigate voltage drop in the second power supply wires, wherein the step of setting includes:
provisionally laying out the plurality of second power supply wires so as to define a plurality of regions in the circuit portion;
calculating a voltage drop value for each block; and
setting an interval of the plurality of second power supply wires such that the total of voltage drop values of a plurality of blocks in each region is substantially equal between the plurality of regions.

41. The method for wiring a power supply according to claim 40, wherein the second power supply wire is one of a plurality of second power supply wires defining the circuit portion into a plurality of rectangular regions, wherein the step of setting includes:
calculating a voltage drop value of each rectangular region; and
adding a partial reinforcing wire to connect two second power supply wires associated with a rectangular region having a voltage drop value that exceeds the tolerable range so as to divide the rectangular region into two.

42. The method for wiring a power supply according to claim 40, wherein the second power supply wire is one of a plurality of second power supply wires, wherein the step of setting includes:
provisionally laying out a plurality of second power supply wires on the circuit portion to divide the circuit portion into a plurality of regions;
dividing each region into a plurality of blocks, each having a predetermined minimum size;
calculating a voltage drop value of each block;
calculating a representative voltage drop value of the plurality of regions;
comparing the representative voltage drop values of blocks in adjacent regions;
provisionally laying out again the plurality of second power supply wires so that the representative voltage drop values in adjacent regions are substantially equal;
obtaining distribution of the voltage drops in the circuit portion after provisionally laying out again the wires;
determining whether or not a voltage drop that exceeds a predetermined upper limit is generated in the circuit portion; and
when a voltage drop exceeding the upper limit is generated, repeating said calculating a voltage drop value, comparing the representative voltage drop values, and provisional laying out again the plurality of second power supply wires until the voltage drop becomes less than or equal to the upper limit.

43. The method for wiring a power supply according to claim 40, wherein the second power supply wire is one of a plurality of second power supply wires, wherein the step of setting includes:
obtaining voltage drop distribution of the circuit portion and storing a provisional voltage drop peak position at which a voltage drop peaks occur;
provisionally laying out a plurality of second power supply wires such that at least one of the plurality of second power supply wires passes through the provisional voltage drop peak position;
increasing width of the second power supply wire that passes through the provisional voltage drop peak position until the voltage drop value becomes less than or equal to a predetermined upper limit at the provisional voltage drop peak position;
obtaining the voltage drop distribution of the circuit portion with the provisionally laid out plurality of second power supply wires, and determining whether or not a voltage drop exceeding the upper limit value is generated in the circuit portion; and
when a voltage drop exceeding the upper limit is generated, repeating said storing the provisional voltage drop peak position, said provisionally laying out the plurality of second power supply wires, said increasing width of the second power supply wires, and determining the voltage drop until the voltage drop becomes less than or equal to the upper limit.

44. The method for wiring a power supply of a semiconductor integrated circuit device according to claim 40, further comprising:
arranging a provisional second power supply wire on the circuit portion;
obtaining a provisional power drop distribution in the circuit portion in a state in which with the provisional second power supply wire is arranged, and storing a provisional voltage drop peak position;
setting a main power piece in the circuit portion so as to include the provisional voltage drop peak position therein and substantially equalize power consumption thereof with a regulated value;
obtaining the provisional voltage drop in the main power piece and storing the provisional voltage drop peak position in the main power piece under the assumption that the main power piece is electrically disconnected from other regions excluding the main power piece in the circuit portion; and
arranging a power supply trunk line so as to connect a power supply portion to the vicinity of the provisional power drop peak position in the main power piece.

45. The method for wiring a power supply of a semiconductor integrated circuit device according to claim 40, further comprising:
arranging a provisional second power supply wire in the circuit portion;
obtaining a provisional voltage drop distribution in the circuit portion in a state in which the provisional second power supply wire is arranged, and storing the provisional voltage drop peak position;
setting a main power piece in the circuit portion so as to include the provisional voltage drop peak position therein and substantially equalize power consumption thereof with a regulated value;
obtaining the provisional voltage drop in the main power piece and storing the provisional voltage drop peak position in the main power piece under the assumption that the main power piece is electrically disconnected from other regions excluding the main power piece in the circuit portion;
laying out a main power supply trunk line so as to connect a power supply portion to the vicinity of the provisional power drop peak position in the main power piece;
obtaining the provisional voltage drop distribution in the circuit portion in a state in which the main power supply trunk line is laid out, and storing the provisional voltage drop peak positions of the other regions; and
laying out a secondary power supply trunk line so as to connect the power supply portion to the vicinity of the voltage drop peak position of the other regions.

46. A method for wiring a power supply of a semiconductor integrated circuit device including a circuit portion and a first power supply wire for supplying power to the circuit portion, the method comprising:
providing second power supply wires electrically connected to the first power supply wire, the second power supply wires defining a plurality of rectangular regions in the circuit portion; and
setting at least one of width of the second power supply wires and an interval of the second power supply wires to mitigate voltage drop in the second power supply wires, wherein the step of setting includes:
calculating a voltage drop value for each of the rectangular regions; and
moving a wire segment of a second power supply wire defining a rectangular region having a voltage drop value that is not tolerable such that the voltage drop values of the plurality of rectangular regions are in a tolerable range.

47. The method for wiring a power supply according to claim 46, wherein the second power supply wire is one of a plurality of second power supply wires defining the circuit portion into a plurality of rectangular regions, wherein the step of setting includes:
calculating a voltage drop value of each rectangular region; and
adding a partial reinforcing wire to connect two second power supply wires associated with a rectangular region having a voltage drop value that exceeds the tolerable range so as to divide the rectangular region into two.

48. The method for wiring a power supply according to claim 46, wherein the second power supply wire is one of a plurality of second power supply wires, wherein the step of setting includes:
provisionally laying out a plurality of second power supply wires on the circuit portion to divide the circuit portion into a plurality of regions;
dividing each region into a plurality of blocks, each having a predetermined minimum size;
calculating a voltage drop value of each block;
calculating a representative voltage drop value of the plurality of regions;
comparing the representative voltage drop values of blocks in adjacent regions;
provisionally laying out again the plurality of second power supply wires so that the representative voltage drop values in adjacent regions are substantially equal;
obtaining distribution of the voltage drops in the circuit portion after provisionally laying out again the wires;
determining whether or not a voltage drop that exceeds a predetermined upper limit is generated in the circuit portion; and
when a voltage drop exceeding the upper limit is generated, repeating said calculating a voltage drop value, comparing the representative voltage drop values, and provisional laying out again the plurality of second power supply wires until the voltage drop becomes less than or equal to the upper limit.

49. The method for wiring a power supply according to claim 46, wherein the second power supply wire is one of a plurality of second power supply wires, wherein the step of setting includes:
obtaining voltage drop distribution of the circuit portion and storing a provisional voltage drop peak position at which a voltage drop peaks occur;
provisionally laying out a plurality of second power supply wires such that at least one of the plurality of second power supply wires passes through the provisional voltage drop peak position;
increasing width of the second power supply wire that passes through the provisional voltage drop peak position until the voltage drop value becomes less than or equal to a predetermined upper limit at the provisional voltage drop peak position;
obtaining the voltage drop distribution of the circuit portion with the provisionally laid out plurality of second power supply wires, and determining whether or not a voltage drop exceeding the upper limit value is generated in the circuit portion; and
when a voltage drop exceeding the upper limit is generated, repeating said storing the provisional voltage drop peak position, said provisionally laying out the plurality of second power supply wires, said increasing width of the second power supply wires, and determining the voltage drop until the voltage drop becomes less than or equal to the upper limit.

50. The method for wiring a power supply of a semiconductor integrated circuit device according to claim 46, further comprising:
arranging a provisional second power supply wire on the circuit portion;
obtaining a provisional power drop distribution in the circuit portion in a state in which with the provisional second power supply wire is arranged, and storing a provisional voltage drop peak position;
setting a main power piece in the circuit portion so as to include the provisional voltage drop peak position therein and substantially equalize power consumption thereof with a regulated value;
obtaining the provisional voltage drop in the main power piece and storing the provisional voltage drop peak position in the main power piece under the assumption that the main power piece is electrically disconnected from other regions excluding the main power piece in the circuit portion; and
arranging a power supply trunk line so as to connect a power supply portion to the vicinity of the provisional power drop peak position in the main power piece.

51. The method for wiring a power supply of a semiconductor integrated circuit device according to claim 46, further comprising:
arranging a provisional second power supply wire in the circuit portion;
obtaining a provisional voltage drop distribution in the circuit portion in a state in which the provisional second power supply wire is arranged, and storing the provisional voltage drop peak position;
setting a main power piece in the circuit portion so as to include the provisional voltage drop peak position therein and substantially equalize power consumption thereof with a regulated value;
obtaining the provisional voltage drop in the main power piece and storing the provisional voltage drop peak position in the main power piece under the assumption that the main power piece is electrically disconnected from other regions excluding the main power piece in the circuit portion;
laying out a main power supply trunk line so as to connect a power supply portion to the vicinity of the provisional power drop peak position in the main power piece;
obtaining the provisional voltage drop distribution in the circuit portion in a state in which the main power supply trunk line is laid out, and storing the provisional voltage drop peak positions of the other regions; and
laying out a secondary power supply trunk line so as to connect the power supply portion to the vicinity of the voltage drop peak position of the other regions.

52. A method for wiring a power supply of a semiconductor integrated circuit including a circuit portion and a plurality of power supply portions, the method including the steps of:
dividing the circuit portion into a plurality of cluster regions, each of which includes at least one segment region;
associating a plurality of cluster regions with a plurality of power supply nodes and provisionally connecting the segment regions of each cluster region to an associated power supply portion with a plurality of power supply trunk lines; and
integrating the plurality of power supply trunk lines provisionally connected to each power supply portion into a single tree-like power supply trunk line having one basal portion connected to an associated power supply node, and a plurality of distal portions connected to a plurality of segment regions of an associated cluster region.
